(19) United States
(12) Patent Application Publication
(10) Pub. No.: US 2006/0093852 A1
(43) Pub. Date: May 4, 2006

(54) Phosphorescent and luminescent conjugated polymers and their use in electroluminescent assemblies

(76) Inventors: Dirk Marsitzky, Munchen (DE); Helmut-Werner Heuer, Krefeld (DE); Rolf Wehrmann, Krefeld (DE); Andreas Elschner, Mulheim (DE); Knud Reuter, Krefeld (DE); Armin Sautter, Shanghai (CN)

Correspondence Address: BAYER MATERIAL SCIENCE LLC, 100 BAYER ROAD, PITTSBURGH, PA, 15205, US

(21) Appl. No.: 10/516,627

(22) PCT Filed: May 30, 2003
(86) PCT No.: PCT/EP03/05699

§ 371 Date: Nov. 7, 2005

(30) Foreign Application Priority Data
Jun. 4, 2002 (DE) 102 24 617.3
Mar. 18, 2003 (DE) 103 11 767.9

(51) Int. Cl. C09K 11/06; H01L 51/54; H05B 33/14

(52) U.S. Cl. 428/690; 252/301.16; 252/301.35; 428/917; 313/504; 313/506; 257/40; 257/E51.044; 257/E51.043; 427/66; 528/9; 528/395

(57) ABSTRACT

The invention relates to phosphorescent or luminescent conjugated polymers, whose emission is based on the phosphorescence of covalently bonded metal complexes, optionally combined with the fluorescence of the polymer chain. The invention also relates to a method for producing said polymers and to their use in electroluminescent assemblies.

The invention relates to phosphorescent or luminescent conjugated polymers, the emission thereof based on phosphorescence of covalently bonded metal complexes optionally in combination with fluorescence of the polymer chain, a process for the preparation thereof and the use thereof in electroluminescent arrangements.

Electrically conductive organic and polymeric materials are increasingly being used in optoelectronic applications, such as, for example, light emitting diodes (LEDs), solar cells, laser diodes, field effect transistors and sensors.

In addition to arrangements based on low molecular weight organic compounds applied by vapour deposition (Tang et al., Appl. Phys. Lett. 1987, 51, 913), polymers such as, for example, poly(p-phenylenes) (PPP), poly(p-phenylenevinylenes) (PPV) and poly-2,7-(fluorenes) (PF), in electroluminescent arrangements have been described (e.g. A. Kraft et al., Angew. Chem. Int. Ed. 1998, 37, 402).

The light emission in organic light emitting diodes usually preferably takes place through fluorescence processes. The electroluminescence (EL) quantum efficiency of an arrangement comprising a fluorescent emitter is, however, limited by the low theoretical ratio of singlet excitons (25%) to triplet excitons (75%), which are formed by electron-hole recombination, since the light emission takes place only from excited singlet states. The advantage of phosphorescent emitters is that both the singlet and the triplet states contribute to the light emission, i.e. the internal quantum efficiency may be up to 100% since all excitons can be used for the light emission.

As a rule, the organic electroluminescence (EL) arrangements contain, in addition to the light-emitting layer, one or more layers comprising organic charge transport compounds. The fundamental structure in the sequence of the layers is as follows:
1 Carrier, substrate
2 Base electrode
3 Hole-injecting layer
4 Hole-transporting layer
5 Light-emitting layer
6 Electron-transporting layer
7 Electron-injecting layer
8 Top electrode
9 Contacts
10 Covering, encapsulation.

The layers 1 to 10 constitute the electroluminescent arrangement. The layers 3 to 7 constitute the electroluminescent element. A hole-blocking layer may furthermore be present between light-emitting layer (5) and electron-transporting layer (6).

This structure describes the most general case and can be simplified by omitting individual layers so that one layer performs a plurality of tasks. In the simplest case, an EL arrangement consists of two electrodes between which there is an organic layer which performs all functions—including the emission of light.

Multilayer systems in LEDs can be built up by chemical vapour deposition methods (CVD) in which the layers are applied successively from the gas phase, or by casting methods. The chemical vapour deposition methods are used in combination with the shadow mask technique for the production of structured LEDs which use organic molecules as emitters. Such gas-phase processes which have to be carried out in vacuo and cannot be operated continuously are, however, expensive and time-consuming. Application processes from solution, such as casting (e.g. spin-coating) and printing processes of all types (inlet, flexographic printing, screen printing, etc.) are generally preferred because of the higher process speeds, the lower complexity of the apparatus and the associated cost saving. The printing technique, in particular the inkjet technique, for structuring polymeric emitters is currently receiving a great deal of attention (Yang et al. Appl. Phys. Lett. 1998, 72 (21), 2660; WO 99/54936).

The incorporation of phosphorescent dopants into organic LEDs has been proposed for increasing the efficiency of the electroluminescent arrangements. For the use of the bis(2-phenylpyridine)iridium(III) acetylacetonate [(ppy)₂Ir(acac)] complex, which phosphoresces green, as a dopant in EL arrangements, external EL efficiencies of 19% were determined (C. Adachi et al., J. Appl. Phys. 2001, 90, 5048).

To date, mainly electroluminescent arrangements comprising phosphorescent dopants (“small molecules”) have been described. In general, a metal complex phosphorescing at room temperature (e.g. iridium(III) complex or platinum(II) complex cyclometallated via carbon-nitrogen) is randomly distributed in an organic molecular or polymeric matrix by vacuum vaporization processes. Furthermore, the doping can be effected by dissolution of dopant and organic matrix together in a solvent and subsequent application by a casting process (e.g. S. Lamansky, Organic Electronics 2001, 2, 53).

Soluble low molecular weight iridium complexes having bulky fluorenyl-pyridine or fluorenyl-phenylpyridine ligands, which are accessible to application from solution but have only very low EL efficiencies of 0.1% in EL arrangements, were recently synthesized (J. C. Ostrowski et al., Chem. Commun. 2002, 784-785).

The disadvantages of the low molecular weight phosphorescent emitter materials in EL arrangements are extinction processes, in general and in particular the reduction in the luminous efficiency at relatively high current densities, which is caused by saturation of the emitting centres owing to long phosphorescence lifetimes and/or by migration processes of the dopants (M. A. Baldo et al., Pure Appl. Chem. 1999, 71 (11), 2095).

The direct covalent linkage of phosphorescent metal complexes to polymers was recently reported. U.S. Pat. No. 0,015,432 A1 describes iridium metal complexes which are complexed with the conjugated polymer backbone via diaza-(bipyridyl) ligands. The polymers described are charged and are surrounded by opposite ions (polyelectrolytes), resulting in migration in an electric field, which migration has a disadvantageous effect on the stability of the arrangements. The light emission of these polymers is, however, limited to the orange-coloured or red spectral range. EP 1 138 746 A1 describes branched conjugated or partly conjugated polymers which may contain a phosphorescent metal complex, a disadvantageous effect being that, owing to the choice of the monomers, an interruption in the conjugation and consequently an undesired shortening of the conjugation length are brought about, resulting in a deterioration in the transport of charge carriers by the layers. Furthermore, owing to the use of iridium-monomer mixtures, it is not possible to prepare polymers having a defined composition, which is likewise disadvantageous for charge carrier transport by the layers. WO 01/96454 A1 describes polymer matrices based on aromatic repeating units which may contain a luminescent metal complex.

For the production of polymeric LEDs having high luminous efficiencies, there is a considerable need for efficient electrophosphorescent polymer emitter materials which can be processed by simple and economical casting or printing methods and lead to high external quantum efficiencies and a long life in the OLED device (OLED=organic light emitting diode).

It was therefore an object to provide improved phosphorescent polymers which are suitable for use as emitter materials, for example in abovementioned LEDs, and are accessible to application from solution.

In particular, white organic light emitting diodes, i.e. those which emit white light, are becoming increasingly interesting as economical backlighting of liquid crystal screens, as flat illumination sources or for the production of full-colour displays by combination with colour filters.

There are various possibilities and concepts for producing white light using organic light emitting diodes. White light is produced by additive colour mixing of the three primary colours red, green and blue or can be produced by mixing complementary colours, such as, for example, blue and yellow light. Light emitting diodes appear white when they have a very broad and uniform emission over the total visible spectral range from 400 to 800 nm.

This emission cannot as a rule be realized using a single emitter material, and mixtures of emitter materials (components) of different colours therefore have to be used. It has proved to be advantageous to choose the structure of the light emitting diodes so that the individual emitter materials are separated from one another in different layers, in order to achieve the uniform and separated emission of the emitters of different colours. Without this separation, energy transfer processes which can be controlled only with difficulty, for example between blue and green or red emitter, generally take place, which reduces the blue component and increases the red component (e.g. EP-A 1 182 244). However, the separation of the emitters in different layers is also not trivial since it is necessary to ensure that the charge carrier recombination, a precondition for emission, takes place efficiently and in a balanced manner in every layer. This leads to complicated multilayer structures which contain additional intermediate layers (e.g. for localization of the excitation states in the respective layer) (U.S. Pat. No. 6,447,934) and are therefore expensive and not very attractive for mass production.

White polymeric light emitting diodes which contain a blue-emitting polymer, e.g. polyfluorene or polyvinylcarbazole, and a suitable red or orange doping dye have been described. The dopant concentrations must be very exactly established and are often only fractions of a percent (Kido et al., Applied Physics Letters 1995, 67(16), 2281). In the case of doping, there is always the danger of a reduction in the long-term stability owing to separation, crystallization and/or migration of the low molecular weight dopants in the emitter layer.

The choice of a plurality of emitter components has a further serious disadvantage, so-called “differential ageing” of the individual emitter components, i.e. the rapid fading of the individual emitters to different degrees, which results in a shift in the colour location away from the white point—often also referred to as the achromatic point.

Many of the white light emitting diodes known to date exhibit a dependence of the colour location on the applied voltage and brightness since various emitter components are used, which in each case have different current-voltage-brightness characteristics.

To date, only two examples based on polymeric white one-component emitter materials have been described in the literature:

Lee et al., Applied Physics Letters 2001, 79(3), 308, describe a copolymer comprising oxadiazole, phenylene-vinylene and alkyl ether units which emits white light in a one-layer light emitting diode. The maximum efficiency is only 0.071 cd/A, the operating voltages are very high, the current flow is low and the light emitting diode exhibits a considerable dependence of the colour location on the voltage (12 V blue-green, 20 V virtually white). Zhan et al., Synthetic Metals 2001, 124, 323 investigated a copolymer comprising diethinylfluorene and thiophene units which emits white light in a two-layer structure (copper phthalocyanine hole-injection layer and polymer emitter layer). The external quantum efficiency is only 0.01%, electroluminescence is detectable only above a voltage of 11 V and the current flow through the device is low (23.7 mA/cm² at 19 V). Owing to their low efficiencies and unsatisfactory current-voltage-brightness characteristics, both examples are of no relevance for industrial use.

A further object was to provide one-component emitter materials which emit white light and can be processed from solution. These should preferably exhibit efficient white emission in the simple device structure itself, for example in the two-layer structure (hole-injection layer and emitter layer).

Surprisingly, it has now been found that phosphorescent polymers which are conjugated and neutral and contain at least one covalently bonded phosphorescent metal complex are suitable for use as emitter materials, for example in abovementioned LEDs, and are accessible to application from solution.

The present invention therefore relates to phosphorescent polymers which are conjugated and neutral and contain at least one covalently bonded phosphorescent metal complex.

In the context of the invention, conjugated means that the main chain of the polymers may be either completely conjugated or partly conjugated. A large conjugation length in the main chain is advantageous for good charge carrier transport, and polymers having such a conjugation length are therefore preferred, in particular polymers having a completely conjugated main chain.

The phosphorescent conjugated polymers according to the invention are preferably straight-chain, which, in the context of the invention, means that they can in some cases contain only short side chains which serve for the covalent linkage of the phosphorescent metal complexes but are not growth sites of the polymer and hence not branching points.

The phosphorescent conjugated polymers according to the invention exhibit electrophosphorescence, i.e. phosphoresce—for example in the OLED—as a result of electrical excitation. However, they may also be caused to phosphoresce by optical excitation.

These are preferably phosphorescent conjugated polymers which contain at least one phosphorescent metal complex covalently bonded via at least one ligand L¹, where the ligand L¹ represents units selected from the formulae I to XXIXc 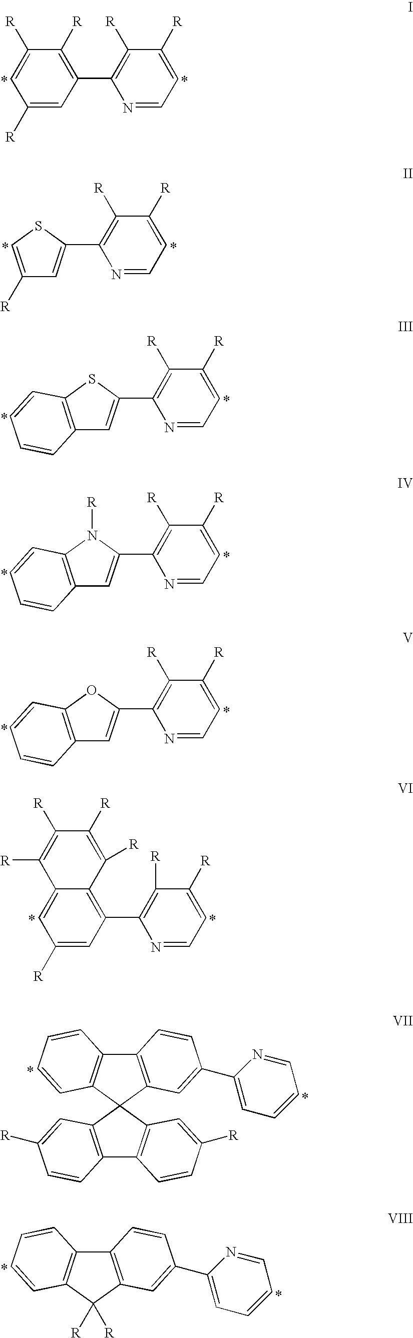 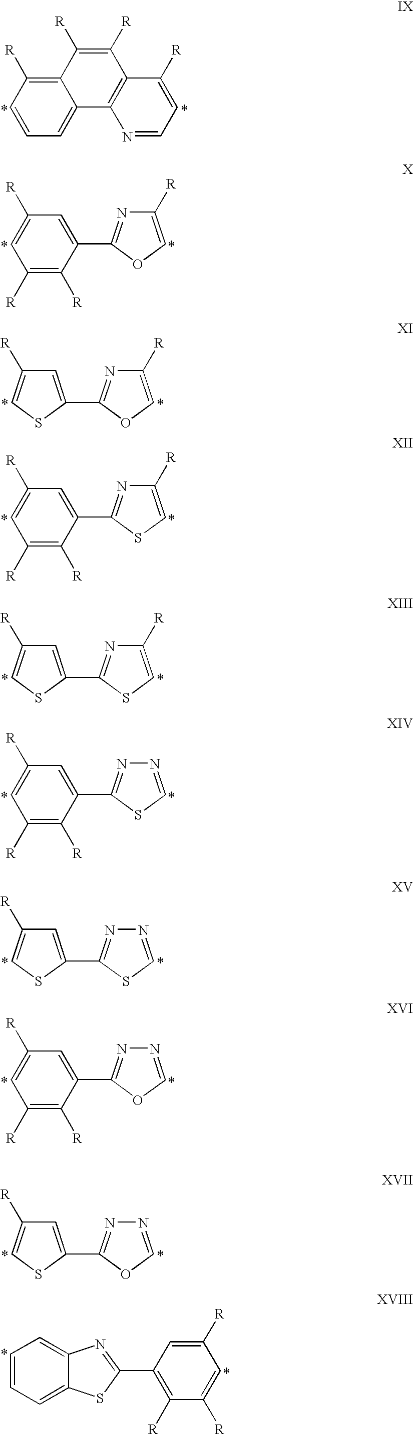 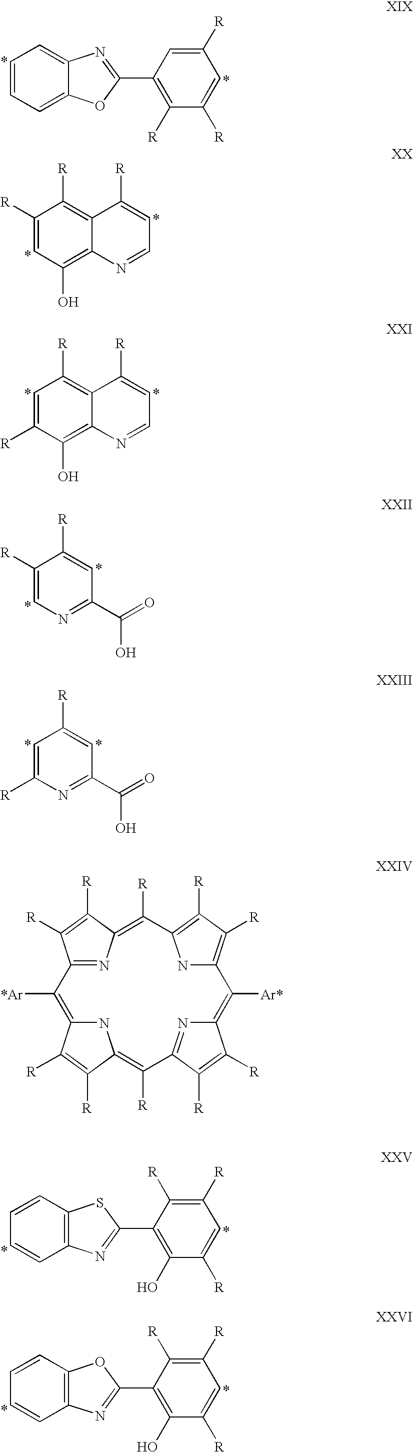 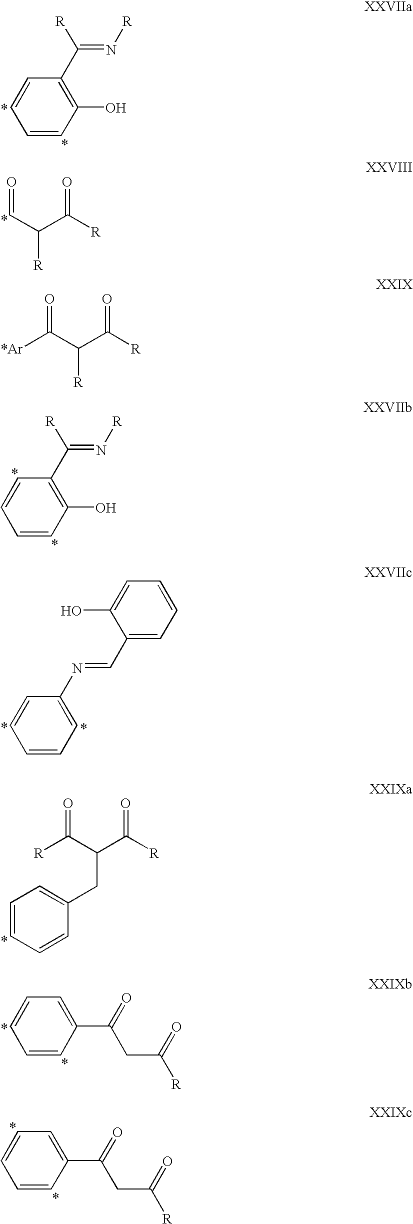
R are identical or different and, independently of one another, represent H, F, CF₃, a linear or branched C₁-C₂₂-alkyl group, a linear or branched C₁-C₂₂-alkoxy group, an optionally C₁-C₃₀-alkyl-substituted C₅-C₁₀-aryl unit and/or an optionally C₁-C₃₀-alkyl-substituted heteroaryl unit having 5 to 9 ring C atoms and 1 to 3 ring hetero atoms from the group consisting of nitrogen, oxygen and sulphur, and/or represent a linear or branched, partly fluorinated or perfluorinated C₁-C₂₂-alkyl group, a linear or branched C₁-C₂₂-alkoxycarbonyl group, a cyano group, a nitro group, an amino group, an alkylamino, dialkylamino, arylamino, diaryl amino or alkylarylamino group or represent an alkyl- or arylcarbonyl group, alkyl denoting C₁-C₃₀-alkyl and aryl denoting C₅-C₂₀-aryl, and
Ar represents optionally substituted phenylene, biphenylene, naphthylene, thienylene and/or fluorenylene units.

In the phosphorescent conjugated polymers according to the invention, L¹ may be either a component of the conjugated main chain, directly covalently bonded to the main chain as one of the abovementioned side chains or may be covalently bonded to the main chain via a linker, referred to below as spacer, or may be a component of the terminal groups of the polymer.

In the phosphorescent conjugated polymers according to the invention, L¹ is preferably either a component of the conjugated main chain or a component of the terminal groups.

In preferred embodiments of the present invention, L¹ in the phosphorescent conjugated polymers according to the invention is a component of the terminal groups.

In the case of coordination to the metal centre, H can optionally be eliminated from the abovementioned ligand units L¹ at the corresponding coordination sites, so that L¹ in the phosphorescent conjugated polymers according to the invention then describes the abovementioned structure without these optionally eliminated H atoms. This may be the case from original hydroxyl groups, in particular with coordination via carbon coordination sites and oxygen coordination sites. The same applies to the ligands L² and L, which are first mentioned below.

The present invention particularly preferably relates to phosphorescent conjugated polymers which contain repeating units of the general formulae A and B-I or A and B-II or have a structure of the general formulae C or D 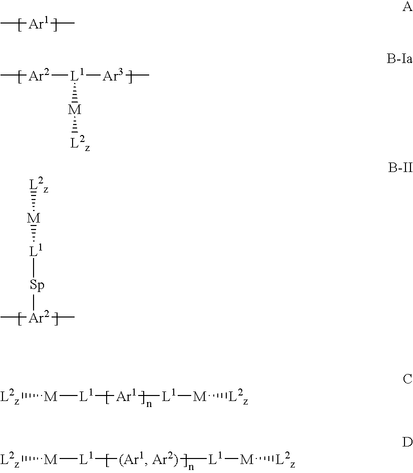
in which
Ar¹, Ar² and Ar³ are identical or different and, independently of one another, represent optionally C₁-C₃₀-alkyl-substituted C₅-C₂₀-aryl units and/or optionally C₁-C₃₀-alkyl-substituted heteroaryl units having 5 to 9 ring C atoms and 1 to 3 ring hetero atoms from the group consisting of nitrogen, oxygen and sulphur,
L¹ and L² are identical or different and
L¹ has one of the abovementioned meanings, in the case of structures B-II, C and D one of the two linkage positions—if a second is present—being saturated by H, F, CF₃, a linear or branched C₁-C₂₂-alkyl group, a linear or branched C₁-C₂₂-alkoxy group, an optionally C₁-C₃₀-alkyl-substituted C₅-C₂₀-aryl unit and/or an optionally C₁-C₃₀-alkyl-substituted heteroaryl unit having 5 to 9 ring C atoms and 1 to 3 ring hetero atoms from the group consisting of nitrogen, oxygen and sulphur and/or by a linear or branched, partly fluorinated or perfluorinated C₁-C₂₂-alkyl group, a linear or branched C₁-C₂₂-alkoxycarbonyl group, a cyano group, a nitro group, an amino group, an alkylamino, dialkylamino, arylamino, diarylamino or alkylarylamino group or by an alkyl- or arylcarbonyl group, alkyl denoting C₁-C₃₀-alkyl and aryl denoting C₅-C₂₀-aryl, and
L², independently of L¹, has one of the meanings mentioned above for L¹, the two linkage positions independently of one another—or the linkage position if no second linkage position is present—being saturated by H, F, CF₃, a linear or branched C₁-C₂₂-alkyl group, a linear or branched C₁-C₂-alkoxy group, an optionally C₁-C₃₀-alkyl-substituted C₅-C₂₀-aryl unit and/or an optionally C₁-C₃₀-alkyl-substituted heteroaryl unit having 5 to 9 ring C atoms and 1 to 3 ring hetero atoms from the group consisting of nitrogen, oxygen and sulphur and/or by a linear or branched, partly fluorinated or perfluorinated C₁-C₂₂-alkyl group, a linear or branched C₁-C₂₂-alkoxycarbonyl group, a cyano group, a nitro group, an amino group, an alkylamino, dialkylamino, arylamino, diarylamino or alkylarylamino group or by an alkyl- or arylcarbonyl group, alkyl denoting C₁-C₃₀-alkyl and aryl denoting C₅-C₂₀-aryl, and linkage positions being understood as meaning the positions marked with * in the formulae I to XXIX,
   the ligands L¹ and L² complex the metal M in a chelate-like manner,
M represents iridium(III), platinum(II), osmium(II), gallium(III) or rhodium(III),
n represents an integer from 3 to 10 000,
z represents an integer from 0 to 3 and
Sp is a spacer, in particular a linear or branched C₂-C₁₅-alkylene unit or a C₂-C₁₅-heteroalkylene unit having 1 to 3 chain hetero atoms from the group consisting of nitrogen, oxygen and sulphur, a C₅-C₂₀-arylene unit and/or a heteroarylene unit having 5 to 9 ring C atoms and 1 to 3 ring hetero atoms from the group consisting of nitrogen, oxygen and sulphur, or a C₁-C₁₂-alkylenecarboxylic acid unit or C₁-C₁₂-alkylenedicarboxylic acid unit or a C₁-C₁₂-alkylenecarboxamide unit or a C₁-C₁₂-alkylenedicarboxamide unit.

In the context of the invention, the general formula D is to be understood as meaning that Ar¹ and Ar² are different and form a copolymer chain which contains repeating units —Ar¹— and —Ar²— which are distributed alternately, in the form of blocks or randomly, it being possible for the copolymer chain to contain a percentage amount of from 0.1 to 99.9% of the repeating units —Ar¹— and a percentage amount of from 0.1 to 99.9% of the repeating units —Ar²—, with the proviso that the two amounts give 100% when summed. The total number of all repeating units —Ar¹— and —Ar¹— in the polymer is n.

Where Ar² and Ar³ in the repeating unit B-Ia are identical to Ar¹ in the repeating unit A, the phosphorescent conjugated polymer according to the invention, corresponding to the above formulation, contains repeating units of the general formulae A and B-Ib 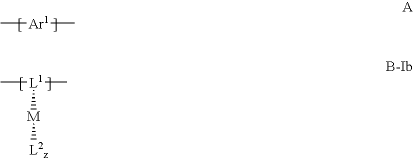
in which Ar¹, L¹, L², M and z have the abovementioned meaning.

For the purposes of the invention, the polymers according to the invention containing repeating units of the general formulae A and B-I, i.e. B-Ia and B-Ib, or B-II may also each contain a plurality of different units, in particular two different units, of the general formula A, i.e. a plurality of different units of the general formula A and units of the general formula B-I, i.e. B-Ia and B-Ib, or B-II.

The invention particularly preferably furthermore relates to phosphorescent conjugated polymers which contain repeating units of the general formulae A and B-Ia, A and B-Ib or A and B-II or have a structure of the general formulae C or D,

in which

Ar¹, Ar² and Ar³ are identical or different and, independently of one another, represent units selected from thiophene units of the formulae XXX and XXXI, benzene, biphenyl and fluorene units of the formulae XXXII to XIV and/or heterocycles of the formulae XXXV to XXXXIV and/or units of the formulae XXXXXV to XXXXXXII, 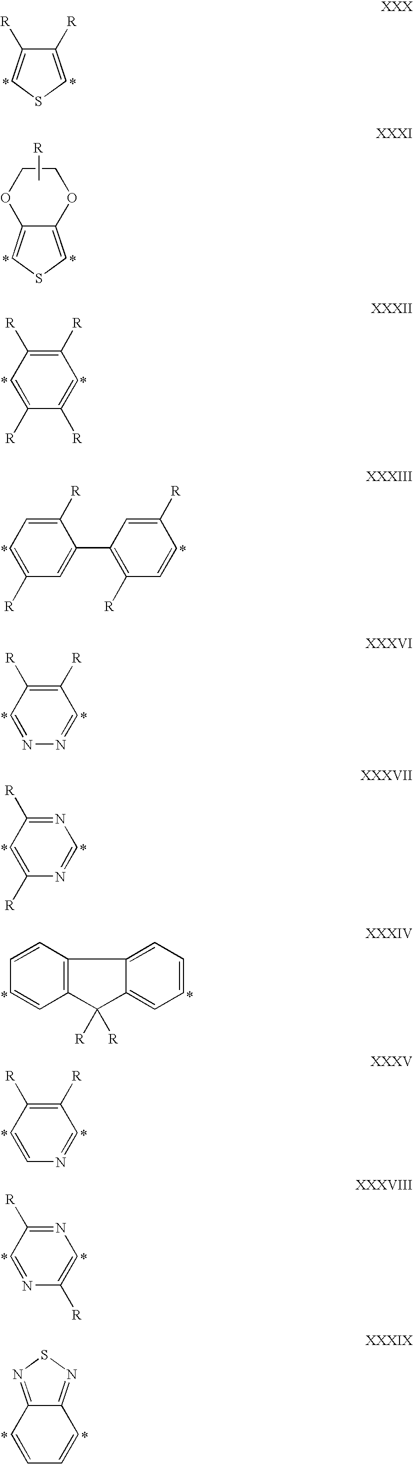 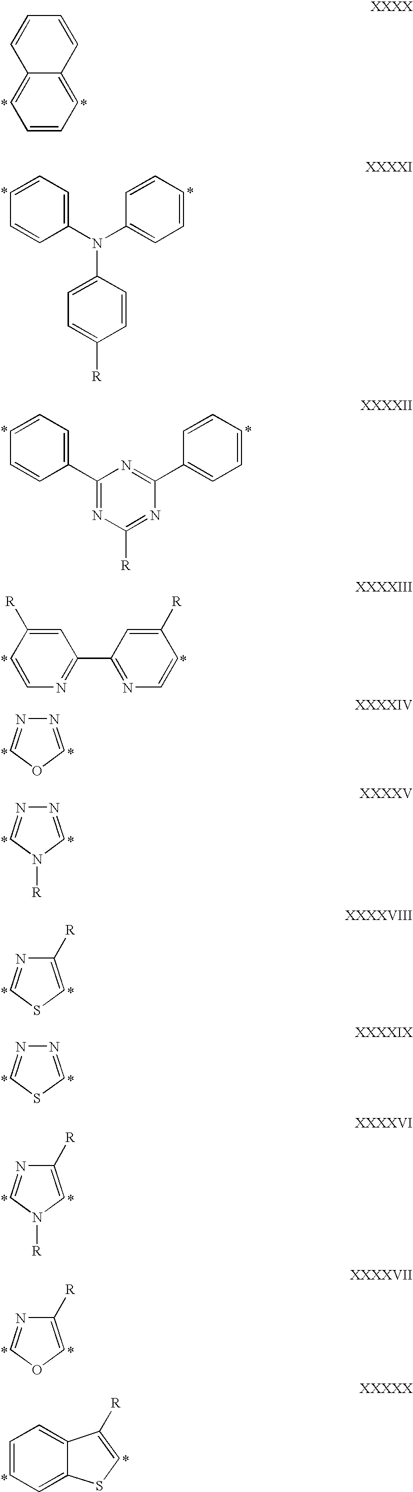 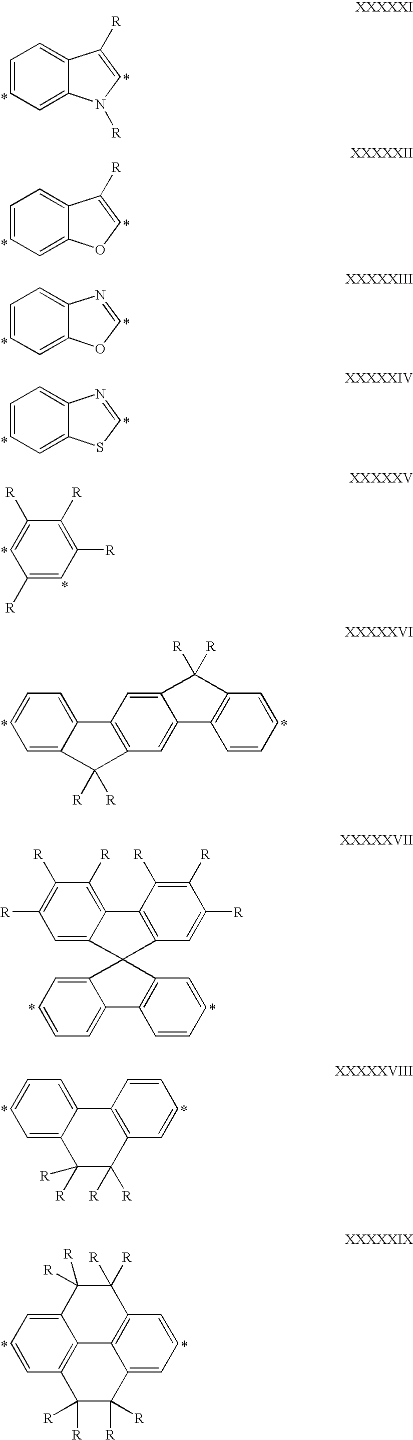 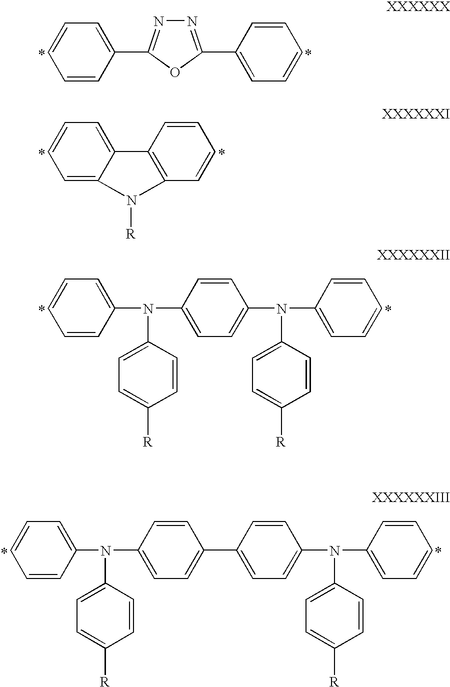
   in which
R are identical or different and, independently of one another, represent H, F, CF₃, a linear or branched C₁-C₂₂-alkyl group, a linear or branched C₁-C₂₂-alkoxy group, an optionally C₁-C₃₀-alkyl-substituted C₅-C₂₀-aryl unit and/or an optionally C₁-C₃₀-alkyl-substituted heteroaryl unit having 5 to 9 ring C atoms and 1 to 3 ring hetero atoms from the group consisting of nitrogen, oxygen and sulphur and/or represent a linear or branched, partly fluorinated or perfluorinated C₁-C₂₂-alkyl group, a linear or branched C₁-C₂₂-alkoxycarbonyl group, a cyano group, a nitro group, an amino group, an alkylamino, dialkylamino, arylamino, diarylamino or alkylarylamino group or represent an alkyl- or arylcarbonyl group, alkyl denoting C₁-C₃₀-alkyl and aryl denoting C₅-C₂₀-aryl, and
L¹ and L² are identical or different and have the abovementioned meanings and M, n, z and Sp have the abovementioned meanings.

These are particularly preferably phosphorescent conjugated polymers which contain repeating units of the general formulae A and B-Ia, A and B-Ib or A and B-II or have a structure of the general formulae C or D

in which

Ar¹, Ar² and Ar³ are identical or different and, independently of one another, represent units selected from thiophene units of the formulae XXX and XXXI, benzene, biphenyl and fluorene units of the formulae XXXII to XXXIV and/or units of the formulae XXXXXVI to XXXXXX 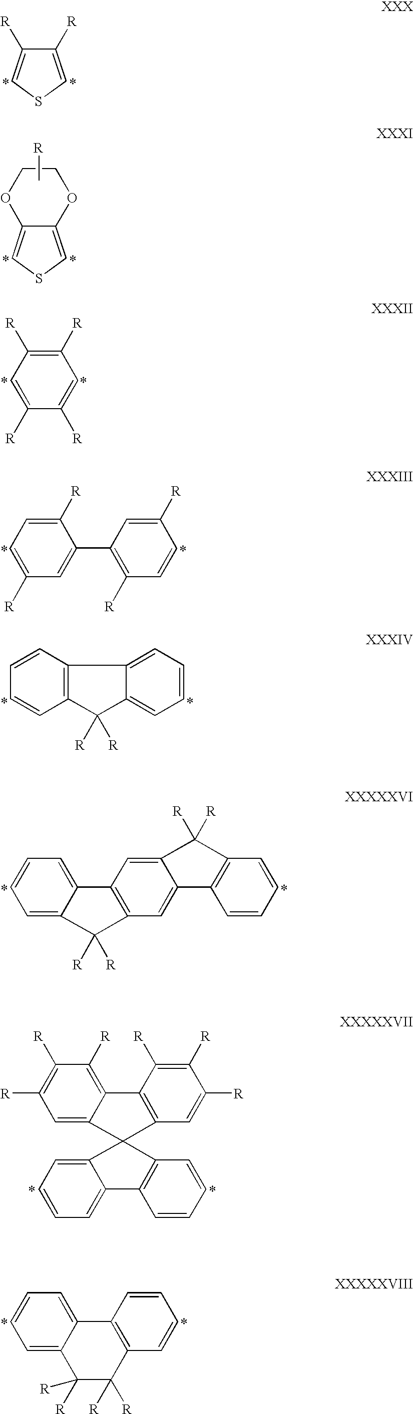 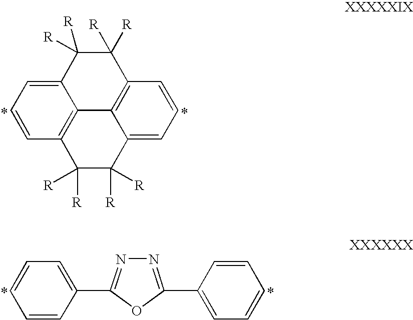
   L¹ and L² are units selected from the formulae I, II, VIII, XVIII, XX, XXI, XXIII, XXIV, XXVIIa, XXVIII, XXIX and XXIXa and 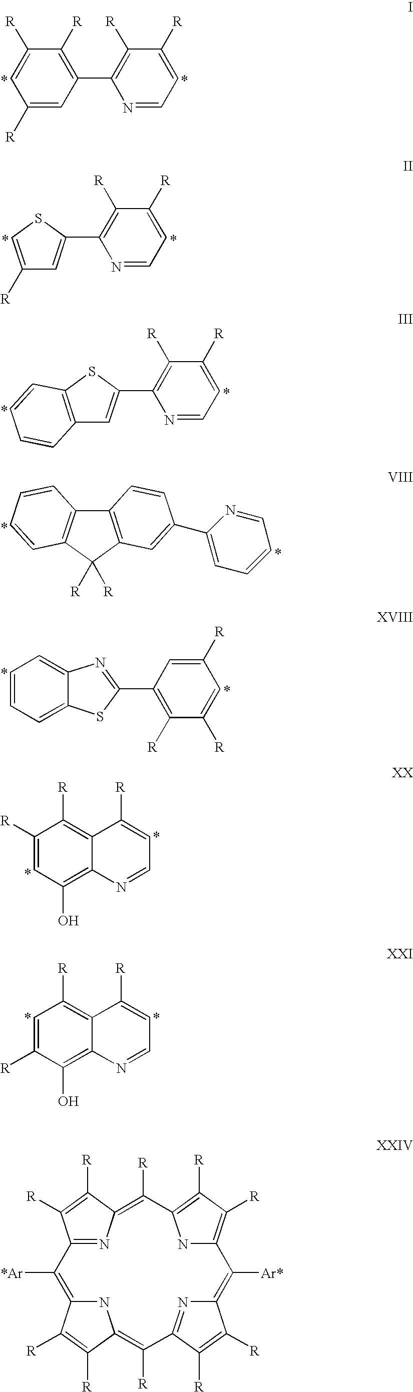 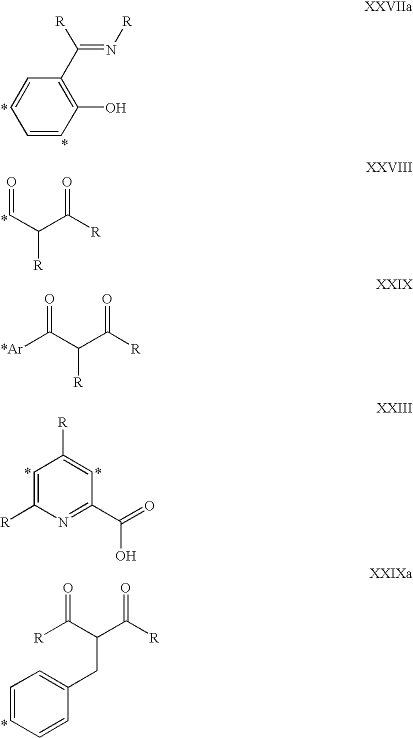
R has one of the abovementioned meanings,
M represents osmium(II), iridium(III), platinum(II) or rhodium(m),
n represents an integer from 5 to 500,
z represents an integer from 1 to 3 and
Sp represents a C₁-C₆-alkyleneoxy or a C₁-C₆-alkylenecarboxylic acid or a C—C₆-alkylene dicarboxylic acid.

These are very particularly preferably phosphorescent conjugated polymers which contain repeating units selected from the following general formulae A and B-I-1 to B-I-6 or A and B-II-1 to B-II-4 or have a structure of the general formulae C-1, C-2 or C-3 or D-1, D-2 or D-3 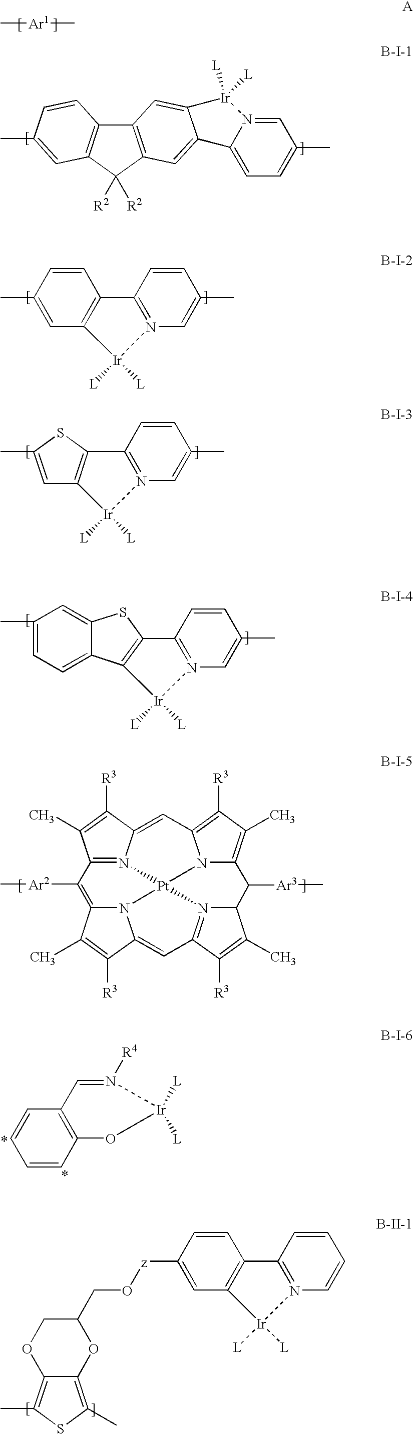 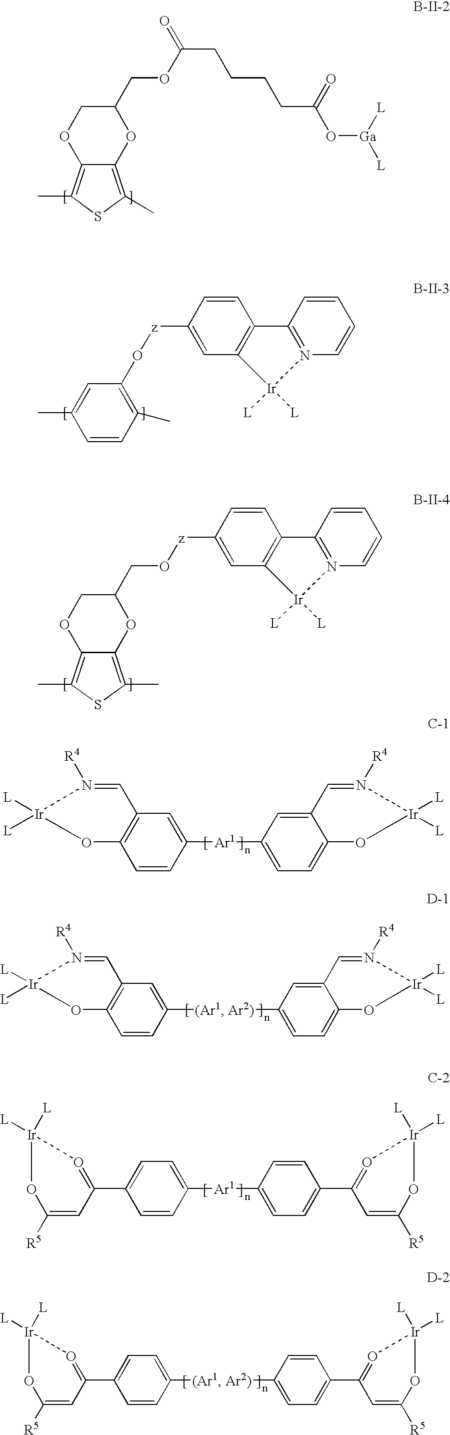 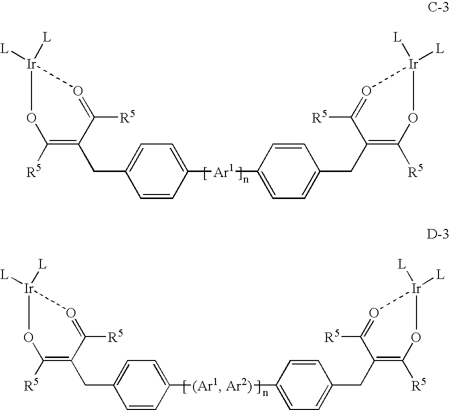
in which
Ar¹ represents units selected from 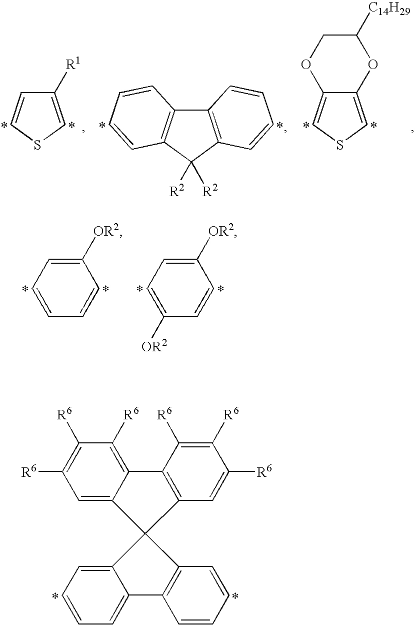
preferably represents units selected from 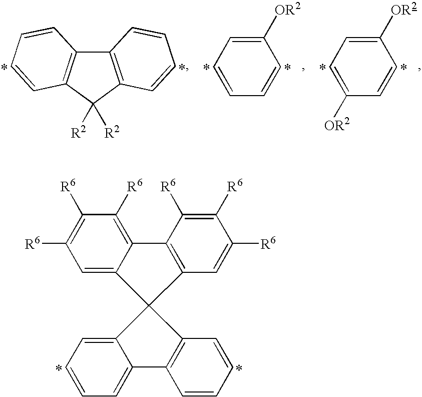
Ar² represents units selected from 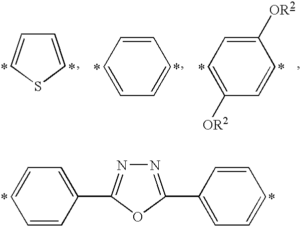
L represents ligands selected from 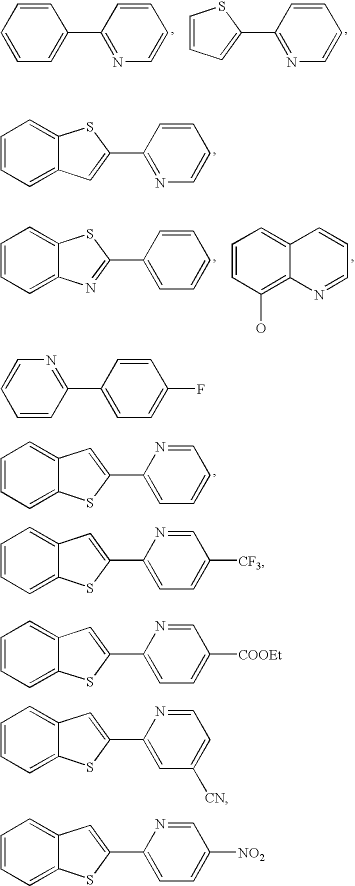
R¹ represents dodecyl,
R² represents n-octyl and 2-ethylhexyl,
R³ represents methyl and ethyl,
R⁴ represents methyl and n-hexyl,
R⁵ represents methyl and phenyl,
R⁶ represents H, a linear or branched C₁-C₂₂-alkyl group or a linear or branched C₁-C₂₂-alkoxy group,
z represents a CH₂ or C═O group and
n has the abovementioned meaning.

In preferred embodiments of the invention, L or L² represents in particular ligands selected from the following

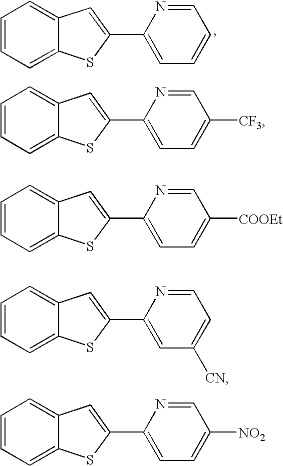

The resulting phosphorescent polymers according to the invention are particularly suitable as red emitters.

The sum of the number of repeating units A and B, B below representing the general formulae B-I (i.e. B-Ia or B-Ib) or B-II and representing the preferred general formulae B-I-1 to B-I-5 or B-I-6 or B-II-1 to B-II-4, is p, where p represents an integer from 3 to 10 000, preferably represents 5 to 500. The repeating units A and B may be distributed alternately, in the form of blocks or randomly in the polymer. The percentage amount of the repeating units A, based on the total number of repeating units in a polymer, may be from 0 to 99.9%, preferably from 75.0 to 99.9%; the percentage amount of the repeating units B, based on the total number of repeating units in a polymer, may be from 0.1 to 100%, preferably from 0.1 to 25%, with the proviso that the two percentage amounts give 100% when summed.

In the context of the invention, all radicals R in the abovementioned units L¹, L², Ar¹, Ar² or Ar³ may be identical or different in different units from among these units and may also be identical or different within one of these units.

The positions marked with * in all preceding and following general formulae, also referred to as linkage positions, are to be understood as meaning the positions via which linkage of the respective unit to further identical or different units can be effected.

At the terminal groups of the phosphorescent conjugated polymers according to the invention, preferably either phosphorescent metal complexes are bonded via a ligand L¹, such as, for example, in the case of phosphorescent polymers according to the invention which have structures of the general formulae C, C-1, C-2 or C-3 or D, D-1, D-2 or D-3, or the free linkage positions are preferably saturated by H or aryl, particularly preferably phenyl, for example in the case of phosphorescent polymers according to the invention which contain repeating units of the general formulae A and B.

In a preferred embodiment, the phosphorescent conjugated polymers according to the invention have an advantage over known phosphorescent polymers in that they have a defined composition, a defined composition in this context not being related to the chain length; the phosphorescent conjugated polymers according to the invention as well as the uncomplexed ligand polymers have a chain length distribution or molar mass distribution (M_{w}). This defined composition is the result of the specific preparation of uncomplexed ligand polymers which can be readily purified and unambiguously characterized and then complexed with corresponding transition metal precursor complexes.

Surprisingly, it has furthermore been found that phosphorescent conjugated polymers exhibit fluorescence in the conjugated main chain in addition to the phosphorescence of the covalently bonded phosphorescent metal complex or complexes emit white light and can be processed from solution.

Such phosphorescent polymers according to the invention are referred to below as luminescent polymers.

For a better overview, the numbering of the structures for the luminescent polymers according to the invention and for the components thereof is independent of that of the phosphorescent polymers according to the invention. Numberings for structures of the luminescent polymers according to the invention and for components thereof are in brackets and are therefore easily distinguishable from those for phosphorescent polymers according to the invention and components thereof.

The present invention therefore relates to luminescent polymers, characterized in that they have a conjugated main chain and contain at least one covalently bonded metal complex, the luminescence being a combination of the fluorescence of the conjugated main chain and of the phosphorescence of the covalently bonded metal complex or complexes.

In the context of the invention, conjugated means that the main chain of the polymers may be either completely conjugated or partly conjugated. A large conjugation length in the main chain is advantageous for good charge carrier transport, and polymers having such a conjugation length are preferred, in particular polymers having a completely conjugated main chain.

The luminescent polymers according to the invention are preferably straight-chain, which, in the context of the invention, means that they may contain in some cases only short side chains which serve for the covalent linkage of the phosphorescent metal complexes but are not growth sites of the polymer and therefore not branching points.

The luminescent polymers according to the invention exhibit electroluminrescence, i.e. luminesce—for example in the OLED—as a result of electrical excitation. However, they can also be caused to luminesce by optical excitation.

The luminescent polymers according to the invention preferably emit white light. In the context of the invention, white light is to be understood as meaning light which is defined by a colour location in the chromaticity diagram according to CIE 1931 (Commission Internationale de l'Eclairage), it being possible for the colour coordinate x to have values of from 0.20 to 0.46 and, independently of x, for the colour coordinate y to have values of from 0.20 to 0.46. This means that, in the context of the invention, white light is white or white-like light having a colour location, defined by the colour coordinates x=0.33±0.13 and y=0.33±0.13 in the chromaticity diagram according to CIE 1931, it being possible for x and y, independently of one another, to represent identical or different values of from 0.20 to 0.46. The value ranges stated for the colour coordinates are continuous value ranges. Particularly preferably, the luminescent polymers according to the invention emit white light which is defined by a colour location in the chromaticity diagram according to CIE 1931, it being possible for the colour coordinate x to have values of from 0.28 to 0.38 and, independently of x, for the colour coordinate y to have values of from 0.28 to 0.38.

In the context of the invention, the emitted light is a combination of the fluorescence of the conjugated main chain and of the phosphorescence of the covalently bonded metal complex or complexes, the emitted light of which, considered individually in each case, may differ in colour from white and this is also preferred. It is only the additive colour mixing, for example of emitted light of the primary colours red, green and blue or of a mixture of complementary colours that enables the emitted light to appear white as a whole.

The invention preferably relates to luminescent polymers in which the metal complex or complexes, which may be identical or different, are covalently bonded to the chain ends of the conjugated main chain.

These are particularly preferably luminescent polymers which have a structure of the general formula (Ia) or (Ib) 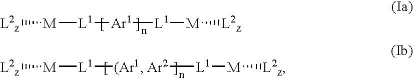
in which
Ar¹ represents units selected from optionally substituted phenylene units (IIa) or (IIb), biphenylene units (IIc), fluorenylene units (IId), dihydroindenofluorenylene units (IIe), spirobifluorenylene units (IIf), dihydrophenanthrylene units (IIg) or tetrahydropyrenylene units (IIh) 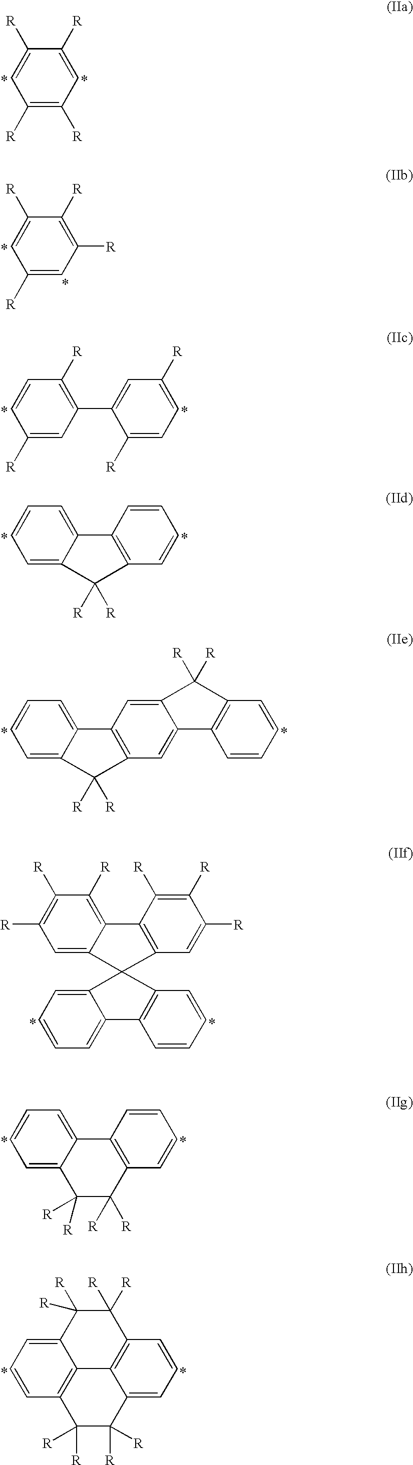
Ar² differs from Ar¹ and represents units selected from (IIa) to (IIq) 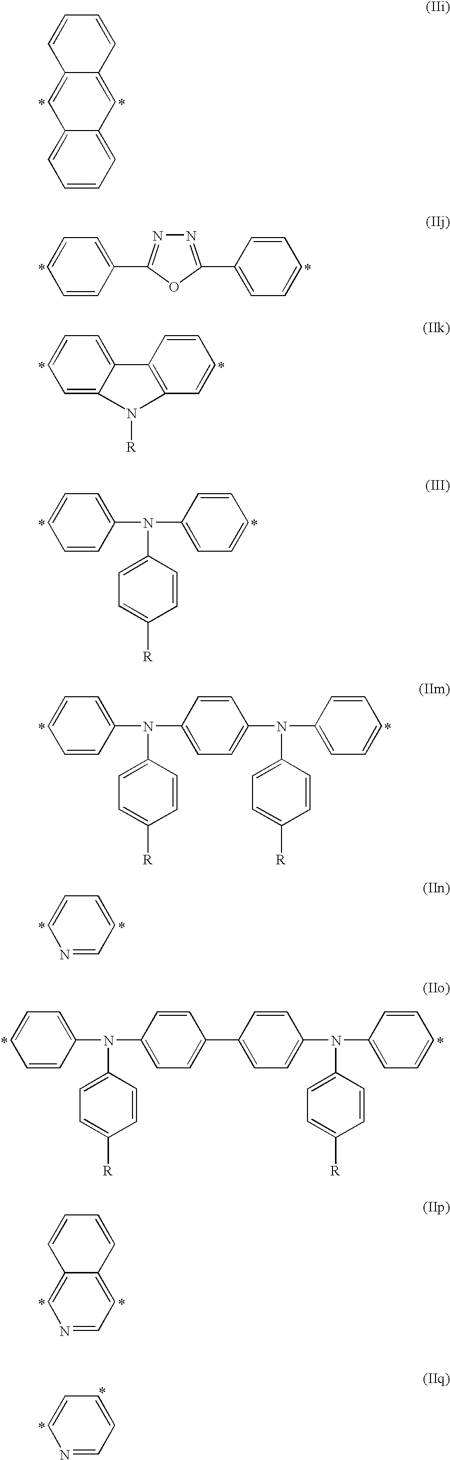
L¹ and L² in each case are identical or different and
L¹ is a ligand of the formulae (IIIa-1) to (IIId-1) 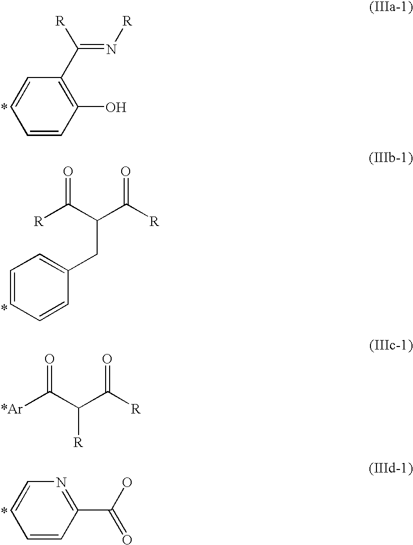
   in which
Ar represents units selected from optionally substituted phenylene, biphenylene, naphthylene, thienylene or fluorenylene units,
L², independently of L¹, is a ligand selected from units of the formulae (IVa-1) to (IVy-1) 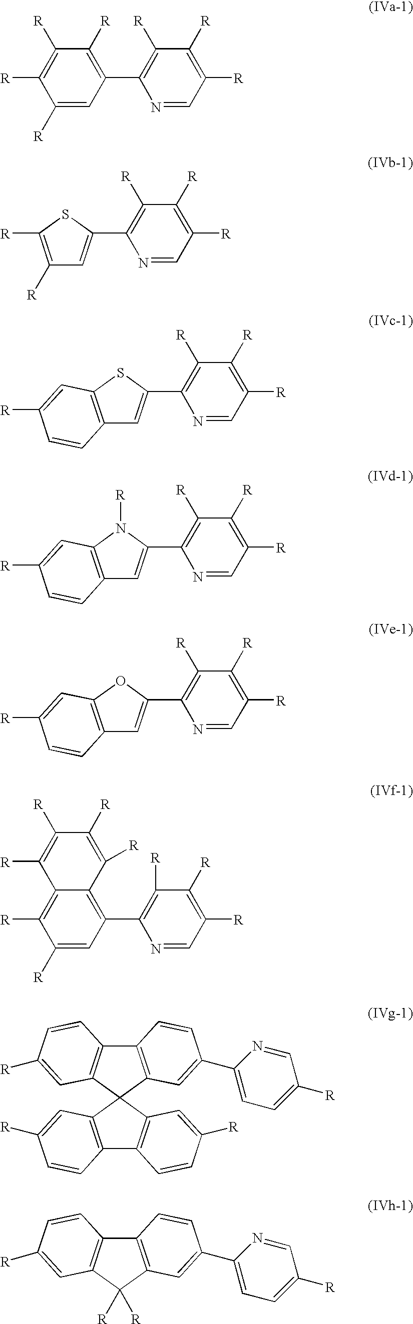 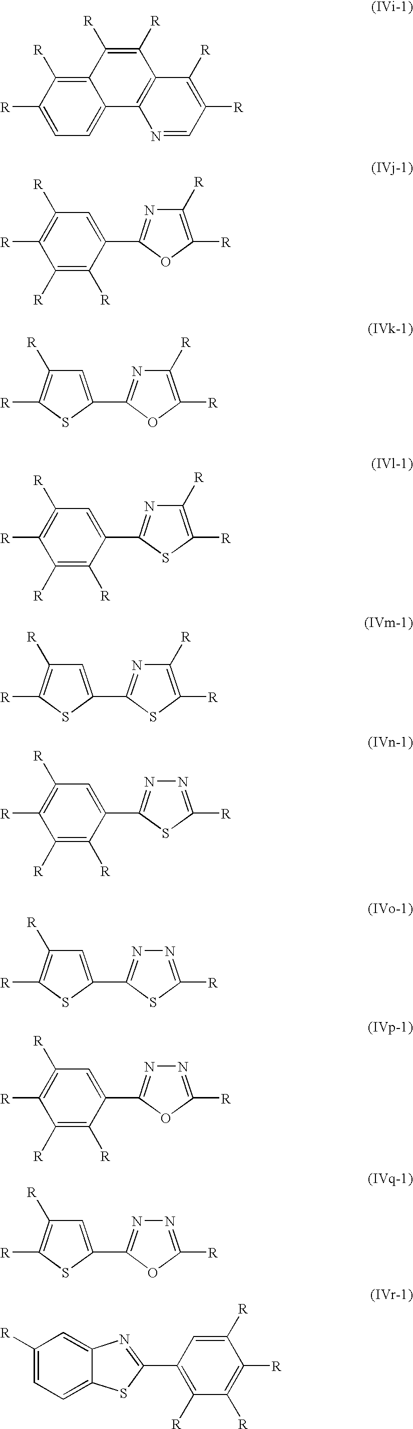 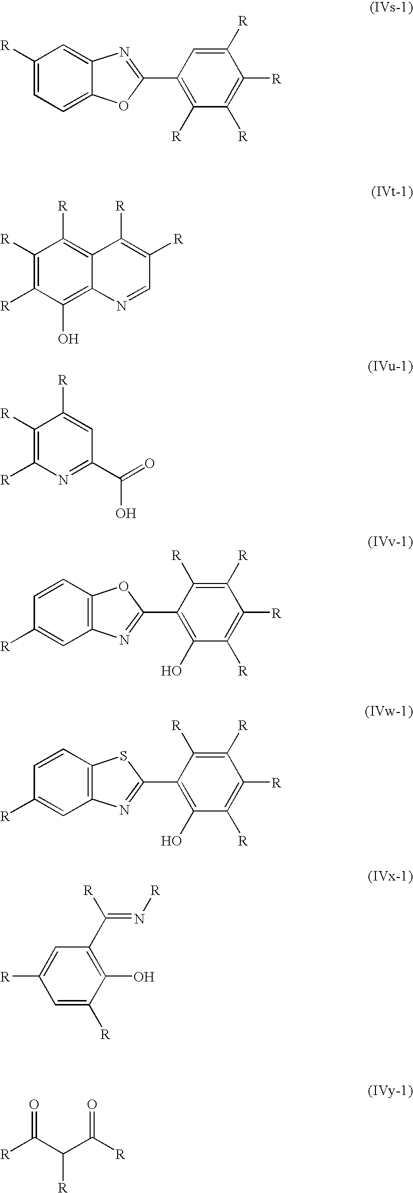
   the ligands L¹ and L² complex the metal M in a chelate-like manner,
M represents iridium(III), platinum(II), osmium(II) or rhodium(III),
n represents an integer from 3 to 10 000, preferably from 10 to 5 000, particularly preferably from 20 to 1000, very particularly preferably from 40 to 500,
z is an integer from 1 to 3 and
R are identical or different radicals and, independently of one another, represent H, F, CF₃, a linear or branched C₁-C₂₂-alkyl group, a linear or branched partly fluorinated or perfluorinated C₁-C₂₂-alkyl group, a linear or branched C₁-C₂₂-alkoxy group, an optionally C₁-C₃₀-alkyl-substituted C₅-C₂₀-aryl unit and/or an optionally C₁-C₃₀-alkyl-substituted heteroaryl unit having 5 to 9 ring C atoms and 1 to 3 ring hetero atoms from the group consisting of nitrogen, oxygen and sulphur and/or represent a linear or branched, partly fluorinated or perfluorinated C₁-C₂₂-alkyl group, a linear or branched C₁-C₂₂-alkoxycarbonyl group, a cyano group, a nitro group, an amino group, an alkylamino, dialkylamino, arylamino, diarylamino or alkylarylamino group or represents an alkyl- or arylcarbonyl group, alkyl denoting C₁-C₃₀-alkyl and aryl denoting C₅-C₂₀-aryl.

In the general formulae (Ia) and (Ib) and below, n is to be understood as meaning the average number of repeating units, since the luminescent polymers preferably have a molar mass distribution.

In the case of coordination to the metal centre, H can optionally be eliminated from the abovementioned ligand units L¹ or L² at the corresponding coordination sites, so that L¹ in the phosphorescent conjugated polymers according to the invention then describes the abovementioned structure without these optionally eliminated H atoms. This may be the case from original hydroxyl groups in particular with coordination via carbon coordination sites and oxygen coordination sites.

These are very particularly preferably luminescent polymers which have a structure of the general formulae (Ia-1), (Ia-2), (Ib-1), (Ib-2), (Ia-3) or (Ib-3) (Ia-1) 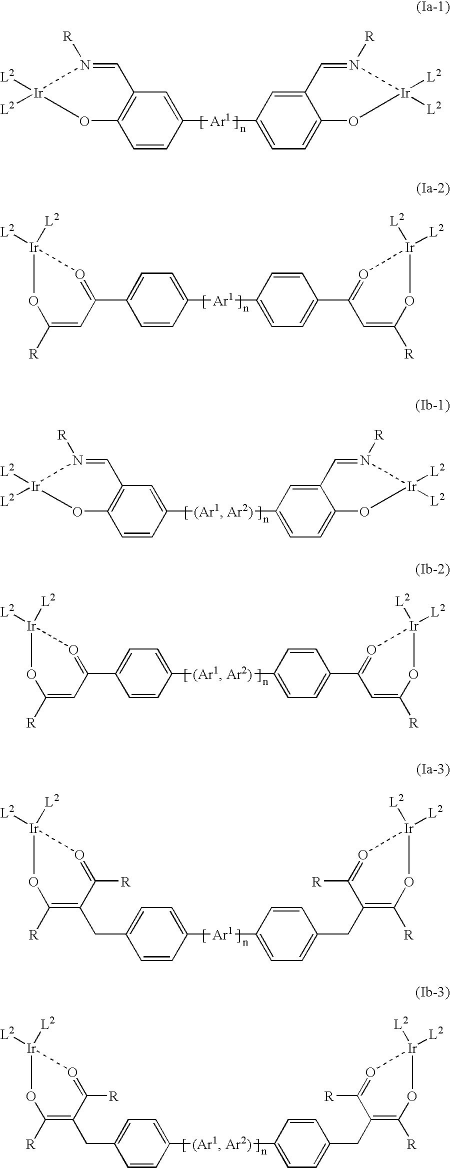
in which
R represents a linear or branched C₁-C₂₂-alkyl group or a linear or branched partly fluorinated or perfluorinated C₁-C₂₂-alkyl group and
   n, Ar¹, Ar² and L² have the abovementioned meaning.

In the context of the invention, the general formulae (Ib-1), (Ib-2) and (Ib-3) are to be understood as meaning that Ar¹ and Ar² are different and form a copolymer chain which contains repeating units —Ar¹— and —Ar²— distributed alternately, in block form or randomly, it being possible for the copolymer chain to contain a percentage amount of from 0.1 to 99.9% of the repeating unit —Ar¹— and a percentage amount of from 0.1 to 99.9% of the repeating unit —Ar²—, with the proviso that the two amounts give 100% when summed. The total number of all repeating units —Ar¹— and —Ar²—in the polymer is n.

The present invention also preferably relates to luminescent polymers in which the metal complex or complexes, which may be identical or different, are covalently bonded to the conjugated main chain.

These are particularly preferably luminescent polymers which contain n repeating units of the general formulae (Ic-1) and (Id) or (Ic-1), (Ic-2) and (Id) 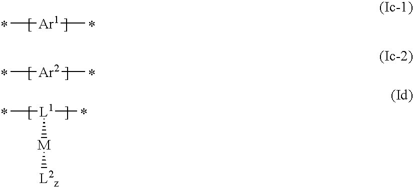
in which
Ar¹ represents units selected from optionally substituted phenylene units (IIa) or (IIb), biphenylene units (IIc), fluorenylene units (IId), dihydroindenofluorenylene units (IIe), spirobifluorenylene units (IIf), dihydrophenanthrylene units (IIg) or tetrahydropyrenylene units (IIh) 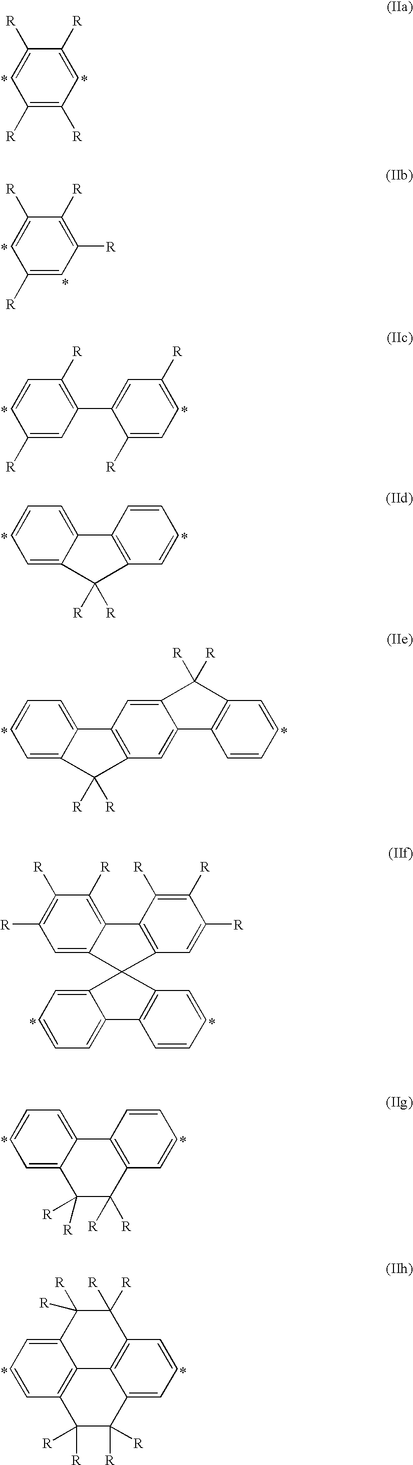
Ar² differs from Ar¹ and represents units selected from (IIa) to (IIq) 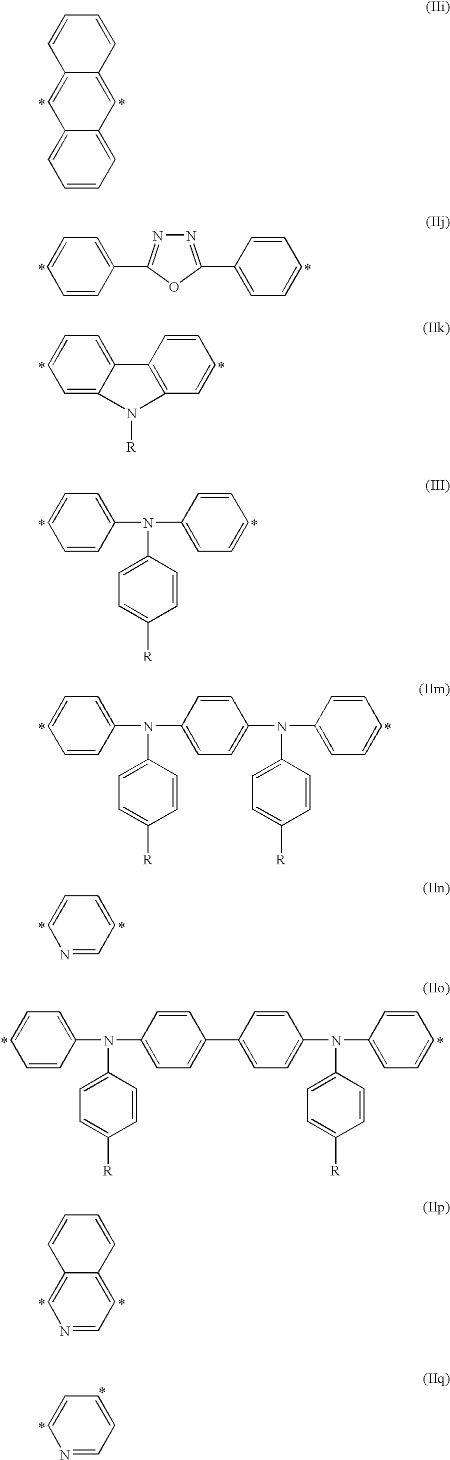
L¹ and L² in each case are identical or different and
L¹ is a ligand of the formulae (IIIa-2) to (IIIi-1) 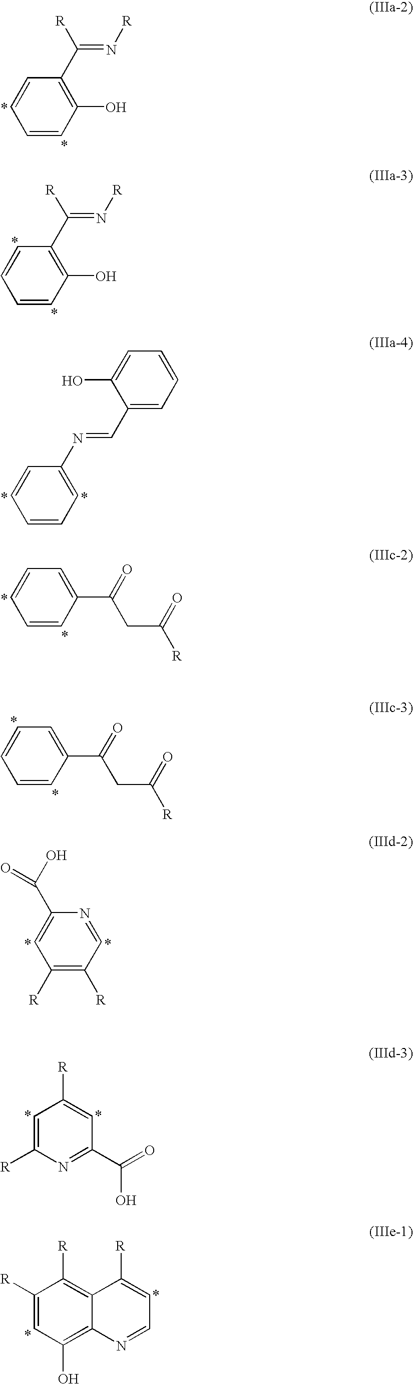 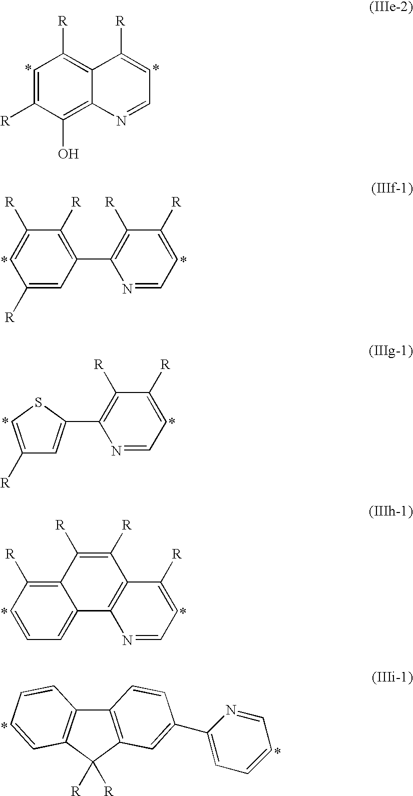
L², independently of L¹, is a ligand selected from units of the formulae (IVa-1) to (Ivy-1) 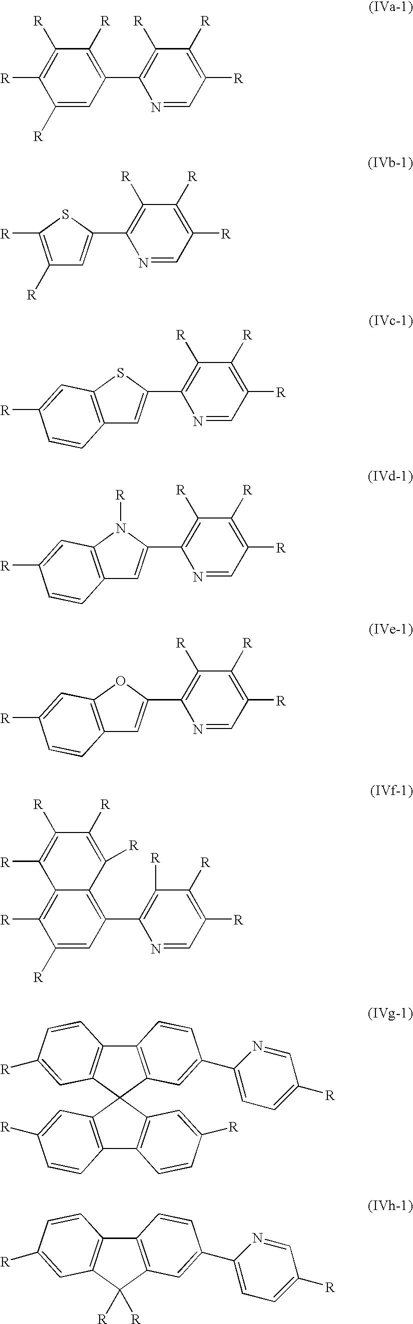 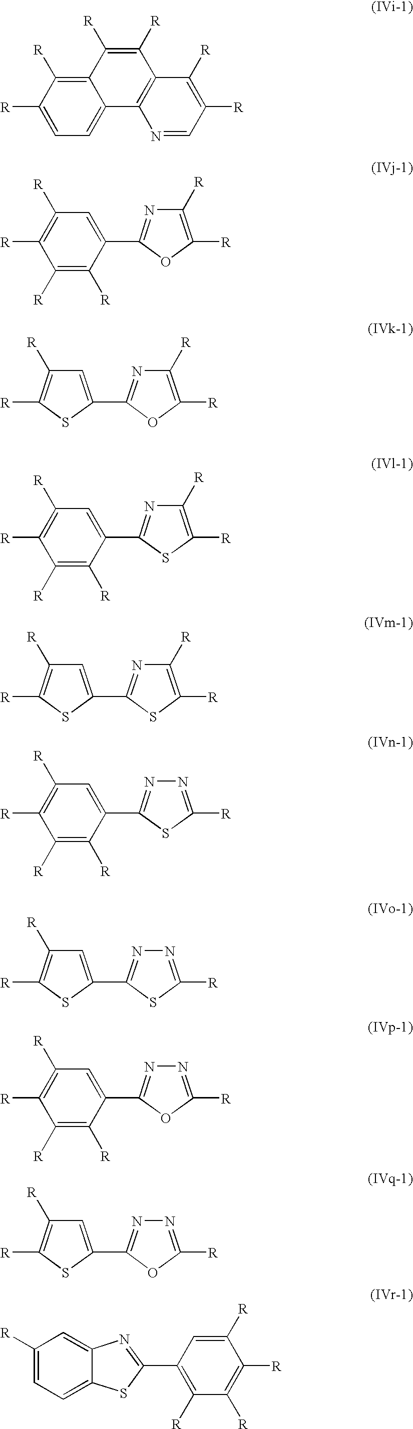 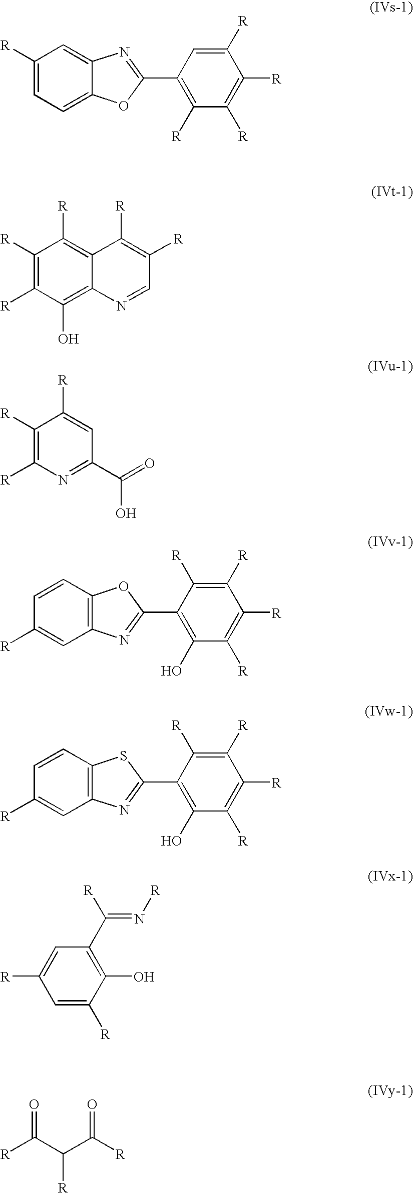
   the ligands L¹ and L² complex the metal M in a chelate-like manner,
M represents iridium(III), platinum(II), osmium(II) or rhodium(III),
n is an integer from 3 to 10 000, preferably from 10 to 5 000, particularly preferably from 20 to 1000, very particularly preferably from 40 to 500,
z represents an integer from 1 to 3 and
R are identical or different radicals and, independently of one another, represent H, F, CF₃, a linear or branched C₁-C₂₂-alkyl group, a linear or branched partly fluorinated or perfluorinated C₁-C₂₂-alkyl group, a linear or branched C₁-C₂₂-alkoxy group, an optionally C₁-C₃₀-alkyl-substituted C₅-C₂₀-aryl unit and/or an optionally C₁-C₃₀-alkyl-substituted heteroaryl unit having 5 to 9 ring C atoms and 1 to 3 ring hetero atoms from the group consisting of nitrogen, oxygen and sulphur and/or represent a linear or branched, partly fluorinated or perfluorinated C₁-C₂₂-alkyl group, a linear or branched C₁-C₂₂-alkoxycarbonyl group, a cyano group, a nitro group, an amino group, an alkylamino, dialkylamino, arylamino, diarylamino or alkylarylamino group or represent an alkyl- or arylcarbonyl group, alkyl denoting C₁-C₃₀-alkyl and aryl denoting C₅-C₂₀ aryl.

These are very particularly preferably luminescent polymers which contain n repeating units of the general formulae (Ic-1) and (Id-1) 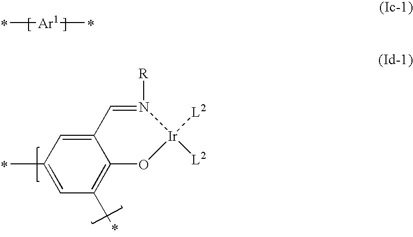
in which
R represents a linear or branched C₁-C₂₂-alkyl group or a linear or branched partly fluorinated or perfluorinated C₁-C₂₂-alkyl group and
n, Ar¹ and L² have the abovementioned meaning.

The sum of the number of repeating units (Ic) and (Id), where (Ic) below represents the general formulae (Ic-1) or (Ic-1) and (Ic-2) and (Id) represents the general formulae (Id) or (Id-1), is n, n representing an integer from 3 to 10 000, preferably from 10 to 5 000, particularly preferably from 20 to 1000, very particularly preferably from 40 to 500, and, in the context of the invention, n always being understood as meaning the average number of repeating units, since the luminescent polymers according to the invention can preferably have a molar mass distribution.

The repeating units (Ic) and (Id) may be distributed alternately, in block form or randomly in the polymer. The percentage amount of the repeating units (Ic), based on the total number of repeating units in a polymer, may be from 0.1 to 99.9%, preferably from 75.0 to 99.9%; the percentage amount of the repeating units (Id), based on the total number of repeating units in a polymer, may be from 0.1 to 100%, preferably from 0.1 to 25%, with the proviso that the two percentage amounts give 100% when summed. In preferred embodiments, the percentage amount of the repeating units (Id), based on the total number of repeating units in a polymer, may be from 0.01 to 15%, preferably from 0.01 to 10%, particularly preferably from 0.01 to 5%; the percentage amount of the repeating units (Ic), based on the total number of repeating units in these preferred embodiments of the luminescent polymers according to the invention can accordingly be from 85 to 99.99%, preferably from 90 to 99.99%, particularly preferably from 95 to 99.99%, likewise with the proviso that the two percentage amounts give 100% when summed. The preceding percentage data are data based on the amount of substance (mol %).

In preferred embodiments of the luminescent polymers according to the invention, L² represents ligands selected from units of the formulae

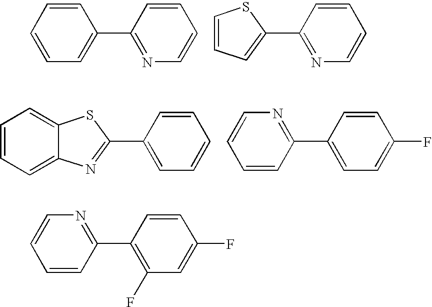

The luminescent polymers of these preferred embodiments can optionally also contain those ligands selected from units of the formulae 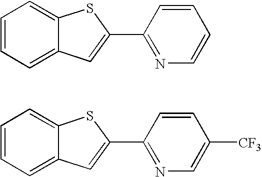
in addition to the abovementioned units for L².

Further preferred embodiments of the present invention are those luminescent polymers according to the invention in which Ar¹ and Ar², independently of one another, represent units of the formulae 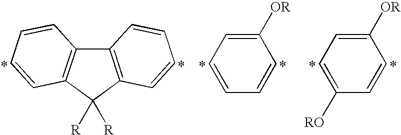
in which
R represents a linear or branched C₁-C₂₂-alkyl group.

In the context of the invention, all radicals R in the abovementioned units L¹, L², Ar¹, Ar² or Ar¹ may be identical or different in different units from among these units and may also be identical or different within one of these units.

The positions marked with * in all preceding and following general formulae, also referred to as linkage positions, are to be understood as meaning the positions via which a linkage of the respective unit to further identical or different units can take place.

At the terminal groups (terminal linkage positions) of the luminescent polymers according to the invention, preferably either phosphorescent metal complexes are bonded via a ligand L¹, such as, for example, in the case of luminescent polymers according to the invention which have structures of the general formulae (Ia) or (Ib) or (Ia-1), (Ia-2), (Ia-3), (Ib-1), (Ib-2) or (Ib-3), or the free linkage positions are preferably saturated by H or aryl, particularly preferably phenyl, for example in the case of luminescent polymers according to the invention which contain repeating units of the general formulae (Ic) and (Id).

Luminescent polymers according to the invention are obtained when the conjugated polymer main chain and the covalently bonded phosphorescent metal complex or complexes are chosen so that the excitation energy is not completely transferred to the phosphorescent metal complex or complexes or does not remain there, i.e. if a part of the excitation energy remains on the conjugated polymer main chain and—in addition to the phosphorescence of the metal complex or complexes—leads to fluorescence of the conjugated main chain.

This may be explained by way of example for polymers according to the invention whose conjugated main chain contains fluorenyl repeating units. If, for example, such a conjugated polyfluorene main chain is combined with iridium complexes having yellow or green phosphorescence, then energy transfer from the polyfluorene main chain to the iridium complex or complexes takes place only incompletely. A part of the excitation energy is converted into blue fluorescence of the polyfluorene main chain and another part into phosphorescence of the iridium complex or complexes.

On the other hand, the combination of polyfluorene main chains with iridium complexes having red phosphorescence leads exclusively to red phosphorescence of the iridium complex or complexes, since in this case the excitation energy is efficiently transferred from the polyfluorene main chain to the iridium complex or complexes.

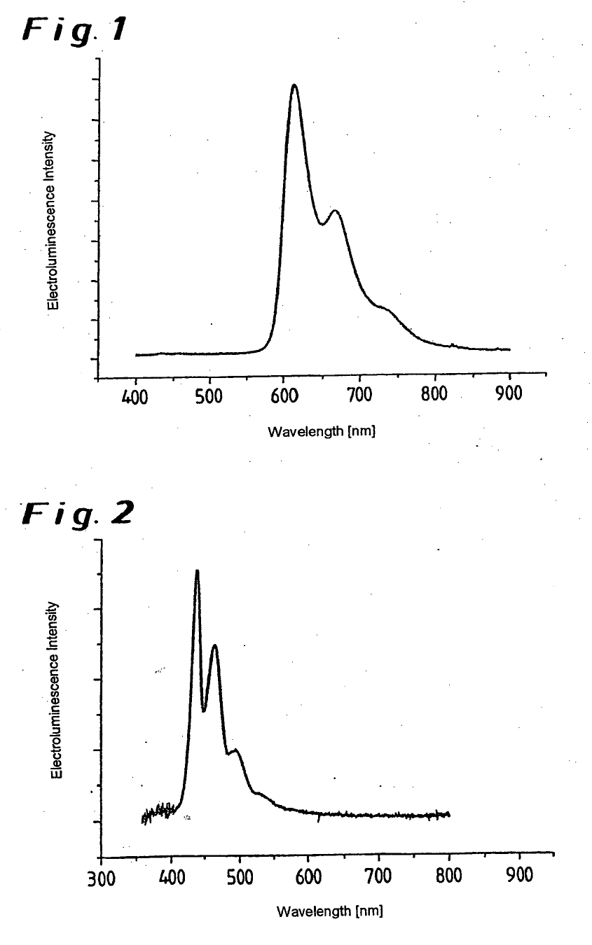

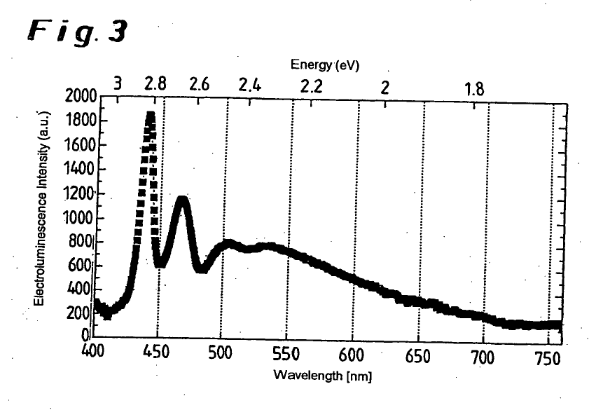

The phosphorescent or luminescent polymers according to the invention can be distinguished on the basis of their emission spectra (e.g. electroluminescence spectra). The emission spectra of the phosphorescent polymers according to the invention are typical phosphorescence spectra and have phosphorescence bands but no fluorescence bands. On the other hand, the emission spectra of the luminescent polymers according to the invention also have fluorescence bands in addition to the phosphorescence bands. FIG. 1 shows a typical electroluminescence spectrum of a phosphorescent polymer according to the invention, and FIG. 3 shows that of a luminescent polymer according to the invention, in which the superposition of the blue polyfluorene fluorescence with the yellow-green iridium phosphorescence is clearly evident. On the other hand, FIG. 2 shows, for comparison, an electroluminescence spectrum which exhibits only fluorescence bands of the polyfluorene.

The phosphorescent or luminescent polymers according to the invention exhibit electroluminescence, i.e. luminesce—for example in the OLED—through electrical excitation. However, they can also be caused to luminesce by optical excitation, i.e. by light. However, the electroluminescence spectrum of a phosphorescent or luminescent polymer according to the invention may differ from its photoluminescence spectrum and consequently the colour of the emitted light may also differ according to excitation (electrical or optical).

The invention furthermore relates to a process for the preparation of the phosphorescent or luminescent polymers according to the invention, uncomplexed ligand polymers being complexed with iridium(III), platinum(II), osmium(II) or rhodium(III) precursor complexes, preferably iridium(III) precursor complexes, in particular those of the general formula E
(L²)₂Ir(μ-Cl)₂Ir(L²)₂ E
in which L² has the abovementioned meaning.

Activation of the iridium precursor complexes of the general formula E may be necessary beforehand and is effected, for example, by stirring with silver(I) salts, in particular silver(I) trifluoromethanesulphonate, in organic solvents or solvent mixtures, for example dichloromethane and/or acetonitrile. Such an activation is required, for example, when the ligand L² complexes the transition metal in a chelate-like manner both via carbon coordinate sites and via nitrogen coordination sites.

Uncomplexed ligand polymers are all polymers containing repeating units of the general formula A or (Ic) and/or F 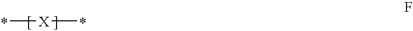
in which X may have the abovementioned meaning of Ar¹, Ar², Ar³ or the abovementioned meaning of L¹ (according to the definition for the general formula B-Ia, B-Ib or (Id)) or combinations thereof and the sum of the number of repeating units A or (Ic) and/or F is equal to n or p, n and p having the abovementioned meaning. The uncomplexed ligand polymers may be functionalized at the chain ends in each case with a ligand L¹ according to the definition for the general formulae C or D or (Ia) or (Ib) or saturated by H or aryl.

This process furthermore has the advantage of varying the transition metal content, in particular iridium content, in the polymer in a simple manner through the choice of the stoichiometric ratio of ligand polymer to transition metal precursor complex, in particular iridium precursor complex.

The syntheses of the iridium precursor complexes are described in the literature, e.g. S. Sprouse, K. A. King, P. J. Spellane, R. J. Watts, J. Am. Chem. Soc. 1984, 106, 6647-6653, or WO 01/41512 A1. The syntheses of the ligand polymers can be effected analogously to the examples described in the literature, e.g. T. Yamamoto et al., J. Am. Chem. Soc. 1996, 118, 10389-10399, T. Yamamoto et al., Macromolecules 1992, 25, 1214-1223, and R. D. Miller, Macromolecules 1998, 31, 1099-1103.

The phosphorescent conjugated polymers according to the invention have the advantage over low molecular weight phosphorescent metal complexes that they are accessible to application from solution, can be applied in one step without additional doping or blending and at the same time have long lives and high external quantum efficiencies in EL arrangements.

The luminescent polymers according to the invention are likewise accessible to application from solution and, compared with mixtures of polymers and low molecular weight dopants or mixtures of emitter materials of different colours, have the advantage that they can be applied in one step without additional doping or blending.

The phosphorescent or luminescent polymers according to the invention furthermore have the advantage that polymer and phosphorescent metal complex cannot separate and the metal complex therefore cannot crystallize. Such separation and crystallization processes have recently been described for blend systems consisting of polymer and admixed low molecular weight iridium complexes (Noh et al., Journal of Chemical Physics 2003, 118(6), 2853-2864).

Surprisingly, it has been found that the luminescent polymers according to the invention are suitable as white one-component emitter materials. The white emitters according to the invention are characterized in that they have fluorescence and phosphorescence components in different spectral ranges. They have the advantage of emitting even at low operating and switch-on voltages and exhibit good current-voltage-brightness characteristics and produce white light with high efficiency even in the two-layer diode structure (hole injection layer and emitter layer).

The phosphorescent or luminescent polymers according to the invention are therefore particularly suitable for use as emitter materials in light-emitting components, for example organic or polymeric LEDs, laser diodes, in indicators or displays (TV, computer monitor), for the backlighting of LCDs and watches, as illumination elements, in flat panel light sources, as billboards and information signs, in mobile communication devices, in displays for household appliances, (e.g. washing machine, refrigerator, vacuum cleaner, etc.), for interior illumination and illumination of dashboards in the automotive sector or as integrated displays in displacement systems, etc.

The luminescent polymers according to the invention are suitable in particular for use as white emitter materials in light-emitting components, such as white organic light emitting diodes, e.g. as economical backlighting of liquid crystal displays, as planar illumination sources or for the production of full-colour displays by combination with colour filters.

The use of the phosphorescent or luminescent polymers according to the invention as emitters in light-emitting components is therefore also according to the invention.

Compared with low molecular weight emitter materials, they have in this respect the advantage that extinction processes which lead to a reduction in the external quantum efficiency are avoided. These occur to a greater extent with increasing iridium concentration (local accumulation) in the case of low molecular weight emitters, owing to migration processes. In the phosphorescent or luminescent polymers according to the invention, the iridium complexes are no longer accessible to migration processes owing to the covalent linkage to the polymer.

The white emitters according to the invention furthermore have the advantage that, being one-component emitters, they do not exhibit the disadvantages of the energy transfer processes and of “differential ageing” (fading of individual emitters to different extents and at different rates) described at the outset, and a shift in colour location away from the white point, also referred to as achromatic point, with relatively long operating time is therefore not to be expected. Furthermore, the white emitters according to the invention do not exhibit any visually perceptible dependence of the colour location of the emitted light on the applied voltage.

In order to establish or to optimize a specific colour location, different polymers according to the invention can be blended, for example phosphorescent polymers according to the invention with further phosphorescent polymers according to the invention and/or with luminescent polymers according to the invention. If, for example, white light is produced in the complementary colours blue and yellow, the light appears white but the red spectral components are absent, so that the colour reproduction of objects illuminated by this light can be falsified. The admixing of red-emitting polymers according to the invention may be advantageous in such cases. Furthermore, red spectral components are absolutely essential when red light is to be produced with the aid of colour filters, since red colour filters filter out all spectral components apart from the red.

The present invention therefore furthermore relates to blends comprising one or more phosphorescent polymer(s) according to the invention and one or more luminescent polymer(s) according to the invention and the use of these blends as emitters in light-emitting components.

Instead of using blends of phosphorescent and luminescent polymers according to the invention, these can also be applied in succession in various layers in order to achieve the corresponding colour location setting or colour location optimization.

The present invention furthermore relates to electroluminescent arrangements which contain at least one phosphorescent or luminescent polymer according to the invention. The phosphorescent or luminescent polymer according to the invention serves as light-emitting material.

The use of the phosphorescent or luminescent polymers according to the invention as light-emitting material has the advantage over known low molecular weight light-emitting materials that additional components, such as, for example, binders, matrix materials or charge transport compounds, are not absolutely essential in the light-emitting layer, but these additional components may nevertheless be present.

The present invention also relates to electroluminescent arrangements which contain blends of one or more phosphorescent polymers according to the invention and one or more luminescent polymers according to the invention.

The present invention preferably relates to electroluminescent arrangements which additionally contain a hole-injecting layer.

These are particularly preferably electroluminescent arrangements in which the hole-injecting layer consists of a neutral or cationic polythiophene of the general formula G 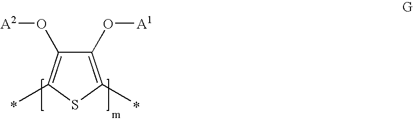
in which
A¹ and A², independently of one another, represent hydrogen, optionally substituted C₁-C₂₀-alkyl, CH₂OH or C₆-C₁₄-aryl or together denote optionally substituted C₁-C₁₃-alkylene or C₆-C₁₄-arylene, preferably C₂-C₄-alkylene, particularly preferably ethylene, and
m represents an integer from 2 to 10 000, preferably from 5 to 5 000.

Polythiophenes of the general formula G are described in EP-A 0 440 957 and EP-A 0 339 340.

A description of the preparation of the dispersions or solutions used can be found in EP-A 0 440 957 and DE-A 42 11 459.

The polythiophenes are used in the dispersion or solution preferably in cationic form, as obtained, for example, by treatment of neutral thiophenes with oxidizing agents. Customary oxidizing agents, such as potassium peroxodisulphate, are used for the oxidation. As a result of the oxidation, the polythiophenes acquire positive charges, which are not shown in the formulae since their number and their position cannot be satisfactorily determined. According to the information in EP-A 0 339 340, they can be prepared directly on carriers.

Preferred cationic or neutral polythiophenes are composed of structural units of the formula G-a 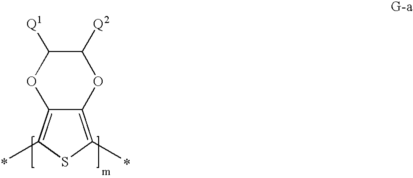
in which
Q¹ and Q², independently of one another, represent hydrogen, optionally substituted (C₁-C₁₈)-alkyl, preferably (C₁-C₁₀)-alkyl, in particular (C₁-C₆)-alkyl, (C₂-C₁₂)-alkenyl, preferably (C₂-C₈)-alkenyl, (C₃-C₇)-cycloalkyl, preferably cyclopentyl or cyclohexyl, (C₇-C₁₅)-aralkyl, preferably phenyl-(C₁-C₄)-alkyl, (C₆-C₁₀)-aryl, preferably phenyl or naphthyl, (C₁-C₁₈)-alkoxy, preferably (C₁-C₁₀)-alkoxy, for example methoxy, ethoxy, n-propoxy or isopropoxy, or (C₂-C₁₈)-alkoxy ester, it being possible for the abovementioned radical to be substituted by at least one sulphonate group, and
m has the abovementioned meaning.

Cationic or neutral poly-3,4-(ethylene-1,2-dioxy)thiophene is very particularly preferred.

In order to compensate the positive charge, the cationic form of the polythiophenes contains anions, preferably polyanions.

Preferably used polyanions are the anions of polymeric carboxylic acids, such as polyacrylic acids, polymethacrylic acid or polymaleic acids, and polymeric sulphonic acids, such as polystyrenesulphonic acids and polyvinylsulphonic acids. These polycarboxylic and polysulphonic acids may also be copolymers of vinylcarboxylic and vinylsulphonic acids with other polymerizable monomers, such as acrylic esters and styrene.

The anion of polystyrenesulphonic acid is particularly preferred as an opposite ion.

The molecular weight of the polyacids providing the polyanions is preferably from 1 000 to 2 000 000, particularly preferably from 2 000 to 500 000. The polyacids or their alkali metal salts are commercially available, for example polystyrenesulphonic acids and polyacrylic acids, or can be prepared by known processes (cf. for example Houben-Weyl, Methoden der organischen Chemie [Methods of Organic Chemistry], Vol. E 20, Makromolekulare Stoffe [Macromolecular Substances], Part 2 (1987), page 1141 et seq.).

Instead of the free polyacids required for the formation of the dispersions of polydioxythiophenes and polyanions, mixtures of alkali metal salts of the polyacids and corresponding amounts of monoacids may also be used.

An optionally present hole-conducting layer is preferably adjacent to the hole-injecting layer and preferably contains one or more aromatic tertiary amino compounds, preferably optionally substituted triphenylamine compounds, particularly preferably tris-1,3,5-(aminophenyl)benzene compounds of the formula K 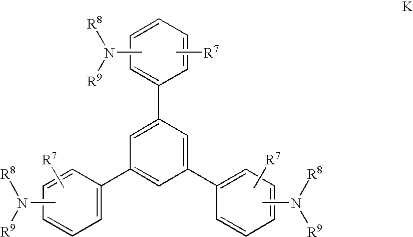
in which
R⁷ represents hydrogen, optionally substituted alkyl or halogen,
R⁸ and R⁹, independently of one another, represent optionally substituted (C₁-C₁₀)-alkyl, preferably (C₁-C₆)-alkyl, in particular methyl, ethyl, n-propyl or isopropyl, n-butyl, isobutyl, sec-butyl or tert-butyl, alkoxycarbonyl-substituted (C₁-C₁₀)-alkyl, preferably (C₁-C₄)-alkoxycarbonyl-(C₁-C₆)-alkyl, such as, for example, methoxy-, ethoxy-, propoxy- or butoxycarbonyl-(C₁-C₄)-alkyl, aryl, aralkyl or cycloalkyl, each of which is optionally substituted, preferably phenyl-(C₁-C₄)-alkyl, naphthyl-(C₁-C₄)-alkyl, cyclopentyl, cyclohexyl, phenyl or naphthyl, each of which is optionally substituted by (C₁-C₄)-alkyl and/or by (C₁-C₄)-alkoxy.
   Optionally present substituents for the abovementioned radicals are to be understood as meaning, for example, straight-chain or branched alkyl, cycloalkyl, aryl, halogenoalkyl, halogen, alkoxy and sulpho radicals.

R⁸ and R⁹, independently of one another, particularly preferably unsubstituted phenyl or naphthyl, or phenyl or naphthyl, each of which is monosubstituted to trisubstituted by methyl, ethyl, n-propyl, isopropyl, methoxy, ethoxy, n-propoxy and/or isopropoxy.
R⁷ preferably represents hydrogen, (C₁-C₆)-alkyl, such as, for example, methyl, ethyl, n-propyl or isopropyl, n-butyl, isobutyl, sec-butyl or tert-butyl, or chlorine.

Such compounds and the preparation thereof are described in U.S. Pat. No. 4,923,774 for use in electrophotography. The tris-nitrophenyl compound can be converted into the tris-aminophenyl compound, for example by generally known catalytic hydrogenation, for example in the presence of Raney nickel (Houben-Weyl 4/1C, 14-102, Ullmann (4) 13, 135-148). The amino compound is reacted with substituted halogenobenzenes in a generally known manner.

In addition to the tertiary amino compounds, further hole conductors, for example in the form of a mixture with the tertiary amino compound, may optionally be used for producing the electroluminescent element. These may be, on the one hand, one or more compounds of the formula K, mixtures of isomers also being included, and, on the other hand, also mixtures of hole-transporting compounds having a different structure with tertiary amino compounds of the general formula K.

A list of possible hole-injecting and hole-conducting materials is given in EP-A 0 532 798.

In the case of mixtures of the aromatic amines, the compounds may be used in any desired ratio.

An optionally present electron-transporting layer is preferably adjacent to the light-emitting layer and preferably contains Alq₃ (q=8-hydroxyquinolinato), Gaq₃, Al(qa)₃, Ga(qa)₃ or a gallium complex from the group consisting of Ga(qa)₂OR⁶, Ga(qa)₂OCOR⁶ or Ga(qa)₂—O—Ga(qa)₂, R⁶ representing substituted or unsubstituted alkyl, aryl, arylalkyl or cycloalkyl and qa representing

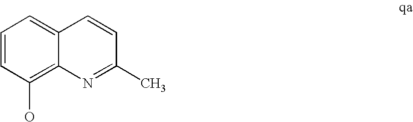

The preparation of the gallium complexes is described in EP-A 949695 and DE 19812258. The electron-transporting layer can be applied by vapour deposition processes (e.g. Alq₃) or preferably by applying the readily soluble gallium complexes described from solution by spin-coating, casting or knife-coating. Suitable solvents are, for example, methanol, ethanol, n-propanol or isopropanol.

In a particular embodiment, the electroluminescent arrangement according to the invention may contain a hole-blocking layer between light-emitting layer and electron-transporting layer. Preferably, the hole-blocking layer contains bathocuproin (BCP) or TPBI (1,3,5-tris[N-phenylbenzimidazol-2-yl]benzene)

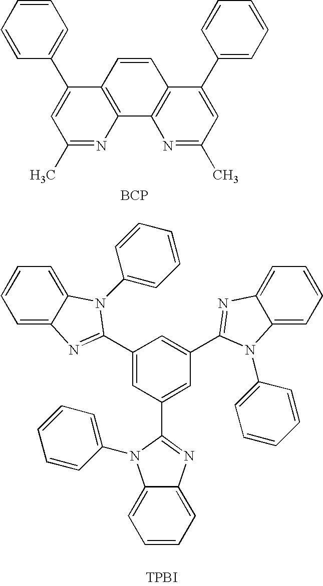

The electron-injecting layer consists of an alkali metal fluoride or alkali metal oxide or of an organic compound n-doped by reaction with an alkali metal. The electron-injecting layer preferably contains LiF, Li₂O, Li quinolate, etc.

The layers or layer present between hole-injecting layer and cathode can also perform a plurality of functions, i.e. a layer may contain, for example, hole-injecting, hole-transporting, electroluminescent (light-emitting), hole-blocking, electron-transporting and/or electron-injecting substances.

The top electrode consists of a conductive substance which may be transparent. Preferably, metals, e.g. Ca, Ba, Li, Sm, Al, Ag, Au, Mg, In, Sn, etc., or alloys of two or more of these metals, which can be applied by techniques such as vapour deposition, sputtering or platinization, are suitable.

Glass, very thin glass (flexible glass) or plastics are suitable as the transparent substrate which is provided with a conductive layer. Particularly suitable plastics are: polycarbonates, polyesters, copolycarbonates, polysulphone, polyethersulphone, polyimide, polyethylene, polypropylene or cyclic polyolefins or cyclic olefin copolymers, hydrogenated styrene polymers or hydrogenated styrene copolymers.

A preferred embodiment of the present invention relates to electroluminescent arrangements in which the electroluminescent element is a two-layer structure comprising a hole-injecting and light-emitting layer.

A further preferred embodiment of the present invention relates to electroluminescent arrangements in which the electroluminescent element is a one-layer structure comprising a light-emitting layer.

In order to prevent degradation, in particular by atmospheric oxygen and water, the arrangement according to the invention can be encapsulated with a material having a high diffusion barrier to oxygen and water. Suitable materials are very thin glass (from Schott Displayglas) and polymer laminate systems which may be coated with metal oxides or metal nitrides by vapour deposition (SiO, Al₂O₃, MgO, SiₓN_{y}, etc.; polyvinyl alcohol, Aclar®, polyvinylidene difluoride, etc.).

In addition to the phosphorescent or luminescent polymers described in the invention, the light-emitting layer may contain further phosphorescent or luminescent polymers and/or conductive polymers known to a person skilled in the art in the form of a blend for improving the film formation properties, for adapting the emission colour and/or for influencing the charge carrier transport properties. The blend polymers are usually used in an amount of up to 95, preferably up to 80, % by weight.

The electroluminescent arrangements emit light of wavelengths from 200 to 2 000 nm, preferably from 400 to 800 nm, on application of a DC voltage in the range from 0.1 to 100 volt, preferably from 1 to 100 volt. Additional emissions in other spectral ranges is not ruled out thereby but has no influence on the visually perceptible colour of the light emitted as a whole.

The electroluminescent arrangements according to the invention can be used, for example, as laser diodes in indicators or as displays (TV, computer monitor-), for backlighting of LCDs and watches, as illumination elements, in flat panels light sources, as information signs, in mobile communication devices, in indicators for household appliances (e.g. washing machine, refrigerator, vacuum cleaner, etc.) or as integrated displays in displacement systems, etc.

The production of the electroluminescent elements in the electroluminescent arrangements is furthermore according to the invention, the phosphorescent or luminescent conjugated polymers being applied from solution.

For the production of the electroluminescent element, the phosphorescent or luminescent polymer is dissolved in a suitable solvent and is applied to a suitable substrate from solution, preferably by spin-coating, casting, immersion, knife-coating, screen printing, inkjet printing, flexographic printing or offset printing. Owing to the higher process speeds and the smaller amount of waste material produced, this method is advantageous compared with vapour deposition methods (e.g. CVD), which are used in the case of low molecular emitter materials, since a substantial cost saving and simplification of the process technology are achieved and a large-area application is permitted. In particular, printing techniques permit targeted application of complicated structures without an expensive mask technique and lithography processes.

Suitable solvents are alcohols, ketones, aromatics, halogenated aromatics, halogenated hydrocarbons, etc. or mixtures of these. Preferred solvents are toluene, o-/m-/p-xylene, chlorobenzene, di- and trichlorobenzene, chloroform, THF, etc. The solution concentrations of phosphorescent or luminescent polymers are between 0.1 and 20% by weight, preferably between 0.5 and 10% by weight, particularly preferably between 0.5 and 3% by weight. The layer thickness of the light-emitting layer is from 5 nm to 1 μm, preferably from 5 nm to 500 nm, particularly preferably from 20 nm to 500 nm, very particularly preferably from 20 nm to 100 nm.

The substrate may be, for example, glass or a plastics material which is provided with a transparent electrode. The plastics material used may be, for example, a film of polycarbonates, polyesters, such as polyethylene terephthalate or polyethylene naphthalate, copolycarbonates, polysulphone, polyethersulphone, polyimide, polyethylene, polypropylene or cyclic polyolefins or cyclic olefin copolymers, hydrogenated styrene polymers or hydrogenated styrene copolymers. The substrate may furthermore be a layer arrangement which already contains one or more of the layers 1 to 10 (cf. page 2), preferably 1 to 7, contained in the fundamental structure of an EL arrangement, it also being possible for one layer to perform the functions of a plurality of these layers.

Suitable transparent electrodes are: metal oxides, e.g. indium tin oxide (ITO), tin oxide (NESA), zinc oxide, doped tin oxide, doped zinc oxide, etc.; semitransparent metal films, e.g. Au, Pt, Ag, Cu, etc.; conductive polymer films, such as polythiophenes, polyanilines, etc. The thickness of the transparent electrode is from 3 nm to about several jlm, preferably from 10 nm to 500 nm.

### EXAMPLES

All molar masses mentioned below were determined by means of GPC (gel permeation chromatography) (calibration against polystyrene standard, dichloromethane solvent).
Iridium Precursor Complexes Used:

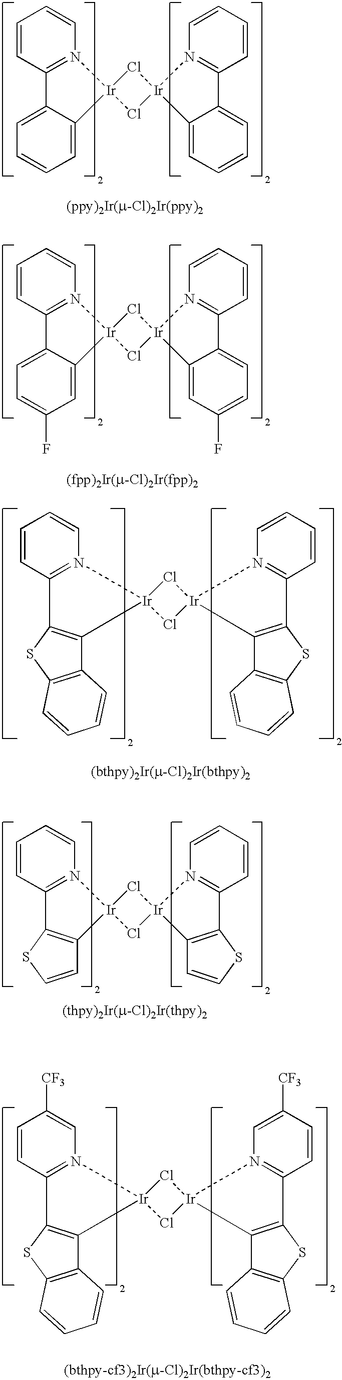

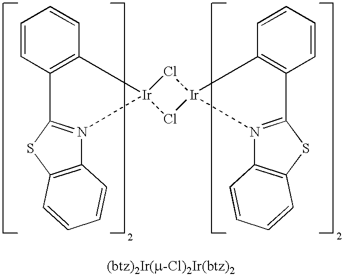

### Example 1

### Synthesis of a Polymer Having Repeating Units of the General Formula A and B-I-1 (Ar¹=2,7-(9,9-di-n-octyl)fluorenyl, R²=octyl, L=2-phenylpyridine (ppy))

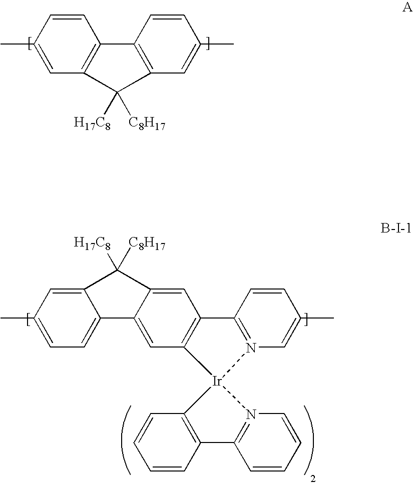 (ppy)₂Ir(μ-Cl)₂Ir(ppy)₂ (67 mg) and silver trifluoromethanesulphonate (32.1 mg) in dichloromethane (25 ml)/acetonitrile (1.25 ml) were stirred under nitrogen and in the absence of light under reflux for 10.5 h. After the silver chloride formed had been separated off by filtration and the solvent had been distilled off, the ligand polymer poly-[(9,9′-di-n-octyl-2,7-fluorenyl)-co-(2,5-pyridyl)] (number of units A: number of units B-I-1=12:1; M_{w}=88 100 (D=2.82); 200 mg), dissolved in a mixture of anisole and 2-ethoxyethanol (85:15) (25 ml), was added. The solution was stirred under reflux for 23 h under nitrogen. After the solution had been filtered and evaporated down to 13 ml, the polymer was precipitated in 400 ml of methanol. The subsequent Soxhlet extraction with methanol/acetone (1:1) gave, after drying in vacuo, 195.6 mg of the desired phosphorescent polymer as an orange-coloured fibrous product. ¹H-NMR (400 MHz, CDCl₃, TMS): δ=9.09 (H_{ppy}), 8.58 (H_{ppy}), 8.26 (H_{ppy}), 7.9-7.6 (H_{Polyfluorene}+H_{ppy}), 6.94 (H_{ppy}), 6.48 (H_{ppy}) 2.12 (H_{CH2}), 1.14 (H_{CH2}), 0.82 (H_{CH3}); photoluminescence (thin film on quartz glass substrate, λₑₓ=296 nm); λ_{em,max}=630 nm.

The synthesis of the other phosphorescent polymers having repeating units of the general formula A and B-I-1 or A and B-I-2 can be carried out in an analogous manner.

### Example 2-a

### Synthesis of a Polymer of the General Formula C-1 (Ar¹=2,7-(9,9′-di-n-octyl)fluorenyl, R⁴=hexyl, L=2-benzo[b]thiophen-2-yl-pyridine (bthpy))

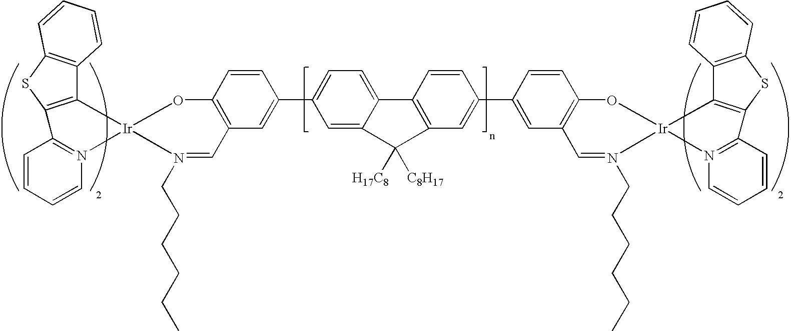

Terminal group-functionalized (salicylaldehyde-n-hexylimine) poly-2,7-9,9′-di-n-octyl)-fluorene (M_{w}=8 400 (D=2.1); 400 mg), (bthpy)₂Ir(μ-Cl)₂Ir(bthpy)₂ (65 mg) and sodium carbonate (14 mg) were heated under reflux for 40 h under a nitrogen atmosphere in a mixture of 1,2-dichloroethane (50 ml) and ethanol (10 ml). After cooling, chloroform (40 ml) was added and filtration was effected. The filtrate was concentrated and was chromatographed over silica gel (CH₂Cl₂). The product fractions were combined and concentrated (5 ml) and the product was precipitated in methanol (300 ml). After drying in vacuo, 366 mg of the desired product were obtained as a yellow-orange flocculant solid which produces intense red luminescence under a UV lamp. ¹H-NMR (CDCl₃, 400 MHz, TMS): δ=8.89 (d), 8.47 (d), 8.17 (s), 7.90-7.60 (H_{Ar-polyfluorene}), 7.53 (m), 7.35 (m), 7.05 (m), 6.92 (t), 6.81 (m), 6.37 (d), 6.09 (d), 3.15 (br, H_{N-CH2}) 2.12 (m, H_{CH2, polyfluorene}), 1.14 (br, H_{CH2, polyfluorene}), 0.82 (t, H_{CH3, polyfluorene}); GPC(CH₂Cl₂): M_{w}=10 500; photoluminescence (thin film on quartz glass substrate, λₑₓ=372 mm), λ_{em,max}=612 nm; electroluminescence: λ_{em,max}=612 nm.

### Example 2-b

### Synthesis of a Polymer, of the General Formula C-1 (Ar¹=2,7-(9,9′-di-n-octyl)fluorenyl, R⁴=hexyl, L=2-benzo[b]thiophen-2-yl-pyridine (bthpy))

The procedure is analogous to example 2-a, but with terminal group-functionalized (salicylaldehyde-n-hexylimine) poly-2,7-(9,9′-di-n-octyl)fluorene (M_{w}=35 200 (D=3.4); 700 mg), (bthpy)₂Ir(μ-Cl)₂Ir(bthpy)₂ (40 mg), Na₂CO₃ (8.5 mg), 1,2-dichloroethane (50 ml) and ethanol (10 ml). Reaction time: 32 h. After isolation of the product, 603 mg of a yellow-orange fibrous solid which produces intense red luminescence under the UV lamp were obtained.

### Example 3

### Synthesis of a Polymer of the General Formula C-1 (Ar¹=2,7-(9,9′-di-n-octyl)fluorenyl, R⁴=hexyl, L=2-(2-thienyl)pyridine (thpy))

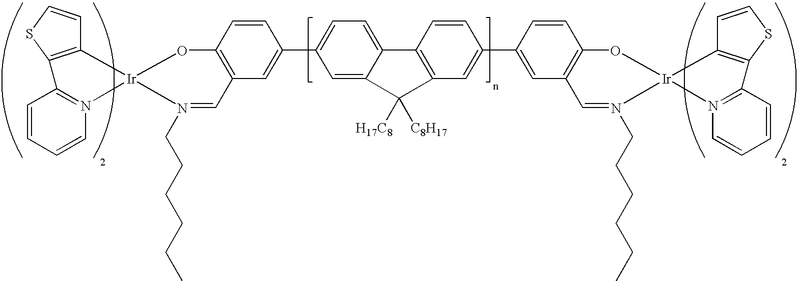

Terminal group-functionalized (salicylaldehyde-n-hexylimine) poly-2,7-(9,9′-di-n-octyl)-fluorene M_{w}=8 400 (D=2.1); 400 mg), (thpy)₂Ir(μ-Cl)₂Ir(thpy)₂ (55 mg) and sodium carbonate (14 mg) were heated under reflux for 27 h under a nitrogen atmosphere in a mixture of 1,2-dichloroethane (50 ml) and ethanol (10 ml). After cooling, chloroform (40 ml) was added and filtration was effected. The filtrate was concentrated and was chromatographed over silica gel (CH₂Cl₂). The product fractions were combined and concentrated (4 ml) and the product was precipitated in methanol (300 ml). After drying in vacuo, 332 mg of the desired product were obtained as a yellow-orange flocculant solid which produces weak orange luminescence under a UV lamp. ¹H-NMR (CDCl₃, 400 MHz, TMS): δ=8.99 (d), 7.90-7.60 (H_{Ar-polyfluorene}), 7.53 (m), 7.35 (m), 7.05 (d), 6.62 (m), 5.91 (d), 3.75 (br, H_{N-CH2}) 2.12 (m, H_{CH2, polyfluorene}), 1.14 (br, H_{CH2, polyfluorene),} 0.82 (t, H_{CH3, polyfluorene}).

### Example 4

### Synthesis of a Polymer of the General Formula C-1 (Ar¹=2,7-(9,9′-di-n octyl)fluorenyl, R⁴ hexyl, L=2-phenyl-benzothiazole (btz))

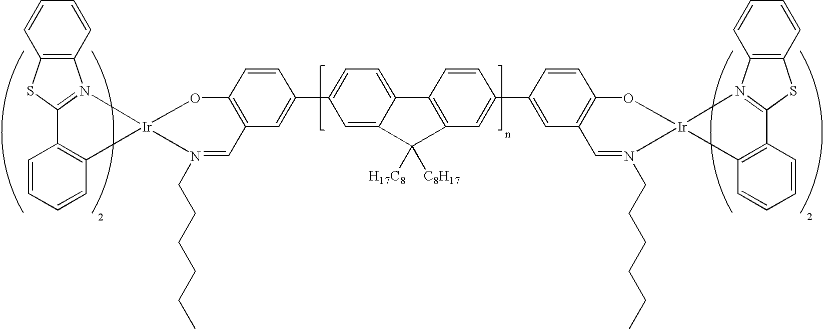

Terminal group-functionalized (salicylaldehyde-n-hexylimine) poly-2,7-(9,9′-di-n-octyl)-fluorene (M_{w}=8 400 (D=2.1); 250 mg), (btz)₂Ir(μ-Cl)₂Ir(btz)₂ (39 mg) and sodium carbonate (10 mg) were heated under reflux for 36 h under a nitrogen atmosphere in a mixture of 1,2-dichloroethane (30 ml) and ethanol (6 ml). After cooling, chloroform (40 ml) was added and filtration was effected. The filtrate was concentrated and was chromatographed over silica gel (CH₂Cl₂). The product fractions were combined and concentrated (10 ml) and the product was precipitated in methanol (500 ml). After drying in vacuo, 180 mg of the desired product were obtained as an orange solid which produces intense orange luminescence under a UV lamp (366 nm). ¹H-NMR (CDCl₃, 400 MHz, TMS): δ=8.75 (d), 8.63 (d), 8.03 (s), 7.90-7.60 (H_{Ar-polyfluorene}), 7.5-7.3 (m), 6.87 (m), 6.73 (m), 6.62 (m), 6.41 (t), 6.26 (d), 5.99 (d), 3.48, 3.28 (br, H_{N-CH2}), 2.12 (m, H_{CH2, polyfluroene}), 1.14 (br, H_{CH2, polyfluorene}), 0.82 (t, H_{CH3, polyfluorene}). Photoluminescence (thin film on quartz glass substrate, λₑₓ=452 nm): λ_{em, max}=581, 614(sh) nm; electroluminescence λ_{em, max}=570(sh), 612 nm.

### Example 5

### Synthesis of a Red-Phosphorescent Polymer Having Repeating Units of the General Formulae A and B-I-6 (Ar¹=2,7-(9,9-di-2-ethylhexyl)fluorenyl, R⁴ hexyl, L=2-benzo[b]thiophen-2-yl-(5-trifluoromethyl)pyridine (bthpy-cf3))

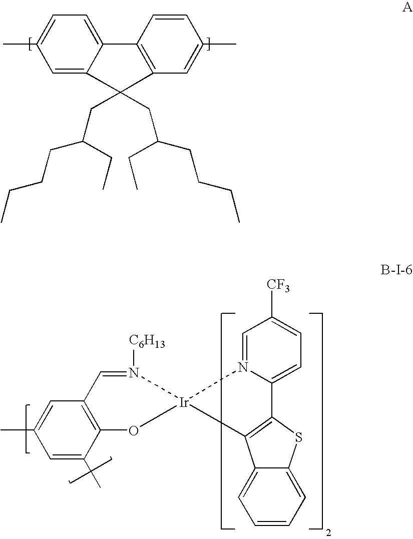

The random polyfluorene ligand copolymer containing 2,7-(9,9′-di-2-ethylhexyl)fluorene units A and 3,5-bridged uncomplexed salicyl-N-hexylimine units B-I-6 in the ratio 98.5 (A): 1.5 (B-I-6) (M_{w}=53 900 (D=2.15)) (250 mg), (bthpy-cf3)₂Ir(μ-Cl)₂Ir(bthpy-cf3)₂ (11 mg) and sodium methanolate (0.8 mg) were heated under reflux under a nitrogen atmosphere in a mixture of chloroform (15 ml) and methanol (1 ml) for 20 h. Working-up as in example 23 gave 211 mg of fibrous yellow solid which produces intense deep red luminescence under a UV lamp.

Evidence of the complexing from ¹H NMR spectroscopy.

Film emission spectrum: (λ_{exc}=411 nm): λ_{em, max}=640 nm.

### Example 6

### Synthesis of a Polymer of the General Formula C-2 (Ar¹=2,7-9,9′-di-n-octyl)fluorenyl, R⁵=methyl, L=2-(2-thienyl)pyridine (thpy))

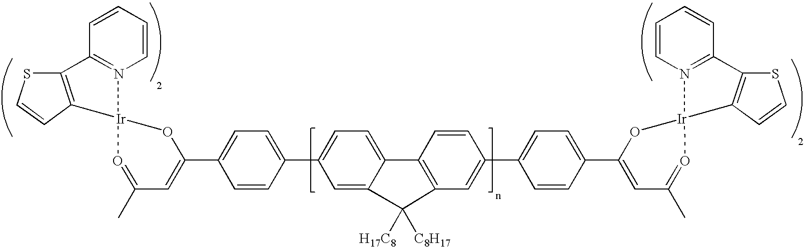

Terminal group-functionalized (4-benzoylacetone)poly-2,7-(9,9′-di-n-octyl)-fluorene (M_{w}=7 600 (D=1.8); 250 mg), (thpy)₂Ir(μ-Cl)₂Ir(thpy)₂ (65 mg) and sodium carbonate (63.6 mg) were stirred under reflux under a nitrogen atmosphere in 2-ethoxyethanol (15 ml) for 13.5 h.

After cooling, water (30 ml) was added, stirring was effected and extraction was then effected with chloroform (3×50 ml). The extracts were evaporated to dryness and taken up again in chloroform and the product was precipitated by being introduced into methanol. After chromatography over silica gel (chloroform), the product fractions were evaporated down and again precipitated in methanol. After drying in vacuo, 97.8 mg of yellow-orange flocculant product which produces intense orange luminescence under a UV lamp (366 nm) were obtained. ¹H NMR (CDCl₃, 400 MHz, TMS): δ=8.44 (d), 8.40 (d), 8.17 (d), 8.08 (d), 7.90-7.60 (7.51 (m), 7.34 (m), 6.90 (m), 6.25 (d), 6.23 (d), 5.98 (s), 2.12 (br, H_{CH2, polyfluorene}), 1.98 (s), 1.14 (br, H_{CH2, polyfluorene}), 0.82 (t, H_{CH3, polyfluorene}).

### Example 7

### Synthesis of a Polymer of the General Formula C-2 (Ar¹=2,7-(9,9′-di-n-octyl)fluorenyl, R¹=methyl, L=2-benzo[b]-thiophen-2-yl-pyridine (bthpy))

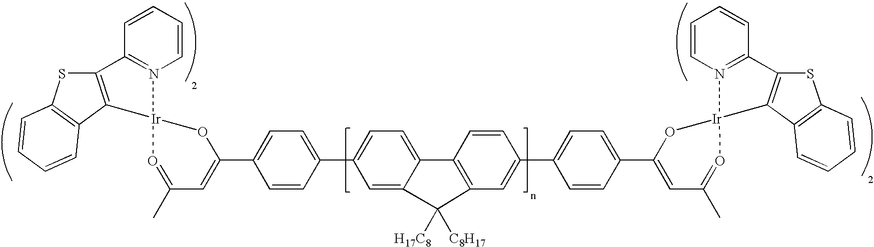

Terminal group-functionalized (4-benzoylacetone)poly-2,7-(9,9′-di-n-octyl)-fluorene (M_{w}=19 500 (D=2.3); 300 mg) and (bthpy)₂Ir(μ-Cl)₂Ir(bthpy)₂ (39 mg), dissolved in chloroform (22.5 ml) were added dropwise under a nitrogen atmosphere to a solution of sodium methylate (2.4 mg) in methanol (0.75 ml), and stirred for 1 h at room temperature and then for 5.5 h under reflux. After cooling, chloroform (20 ml) was added, filtration was effected and the filtrate was evaporated down. After chromatography over silica gel (dichloromethane), the product fractions were concentrated (5 ml) and precipitated in methanol (400 ml). After drying in vacuo, 203 mg of orange flocculant product which produces intense red luminescence under a UV lamp (366 nm) were obtained. ¹H NMR (CDCl₃, 400 MHz, TMS): δ=8.53 (d), 8.48 (d), 7.90-7.60 (H_{Ar-polyfluorene}) 7.40-7.30 (m), 7.09 (m), 6.98 (m), 6.84 (t), 6.30 (d), 6.27 (d), 6.02 (s), 2.12 (br, H_{CH2, polyfluorene}), 1.96 (s), 1.14 (br, H_{CH2, polyfluorene}) 0.82 (t, H_{CH3, polyfluorene}).

### Example 8

### Synthesis of a Polymer of the General Formula C-2 (Ar¹=2,7-(9,9′-di-n-octyl)fluorenyl, R⁵=methyl, L=4-fluorophenyl-2-pyridine (fpp))

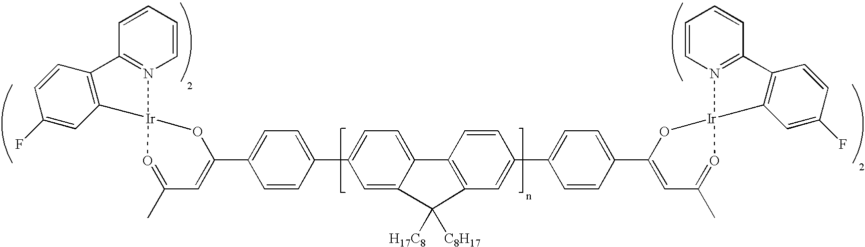

Terminal group-functionalized (4-benzoylacetone)poly-2,7-(9,9′-di-n-octyl)-fluorene (M_{w}=19 500 (D=2.3); 200 mg) and (fpp)₂Ir(μ-Cl)₂Ir(fpp)₂ (23 mg), dissolved in chloroform (15 ml), were added dropwise under a nitrogen atmosphere to a solution of sodium methylate (1.6 mg) in methanol (0.5 ml), stirred for 1 h at room temperature and then for 5 h under reflux. After cooling, filtration was effected and the filtrate was evaporated to dryness. The product was taken up again in dichloromethane and chromatographed over silica gel (dichloromethane). The product fractions were concentrated and precipitated in methanol. After drying in vacuo, 192 mg of yellow product which produces blue luminescence under a UV lamp (366 nm) were obtained. ¹H NMR (CDCl₃, 400 MHz, TMS): δ=9.13 (d), 8.54 (d), 8.49 (d), 7.90-7.60 (H_{Ar-polyfluorene}), 7.40-7.30 (m), 7.15 (m), 6.60 (d), 6.58 (d), 5.99 (s), 5.95 (m), 5.92 (d), 2.12 (br, H_{CH2, polyfluorene}), 1.97 (s), 1.14 (br, H_{CH2, polyfluorene}), 0.82 (t, H_{CH3, polyfluorene}).

### Example 9

The substance according to the invention from example 2-a is used for producing an organic light emitting diode (OLED). The following procedure is adopted in the production of the OLED:

1. Cleaning of ITO Substrate

ITO-coated glass Merck Balzers AG, FL, Part No. 253 674 XO) is cut into 50 mm×50 mm pieces (substrates). The substrates are then cleaned in 3% strength aqueous Mucasol solution in an ultrasonic bath for 15 min. Thereafter, the substrates are rinsed with distilled water and spun dry in a centrifuge. This rinsing and drying process is repeated 10 times.

2. Application of the Baytron® P Layer

About 0.10 ml of the 1.3% strength polyethylenedioxythiophene/polysulphonic acid solution (Bayer AG, Baytron® P, TP AI 4083) are filtered (Millipore HV, 0.45 μm). The substrate is then placed on a spin coater and the filtered solution is distributed over the ITO-coated side of the substrate. The supernatant solution is then spun off by rotating the turntable at 500 rpm over a period of 3 min. The substrate coated in this manner is then dried at 110° C. on a hotplate for 5 min. The layer thickness is 60 nm (Tencor, Alphastep 200).

3. Application of the Emitter Layer

5 ml of a 1% by weight toluene solution of the substance according to the invention from example 2-a are filtered (Millipore HV, 0.45 μm) and distributed over the dried Baytron® P layer. The supernatant solution is then spun off by rotating the turntable at 300 rpm for 30 sec. The substrate coated in this manner is then dried at 110° C. on a hotplate for 5 ml. The total layer thickness is 150 nm.

4. Application of the Metal Cathode

A metal electrode is applied to the organic layer system by vapour deposition. The vapour deposition unit (Edwards) used for this purpose is integrated in an inert gas glovebox (Braun). The substrate is placed with the organic layer facing downwards on a perforated mask (hole diameter 2.5 mm). A 30 nm thick Ca layer and then a 200 nm Ag layer are applied in succession by vapour deposition from two vaporization boats at a pressure of p=10⁻³ Pa. The vapour deposition rates are 10 Å/sec for Ca and 20 Å/sec for Ag.

5. Characterization of the OLED

The two electrodes of the organic LED are connected via electric leads to a voltage source. The positive pole is connected to the ITO electrode and the negative pole is connected to the metal electrode. The OLED current and the electroluminescence intensity, which is detected by means of a photodiode (EG&G C30809E), are plotted as a function of the voltage. The spectral distribution of the electroluminescence is then measured using a glass fibre spectrometer (Zeiss MSC 501). All OLED characterizations are carried out in a glovebox under inert conditions. Above a voltage of 6 volt, electroluminescence is detectable. The colour of the electroluminescence is red and the maximum of the spectral electroluminescence distribution is voltage-independent and is 612 nm (cf. FIG. 1). The CIE colour coordinates of the emission are: x=0.660; y=0.332.

FIG. 1: Electroluminescence spectrum from example 9

### Comparative Example 1

The procedure is as in example 9, with the following difference in the case of step 3 (application of the emitter layer).

3. Application of the Emitter Layer

5 ml of a 1% by weight chloroform solution of a poly-2,7-(9,9′-di-n-octyl)fluorene (cf. structural formula) are filtered (Millipore HV, 0.45 μm) and distributed over the dried Baytron P layer. The supernatant solution is then spun off by rotating the turntable at 2 500 rpm for 120 sec. The substrate coated in this manner is then dried at 110° C. on a hotplate for 5 min. The total layer thickness is 250 nm.

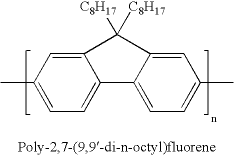

The colour of the electroluminescence in comparative example 1 is bluish, the maximum of the spectral electroluminescence distribution is 438.5 nm (cf. FIG. 2) and the CIE colour coordinates are: x=0.164; y=0.113.

FIG. 2: Electroluminescence spectrum from comparative example 1

In comparison with example 9, it is clearly shown here that the covalent linkage of the Ir complexes to the polyfluorene ligand groups changes the emission colour.

### Comparative Example 2

The procedure is as in example 9, with the following difference in the case of step 3 (application of the emitter layer).

3. Application of the Emitter Layer

5 ml of a 1% by weight chloroform solution consisting of 97% by weight of poly-2,7-(9,9′-di-n-octyl)fluorene (cf. example 8) and 3% by weight of tris(2-phenylpyridine)iridium (cf. structural formula) are filtered (Millipore RV, 0.45 μm) and distributed over the dried Baytron P layer. The supernatant solution is then spun off by rotating the turntable at 2 500 rpm for 150 sec. The substrate coated in this manner is then dried at 110° C. on a hotplate for 5 min. The total layer thickness is 250 nm.

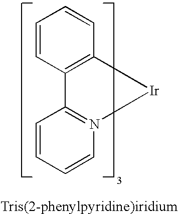

The electroluminescence spectrum of this structure corresponds to that described in comparative example 1 (cf. FIG. 2), i.e. the spectrum is identical to that of pure poly-2,7-(9,9′-di-n-octyl)fluorene.

This examples shows that the doping of the polyfluorene emitter polymer with Ir complexes by simple admixing does not lead to the desired emission of the iridium complex.

### Example 10

### Synthesis of a Polymer of the General Formula (Ia-1) (Ar¹=2,7-(9,9′-di-n-octyl)fluorenyl, R=hexyl, L²=4-fluorophenyl-2-pyridine (fpp))

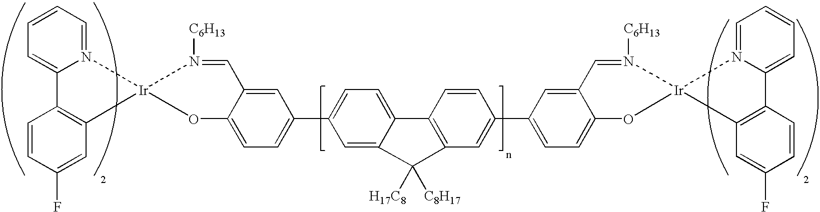 600 mg of ligand polymer containing 4 mol % of uncomplexed salicyl-N-hexylimine terminal groups, 30 mg (0.026 mmol) of (fpp)₂Ir(μ-Cl)₂Ir(fpp)₂ and 7.8 mg of sodium carbonate (0.074 mmol) in a mixture of 42 ml of 1,2-dichloroethane and 8 ml of ethanol were stirred under reflux under a nitrogen atmosphere for 38 h. After filtration, the solution was evaporated to dryness and the residue was taken up in a little chloroform and chromatographed over silica gel (CH₂Cl₂). The product fractions were concentrated (15 ml) and precipitated by being introduced into methanol (800 ml). Filtration with suction and drying under a vacuum from an oil pump gave 507 mg of product (yellow, fibrous).

The polymer contains 4 mol % of terminal groups, i.e. the iridium complex concentration is 4 mol %, based on the fluorene derivative fraction in the polymer.

The product produces white luminescence under UV irradiation (366 nm).

GPC(CH₂Cl₂ against PS): M_{w}=40 100.

Characterization and detection of complexing by ¹H NMR (400 MHz in CDCl₃/TMS, 25° C.).

### Example 11

### Synthesis of a Polymer of the General Formula (Ia-1) (Ar¹=2,7-(9,9′-di-n-octyl)fluorenyl, R=hexyl, L²=4-fluorophenyl-2-pyridine (fpp)

The synthesis is as described in example 10, with 200 mg of ligand polymer containing 2 mol % of uncomplexed salicyl-N-hexylimine terminal groups (M_{w}=71 300), 5 mg (0.004 mmol) of (fpp)₂Ir(μ-Cl)₂Ir(fpp)₂ and 1.3 mg of sodium carbonate (0.011 mmol) in a mixture of 15 ml of 1,2-dichloroethane and 2.8 ml of ethanol. The duration of the reaction is 38 h under reflux. After working-up, 123 mg of product were obtained (pale yellow, fibrous).

The polymer is identical to that of example 10, but the polymer in example 11 contains only 2 mol % of terminal groups, i.e. the iridium complex concentration is 2 mol %, based on the fluorene derivative fraction in the polymer.

The product produces white luminescence under UV irradiation (366 nm).

Characterization and detection of complexing by ¹H NMR (400 MHz in CDCl₃/TMS, 25° C.).

### Example 12

### Synthesis of a Polymer of the General Formula (Ia-1) (Ar¹=2,7-(9,9′-di-n-octyl)fluorenyl, R=hexyl, L²=phenyl-2-pyridine (ppy))

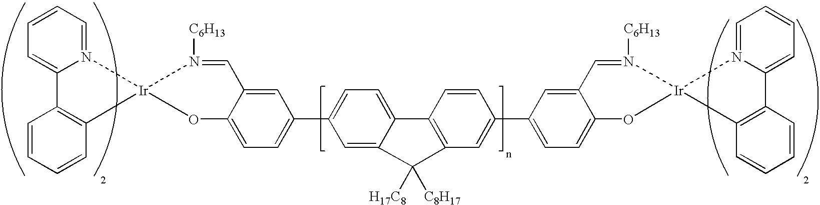

The procedure is as described in example 10, with 170 mg of ligand polymer containing 2 mol % of uncomplexed salicyl-N-hexylimine terminal groups (M_{w}=71 300), 4.3 mg (0.004 mmol) of (Ppy)₂Ir(μ-Cl)₂Ir(Ppy)₂ and 1 mg of sodium carbonate (0.009 mmol) in a mixture of 15 ml of 1,2-dichloroethane and 3 ml of ethanol. The duration of the reaction is 8 h under reflux. After working-up, 127 mg of the product were obtained (yellow, fibrous).

The product contains 2 mol % of terminal groups, i.e. the iridium complex concentration is 2 mol %, based on the fluorene derivative fraction in the polymer.

The product produces white luminescence under UV irradiation (366 nm).

Characterization and detection of complexing by ¹H NMR (400 MHz in CDCl₃/TMS, 25° C.).

Film emission spectrum: (λ_{exc}=398 nm): λₑₘ=439, 465, 550 nm.

### Example 13

### Synthesis of a Polymer of the General Formula (Ia-1) (Ar¹=2,7-(9,9′-di-n-octyl)fluorenyl, R=hexyl, L²=phenyl-2-pyridine (ppy))

The procedure is as in example 12, with 350 mg of ligand polymer containing 1 mol % of uncomplexed salicyl-N-hexylimine terminal groups (M_{w}=122 600), 8.6 mg (0.008 mmol) of (Ppy)₂Ir(μ-Cl)₂Ir(Ppy)₂ and 2.2 mg of sodium carbonate (0.02 mmol) in a mixture of 25 ml of 1,2-dichloroethane and 4 ml of ethanol. The duration of the reaction is 18.5 h under reflux. After working-up, 284 mg of product were obtained (pale yellow, fibrous).

The polymer is identical to that in example 12 but the product from example 13 contains only 1 mol % of terminal groups, i.e. the iridium concentration is 1 mol %, based on the fluorene derivative fraction in the polymer.

### Example 14

### Synthesis of a Polymer having Repeating Units of the General Formulae (Ic-1) and (Id-1) (Ar¹=2,7-(9,9′-di-n-octyl)fluorenyl, R=hexyl, L¹=2-(2-thienyl)pyridine (thpy))

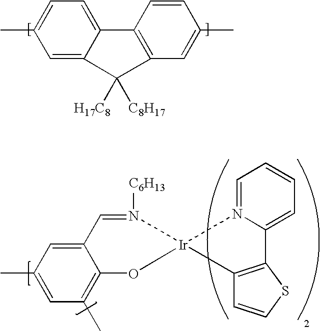

The procedure is as described in example 10, with 300 mg of ligand polymer containing 2.5 mol % of 3,5-linked uncomplexed salicyl-N-hexylimine repeating units which are randomly incorporated into the polymer (M_{w}=89 700), 17 mg (0.015 mmol) of (thpy)₂Ir(μ-Cl)₂Ir(thpy)₂ and 1.7 mg of sodium methanolate (0.031 mmol) in a mixture of 1 ml of methanol and 30 ml of chloroform. The duration of the reaction is 12 h under reflux. After working-up was complete, the product was taken up again in CH₂Cl₂ (10 ml) and precipitated by being introduced into a 1:1 mixture of acetone and methanol (400 ml). Filtration with suction and drying under a vacuum from an oil pump gave 232 mg of product (yellow, fibrous).

The polymer contains 2.5 mol % of iridium complexes in the polymer main chain, based on the fluorene derivative fraction in the polymer.

The product produces white luminescence on exposure to UV irradiation (366 nm). Characterization and detection of complexing by ¹H NMR (400 MHz in CDCl₃/TMS, 25° C.).

### Example 15

### Synthesis of a Polymer having Repeating Units of the General Formula (Ic-1) and (Id-1) (Ar¹=2,7-(9,9′-di-n-octyl)fluorenyl, R hexyl, L²=phenyl-2-pyridine (ppy))

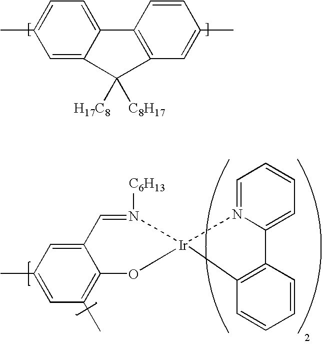

The procedure is as described in example 14, with 300 mg of ligand polymer containing 2.5 mol % of 3,5-linked uncomplexed salicyl-N-hexylimine repeating units which are randomly incorporated into the polymer (M_{w}=89 700), 16 mg (0.015 mmol) of (ppy)₂Ir(μ-Cl)₂Ir(ppy)₂ and 1.7 mg of sodium methanolate (0.031 mmol) in a mixture of 1 ml of methanol and 20 ml of chloroform. The duration of the reaction is 8 h under reflux. After working-up, 189 mg of product were obtained (yellow, fibrous).

The polymer contains 2.5 mol % of iridium complexes in the polymer main chain, based on the fluorene derivative fraction in the polymer.

The product produces white luminescence under UV irradiation (366 nm). Characterization and detection of complexing by ¹H NMR (400 MHz in CDCl₃/TMS, 25° C.).

### Example 16

### Synthesis of a Polymer having Repeating Units of the General Formula (Ic-1) and (Id-1) (Ar¹=2,7-(9,9′-di-n-octyl)fluorenyl, R=hexyl, L²−4-fluorophenyl-2-pyridine (fpp))

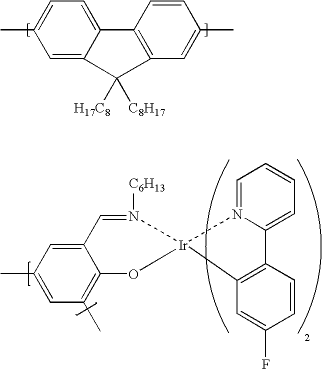

The procedure is as described in example 14, with 300 mg of ligand polymer containing 2.5 mol % of 3,5-linked uncomplexed salicyl-N-hexylimine repeating units which are randomly incorporated into the polymer (M_{w}=89 700), 17.1 mg (0.015 mmol) (fpp)₂Ir(μ-Cl)₂Ir(fpp)₂ and 1.7 mg of sodium methanolate (0.031 mmol) in a mixture of 1 ml of methanol and 20 ml of chloroform. The duration of the reaction is 8 h under reflux. After working-up, 175 mg of product were obtained (yellow, fibrous).

The polymer contains 2.5 mol % of iridium complexes in the polymer main chain, based on the content of fluorene derivative in the polymer.

The product produces white luminescence under UV irradiation (366 rm). Characterization and detection of complexing by ¹H NMR (400 MHz in CDCl₃/TMS, 25° C.).

### Example 17

### Synthesis of a Polymer having Repeating Units of the General Formula (Ic-1) and Various Repeating Units of the General Formula (Id-1) (Ar¹=2,7-(9,9′-di-n-octyl)fluorenyl, R=hexyl, L²=phenyl-2-pyridine (ppy) or 2-benzo[b]thiophen-2-yl-pyridine (bthpy))

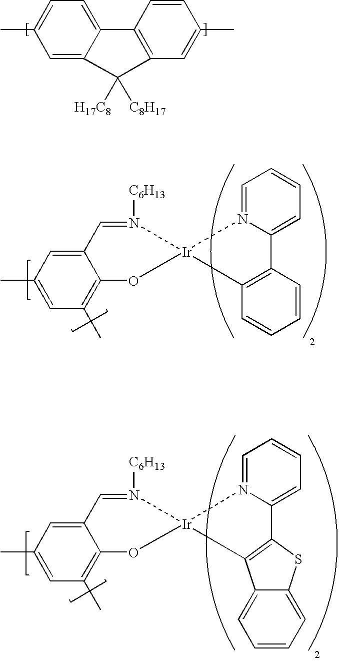

The procedure is as described in example 14, with 200 mg of ligand polymer containing 2.5 mol % of 3,5-linked uncomplexed salicyl-N-hexylimine repeating units which are randomly incorporated into the polymer, 3.3 mg (3.1 μmol) of (ppy)₂Ir(μ-Cl)₂Ir(ppy)₂, 0.3 mg (0.24 μmol) of (bthpy)₂Ir(μ-Cl)₂Ir(bthpy)₂ and 1 mg of sodium methanolate (0.02 mmol) in a mixture of 1 ml of methanol and 20 ml of chloroform. Duration of reaction 8 h under reflux. After working-up, 106 mg of product were obtained (yellow).

The polymer contains altogether 2.5 mol % of iridium complexes in the polymer main chain, based on the content of fluorene derivative in the polymer. The polymer contains two, different iridium complexes which have spectrally different emission properties: bis(phenyl-2-pyridine)iridium-salicylimine ((ppy)₂Ir(sal)) and bis(2-benzo[b]thiophen-2-yl-pyridine)iridium-salicylimine ((bthpy)Ir(sal)), which are randomly incorporated in the conjugated polymer main chain. The ratio of (ppy)₂Ir(sal) to (bthpy)₂Ir(sal) is about 93 to 7.

Characterization and detection of complexing by ¹H NMR (400 MHz in CDCl₃/TMS, 25° C.). The product produces white luminescence under a UV lamp (366 nm).

### Example 18

### Synthesis of a Polymer of the General Formula (Ia-2) (Ar¹=2,5-(2-ethylhexyloxy)phenylene, R=methyl, L²=phenyl-2-pyridine (ppy))

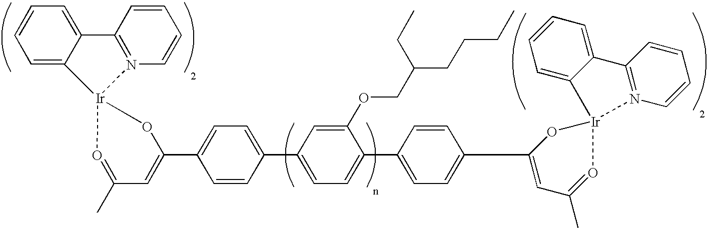

The procedure is as described in example 14, with 250 mg of ligand polymer containing 2 mol % of terminal benzoylacetone ligand groups (M_{w}=48 300), 19 mg (0.018 mmol) of (ppy)₂Ir(μ-Cl)₂Ir(ppy)₂ and 3 mg of sodium methanolate (0.055 mmol) in a mixture of 1 ml of methanol and 15 ml of chloroform. Duration of reaction 22 h under reflux. After working-up, 206 mg of product were obtained (pale yellow, fibrous).

The polymer contains 2 mol % of terminal groups, i.e. the concentration of iridium complex is 2 mol %, based on the content of phenylene derivative in the polymer.

The product produces white luminescence under a UV lamp (366 nm).

Characterization and detection of complexing by ¹H NMR (400 MHz in CDCl₃/TMS, 25° C.). Film emission spectrum: (λ_{exc}=370 nm): λₑₘ=413, 580 nm.

### Example 19

### Synthesis of a Polymer of the General Formula (Ia-2) (Ar¹=2,5-(2-ethylhexyloxy)phenylene, R=methyl, L²=4-fluorophenyl-2-pyridine (fpp))

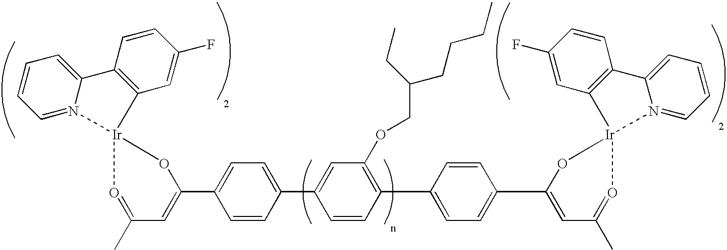

The procedure is as described in example 14, with 200 mg of ligand polymer containing 2 mol % of terminal benzoylacetone ligand groups (M_{w}=48 300), 18.5 mg (0.016 mmol) of (fpp)₂Ir(μ-Cl)₂Ir(fpp)₂ and 2.5 mg of sodium methanolate (0.04 mmol) in a mixture of 1 ml of methanol and 20 ml of chloroform. Duration of reaction 12.5 h under reflux. After working-up, 170 mg of product were obtained (pale yellow, fibrous).

The polymer contains 2 mol % of terminal groups, i.e. the concentration of iridium complex is 2 mol %, based on the content of phenylene derivative in the polymer.

The product produces white luminescence under a UV lamp (366 nm). Characterization and detection of complexing by ¹H NMR (400 MHz in CDCl₃/TMS, 25° C.). Film emission spectrum: (λ_{exc}=373 nm): λₑₘ=413, 597 nm.

### Example 20

The polymer according to the invention from example 11 is tested as an emitter layer in an OLED structure. The following procedure is adopted in the production of the OLED structure:

1. Structure of the ITO Substrates:

ITO-coated glass having a surface resistance of 20 ohm/sq (MDT, Merck KgaA) is cut into 50 mm×50 mm substrates and structured by a photoresist technique and subsequent etching so that 2 mm wide and about 10 mm long ITO lands remain.

2. Cleaning of the ITO Substrates:

The substrates are wiped manually with acetone-impregnated cloths and then cleaned in a 3% strength aqueous Mucasol solution in an ultrasonic bath for 15 min. Thereafter, the substrates are rinsed 10 times with distilled water and then spun dry in a centrifuge.

3. Application of the Baytron® P Layer (Hole-Injection Layer)

About 10 ml of a 1.6% strength polyethylenedioxythiophene/polysulphonic acid solution (H. C. Starck GmbH, Baytron® P TP AI 4083) are filtered (Millipore HV, 0.45 μm). The cleaned substrate is then placed on a spin coater and the filtered solution is distributed over the ITO-coated side of the substrate. The supernatant solution is then spun off by rotating the turntable at 2 500 rpm over a period of 2 min with the cover closed. The substrate coated in this manner is then dried on a hotplate for 5 min at 110° C. The layer thickness is 50 nm (Tencor, Alphastep 500).

4. Application of the Emitter Layer (Light-Emitting Layer):

The polymer described in example 11 is dissolved in chloroform (1% by weight). The solution is filtered (Millipore RV, 0.45 μm) and distributed over the dried Baytron® P layer. The supernatant solution is then spun off by rotating the turntable at 3 000 rpm over a period of 30 sec (Convac spin coater), the cover being raised over the chuck after 10 sec. The substrate coated in this manner is then dried on a hotplate for 5 min at 110° C. The total layer thickness comprising Baytron® P layer and emitter layer is 150 nm.

5. Application of the Metal Cathode:

A metal electrode is applied by vapour deposition to the organic layer system. The vapour deposition unit used for this purpose (Edwards) is integrated in an inert gas glovebox (Braun). The substrate is placed with the organic layer facing downwards on a vapour deposition mask having 1 mm wide and about 10 mm long slots. A 30 nm thick Ca layer and then a 200 nm Ag layer are applied in succession from two vaporization boats at a pressure of p 10⁻³ Pa. The vapour deposition rates are 10 Å/sec for Ca and 20 Å/sec for Ag.

6. Characterization of the OLED:

The two electrodes of the organic LED are connected to a voltage source via electric leads. The positive pole is connected to the ITO electrode and the negative pole is connected to the metal electrode. The OLED current and the electroluminescence intensity are plotted as a function of the voltage. The electroluminescence is detected by means of a photodiode (EG&G C30809E). The voltage pulse duration is in each case 300 msec. The waiting time between the voltage pulses is 1 sec. The spectral distribution of the electroluminescence (EL) is then measured by means of a glass fibre spectrometer card (Sentronic CDI-PDA). The luminance is measured by means of a luminance meter (LS 100 Minolta). All OLED characterizations are carried out under inert conditions in a glovebox.

Results:

Above 4 V, electroluminescence is detectable. At 12 V, the current density is 1.3 A/cm² and the luminance is 180 cd/m² (efficiency at 12 V: η=0.014 cd/A). The following CIE colour coordinates are calculated from the electroluminescence spectrum (FIG. 3): x=0.28, y=0.31. The colour location is therefore close to the achromatic point and the emission appears white.

FIG. 3 Electroluminescence spectrum from example 20

### Example 21

The polymer according to the invention from example 13 is tested as an emitter layer in an OLED structure. The procedure corresponds to that in example 20, with the exception of subsection 4:

4. Application of the Emitter Layer:

The polymer described in example 13 is dissolved in toluene (1% by weight). The solution is filtered (Millipore HV, 0.45 μm) and distributed over the dried Baytron® P layer. The supernatant solution is then spun off by rotating the turntable at 600 rpm over a period of 30 sec with the cover opened (K. Süss RC-13 spin coater). The substrate coated in this manner is then dried on a hotplate for 5 min at 110° C. The total layer thickness comprising Baytron® P layer and emitter layer is 150 nm.

Results:

Above 4 V, electroluminescence is detectable. At 11.8 V, the current density is 300 mA/ci² and the luminance is 260 cd/m² (efficiency at 11.8 V: η=0.087 cd/A). The following CIE colour coordinates are calculated from the electroluminescence spectrum: x=0.29, y=0.31. The colour location is thus close to the achromatic point and the emission appears white.

### Example 22

The polymer according to the invention from example 12 is tested as an emitter layer in an OLED structure (OLED-a). For comparison, an OLED structure comprising pure polyfluorene which is blended with 2 mol % of bis(phenyl-2-pyridine)-iridium-salicyl-N-hexylimine) is tested (OLED-b). The two emitter systems contain identical amounts (2 mol %) of Ir complexes.

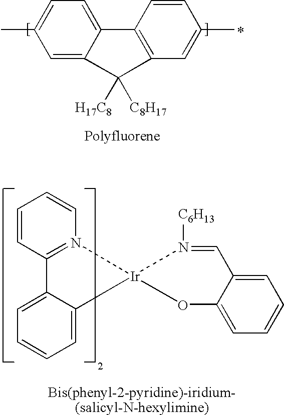

The procedure corresponds to example 20, with the exception of subsection 4:

4a. Application of the Polymer According to the Invention from example 12 as an Emitter Layer

The polymer described in example 12 is dissolved in toluene (1% by weight). The solution is filtered (Millipore HV, 0.45 μm) and distributed over the dried-Baytron® P. The supernatant solution is then spun off by rotating the turntable at 400 rpm over a period of 30 sec with the cover closed (K. Süss RC-13 spin coater). The substrate coated in this manner is then dried on a hotplate for 5 min at 110° C. The total layer thickness comprising Baytron® P layer and emitter layer is 150 nm.

4b. Application of the Polymer Blend as an Emitter Layer

69.5 g (179.1 μmol of fluorenylene repeating units) of the polyfluorene and 2.4 mg (3.4 μmol) of bis(phenyl-2-pyridine)-iridium-(salicyl-N-hexylimine) are dissolved in 28.69 g of chloroform. The solution is filtered (Millipore HV, 0.45 μm) and distributed over the dried Baytron® P layer. The supernatant solution is then spun off by rotating the turntable at 200 rpm over a period of 30 sec (K. Süss RC-13 spin coater). The cover is raised after 10 sec. The substrate coated in this manner is then dried on a hotplate for 5 min at 110° C. The total layer thickness comprising Baytron® P layer and emitter layer is 150 nm.

The layer structures OLED-a and OLED-b produced according to 4a and 4b are provided with a metal layer as cathodes, as described in example 20, by vapour deposition.

Result:

Electroluminescence is detectable as soon as above 4 V in the case of OLED-a and only above 5 V in the OLED-b. At 12 V, the current and the luminance are, respectively, 85 mA/cm² and 170 cd/d² for OLED-a and, respectively, 500 mA/cm² and 110 cd/m² for OLED-b (efficiency at 12 V: η=0.2 cd/A (OLED-a) and η=0.022 cd/A (OLED-b)). The following CIE colour coordinates are calculated from the electroluminescence spectrum: x=0.38, y=0.44 (OLED-a) and x=0.35, y=0.34 (OLED-b).

This comparative example shows that the covalent bonding of the Ir complex leads to more efficient OLEDs than the mixture of the Ir complex with the polymer. For example, OLED-a exhibits 10 times higher efficiency than OLED-b.

### Example 23

### Synthesis of a Red-Phosphorescent Polymer of the General Formula C-1 (Ar¹=2,7-(9,9′-di-n-octyl)fluorenyl, R⁴=hexyl, L=2-benzo[b]thiophen-2-yl-pyridine (bthpy))

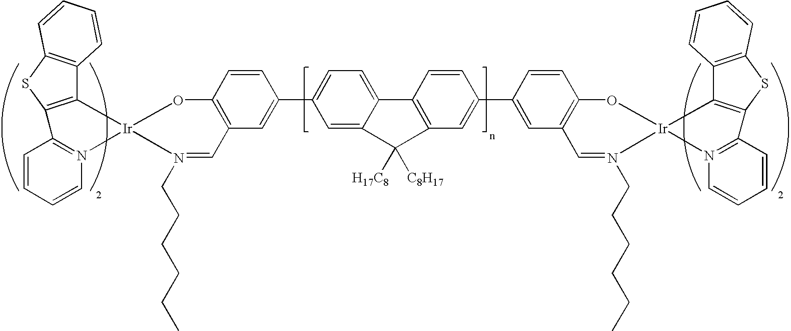

Terminal group-functionalized (salicylaldehyde-N-hexylimine)poly-2,7-(9,9′-di-n-octyl)fluorene (M_{w}=48 700 (D=2.3); 2 280 mg) containing about 2 mol % of ligand units, (bthpy)₂Ir(μ-Cl)₂Ir(bthpy)₂ (114 mg) and sodium carbonate (24.7 mg) were heated under reflux under a nitrogen atmosphere in a mixture of 1,2-dichloroethane (160 ml) and ethanol (30 ml) for 40.5 h. Working up as in example 2-a, additional reprecipitation of the product from chloroform in acetone/methanol (1:1). 1 780 mg of fibrous yellow solid which produces intense red fluorescence under a UV lamp.

Detection of complexing by ¹H NMR spectroscopy.

Electroluminescence: λ_{em, max}=612 nm.

### Example 24

### Synthesis of a Red-Phosphorescent Polymer having Repeating Units of the General Formulae A and B-I-6 (A¹=2,7-(9,9-di-n-octyl)fluorenyl, R⁴=hexyl, L=2-benzo[b]thiophen-2-yl-pyridine (bthpy))

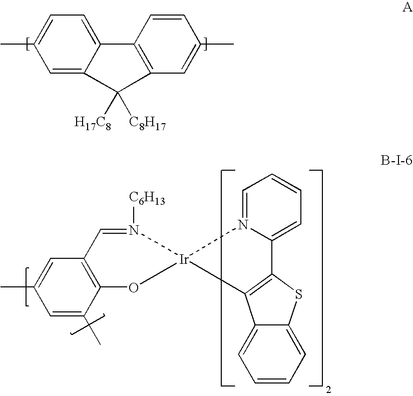

The random polyfluorene ligand copolymer containing 2,7-(9,9′-di-n-octyl)-fluorene units A and 3,5-bridge uncomplexed salicyl-N-hexylimine units B-1-6 in the molar ratio 97.5 (A): 2.5 (B-I-6) (M_{w}=119 400 (D=3.43) (1 650 mg), (bthpy)₂Ir(μ-Cl)₂Ir(bthpy)₂ (110 mg) and sodium methanolate (9 mg) were heated under reflux under a nitrogen atmosphere in a mixture of chloroform (100 ml) and methanol (2.5 ml) for 21 h. Working-up as in example 23, but reprecipitation of the product from chloroform in acetone/methanol (1:2). 1 430 mg of fibrous yellow solid which produces intense red luminescence under a UV lamp. Detection of complexing by ¹H NMR spectroscopy.

### Example 25

### Synthesis of a Red-Phosphorescing Polymer having Various Repeating Units of the General Formula A and Repeating Units of the General Formula B-I-6 (Ar¹=2,7-(9,9-di-n-octyl)fluorenyl and 2,5-diphenylene[13.4]oxadiazole, R⁴=hexyl, L=2-benzo[b]thiophen-2-yl-pyridine (bthpy))

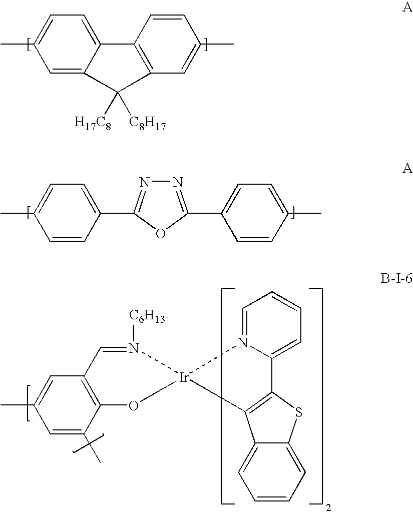

The random polyfluorene ligand terpolymer containing 2,7-(9,9′-di-n-octyl)-fluorene units A-1, diphenyloxadiazole units A-2 and 3,5-bridge uncomplexed salicyl-N-hexylimine units B-I-6 in the molar ratio 75 (A-1): 23 (A-2): 2 (B-1-6) (M_{w}=67 000 (D=2.17) (300 mg), (bthpy)₂Ir(μ-Cl)₂Ir(bthpy)₂ (16.9 mg) and sodium methanolate (1.4 mg) were heated under reflux under a nitrogen atmosphere in a mixture of chloroform (20 ml) and methanol (1 ml) for 15 h. Working-up as in example 23. 163 mg of fibrous yellow solid which produces intense red fluorescence under a UV lamp.

Detection of complexing by ¹H NMR spectroscopy.

Film emission spectrum: (λ_{exc}=399 nm): λ_{em,max}=619 nm.

### Example 26

### Synthesis of a Yellow-Phosphorescing Polymer of the General Formula C-1 (Ar¹=2,5-(1-ethylhexyloxy)phenylene, R⁴=hexyl, L=phenyl-2-pyridine (ppy))

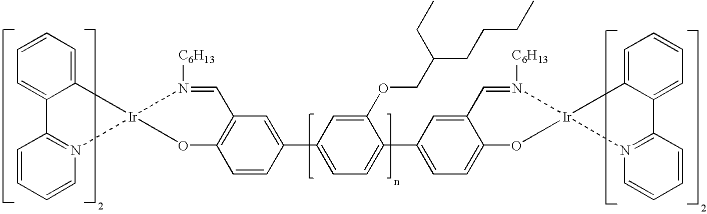 200 mg of ligand polymer containing about 5 mol % of terminal salicyl-N-hexylimine ligand groups (M_{w}=18 200; D=1.99), 25.6 mg (0.024 mmol) of (ppy)₂Ir(μ-Cl)₂Ir(ppy)₂ and 3 mg of sodium methanolate (0.055 mmol) in a mixture of 1 ml of methanol and 20 ml of chloroform. Duration of reaction 9 h under reflux. After working-up according to example 23, 130 mg of product were obtained (yellow powder).

The product produces intense yellow luminescence under a UV lamp (366 nrm). Characterization and detection of complexing by ¹H NMR (400 MHz in CDCl₃/TMS, 25° C.).

Film emission spectrum: (λ_{exc}=446 nm): λ_{em,max}=580 nm.

### Example 27

### Synthesis of a Green-Phosphorescing Polymer of the General Polymer C-3 (Ar¹=2,5-(1,4-dioctyloxy)phenylene, R⁵=methyl, L=4-fluoro-phenyl-2-pyridine (fpp))

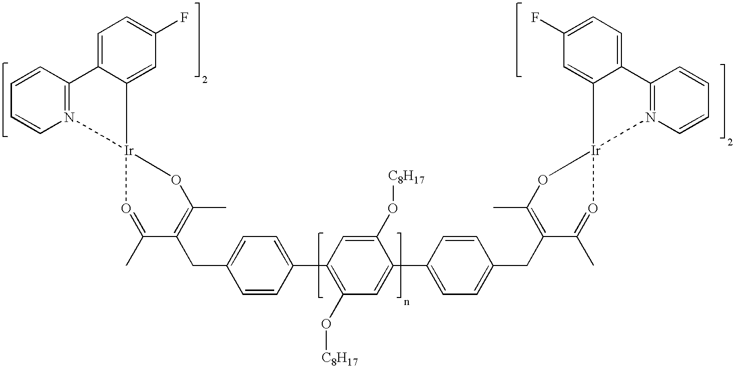 600 mg of ligand polymer containing about 2 mol % of terminal benzylacetylacetone ligand groups (M_{w}=22 100; D=1.86), 28 mg (0.024 mmol) of (fpP)₂Ir(μ-Cl)₂Ir(fpp)₂ and 2.7 mg of sodium methanolate (0.05 mmol) in a mixture of 1 ml of methanol and 30 ml of chloroform. Duration of reaction 26.5 h under reflux. After working-up according to example 23, 515 mg of product were obtained (yellow powder).

The product produces intense green luminescence under a UV lamp (366 nm). Characterization and detection of complexing by ¹H NMR (400 MHz in CDCl₃/TMS, 25° C.). Film emission spectrum: (λ_{exc}=362 nm): λ_{em, max}=502 nm, weak residual fluorescence from conjugated polymer at 422 nm.

### Example 28

The polymers according to the invention from examples 23 and 24 are each tested as an emitter layer in an OLED structure. The OLED structures are produced by the procedure according to example 20. For comparison, two OLED structures comprising pure polyfluorene which is blended with 0.95 mol % (comparison 1) or 1.9 mol % (comparison 2) of bis(2-benzo[b]thiophen-2-yl-pyridine)-iridium-salicyl-N-hexylimine) (bthpy)₂Ir(sal) are tested.

| | |
|---|---|
| 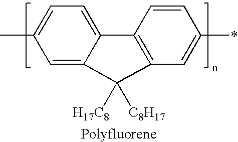 | 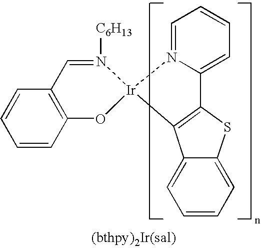 |

Result:

| Polymer | 1% | Thickness | Max. of | | | | | | |
|---|---|---|---|---|---|---|---|---|---|
| from | strength | of the | the EL | Colour | | | Current | EL | |
| example | solution | polymer layer | emission | coordinates | | Voltage | density | intensity | Efficiency |
| | | nm | nm | x | y | V | mA/cm² | cd/m² | cd/A |
| 23 | Toluene | 100 | 612 | 0.639 | 0.323 | 10.9 | 20.0 | 130 | 0.65 |
| 24 | Toluene | 100 | 623 | 0.656 | 0.321 | 9.5 | 8.2 | 98 | 1.2 |
| 24 | Toluene | 50 | 617 | 0.635 | 0.319 | 9.0 | 340 | 412 | 0.12 |
| Comparison 1 | Chloroform | 100 | 615 | 0.510 | 0.287 | 10.0 | 0.02 | <<1 | n.d. |
| Comparison 2 | Chloroform | 100 | 615 | 0.557 | 0.320 | 10.0 | 0.08 | <<1 | n.d. |

(n.d. = not determinable)

The results show that high EL intensities and high efficiencies are achieved with the phosphorescent polymers according to the invention in OLED structures. Furthermore, the results show that EL intensities and efficiencies can be varied by changing the layer thickness. Moreover, the results show that covalently bonded Ir complexes lead to substantially higher luminances at comparable voltages than molecular Ir complexes which were added as dopants to the same polymer matrix. The polymers (23, 24) according to the invention are therefore substantially more efficient than the polymers (comparisons 1 and 2) with molecular dopants.

1. Phosphorescent polymer, characterized in that it is conjugated and neutral and contains at least one covalently bonded phosphorescent metal complex.

2. Phosphorescent conjugated polymer according to claim 1, characterized in that it contains at least one phosphorescent metal complex covalently bonded by at least one ligand L¹ and the ligand L¹ represents units of the formulae I to XXIX 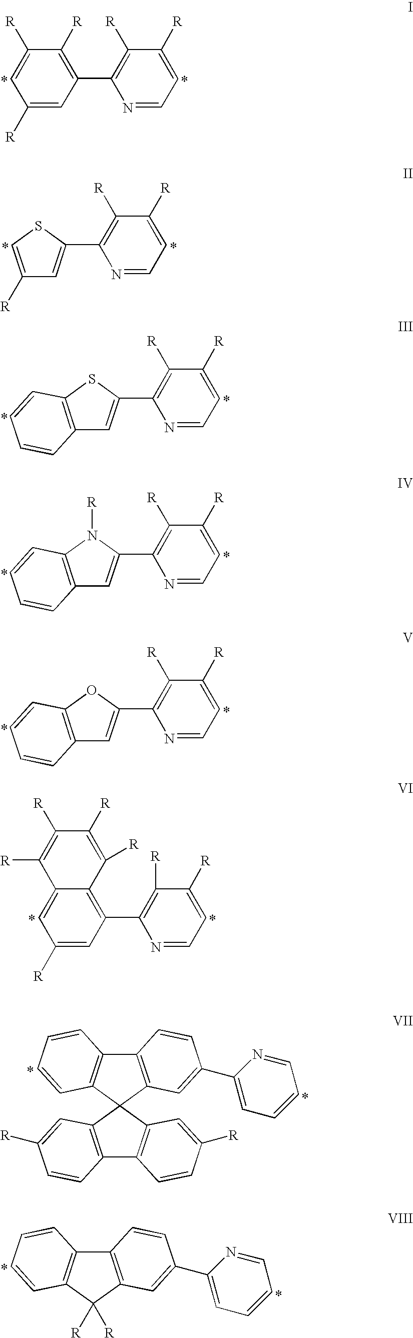 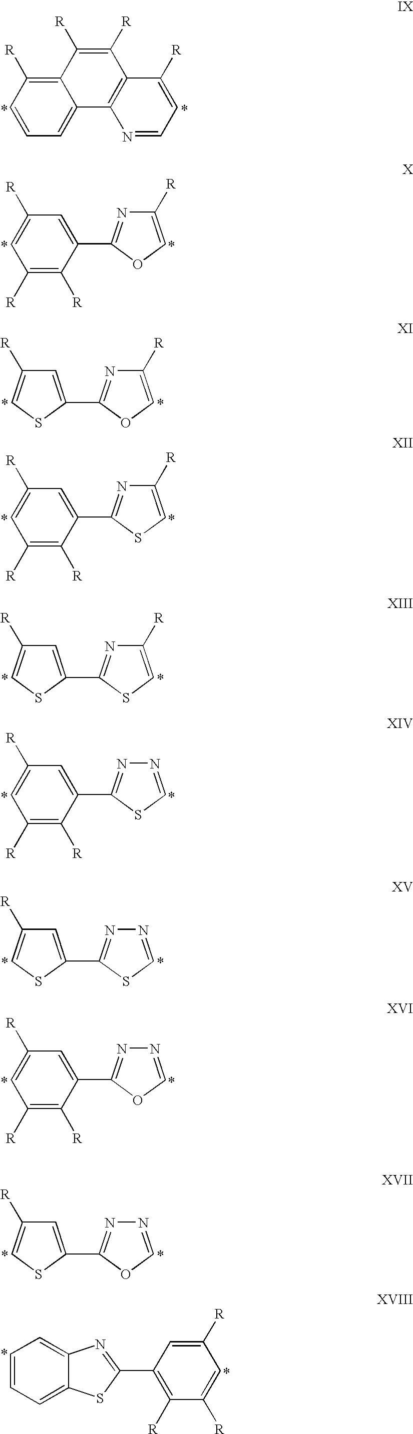 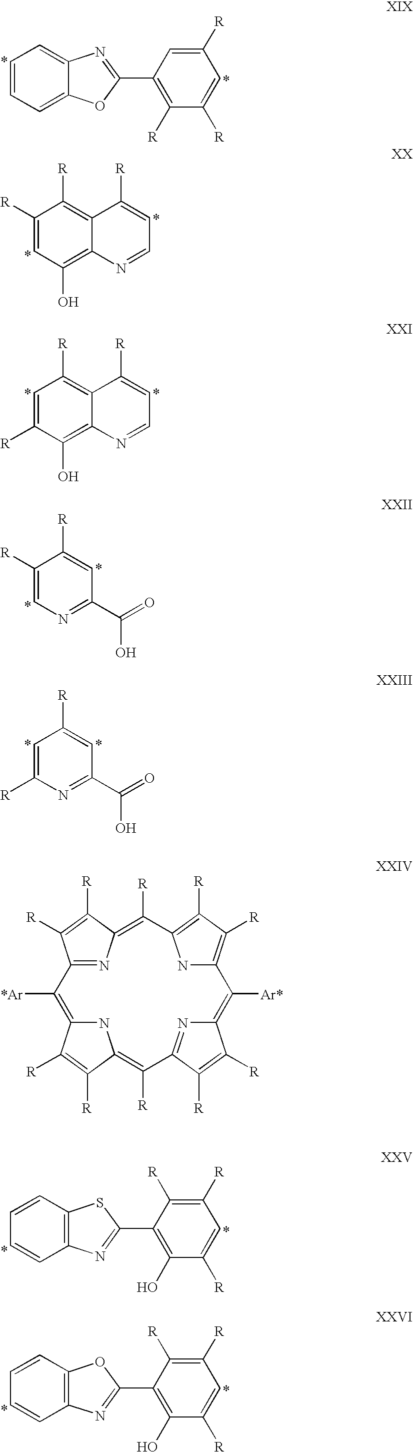 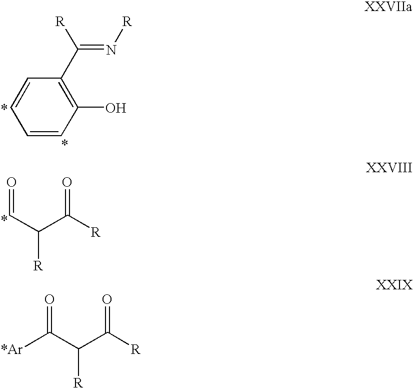
R are identical or different and, independently of one another, represent H, F, CF₃, a linear or branched C₁-C₂₂-alkyl group, a linear or branched C₁-C₂₂-alkoxy group, an optionally C₁-C₃₀-alkyl-substituted C₅-C₂₀-aryl unit and/or an optionally C₁-C₃₀-alkyl-substituted heteroaryl unit having 5 to 9 ring C atoms and 1 to 3 ring hetero atoms from the group consisting of nitrogen, oxygen and sulphur and
Ar represents optionally substituted phenylene, biphenylene, naphthylene, thienylene and fluorenylene units.

3. Phosphorescent conjugated polymer according to at least one of claims 1 and 2, characterized in that it contains repeating units of the general formulae A and B-Ia or A and B-II or has a structure of the general formulae C or D 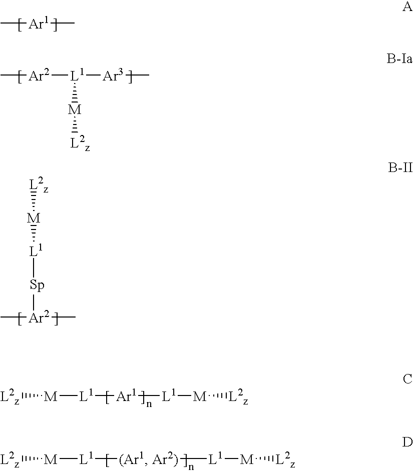
in which
Ar¹, Ar² and Ar³ are identical or different and, independently of one another, represent optionally C₁-C₃₀-alkyl-substituted C₅-C₂₀-aryl units and/or optionally C₁-C₃₀-alkyl-substituted heteroaryl units having 5 to 9 ring C atoms and 1 to 3 ring hetero atoms from the group consisting of nitrogen, oxygen and sulphur,
L¹ and L² are identical or different and
L¹ has one of the meanings stated in claim 2, in the case of structures B-II, C and D one of the two linkage positions being saturated by H, F, CF₃, a linear or branched C₁-C₂₂-alkyl group, a linear or branched C₁-C₂₂-alkoxy group, an optionally C₁-C₃₀-alkyl-substituted C₅-C₂₀-aryl unit and/or an optionally C₁-C₃₀-alkyl-substituted heteroaryl unit having 5 to 9 ring C atoms and 1 to 3 ring hetero atoms from the group consisting of nitrogen, oxygen and sulphur and
L² independently of L¹, has one of the meanings stated for L¹ in claim 2, the two linkage positions, independently of one another, being saturated by H, F, CF₃, a linear or branched C₁-C₂₂-alkyl group, a linear or branched C₁-C₂₂-alkoxy group, an optionally C₁-C₃₀-alkyl-substituted C₅-C₂₀-aryl unit and/or an optionally C₁-C₃₀-alkyl-substituted heteroaryl units having 5 to 9 ring C atoms and 1 to 3 ring hetero atoms from the group consisting of nitrogen, oxygen and sulphur,
the ligands L¹ and L² complex the metal M in a chelate-like manner,
M represents iridium(II), platinum(II), osmium(II) or gallium(III),
n represents an integer from 3 to 10 000,
z represents an integer from 0 to 3 and
Sp is a spacer, in particular a linear or branched C₂-C₁₅-alkylene unit or a C₂-C₁₅-heteroalkylene unit having 1 to 3 chain hetero atoms from the group consisting of nitrogen, oxygen and sulphur, a C₅-C₂₀-arylene unit and/or a heteroarylene unit having 5 to 9 ring C atoms and 1 to 3 ring hetero atoms from the group consisting of nitrogen, oxygen and sulphur or a C₁-C₁₂-alkylenecarboxylic acid or C₁-C₁₂-alkylenedicarboxylic acid or a C₁-C₁₂-alkylenecarboxamide or a C₁-C₁₂-alkylenedicarboxamide unit.

4. Phosphorescent conjugated polymer in at least one of claims 1 to 3, characterized in that it contains repeating units of the general formulae A and B-Ia or A and B-II or has a structure of the general formulae C or D
in which
Ar¹, Ar² and Ar³ are identical or different and, independently of one another, represent thiophene units of the formula XXX and XXXI, benzene, biphenyl and fluorene units of the formulae XXXII to XXXIV and/or heterocycles of the formulae XXXV to 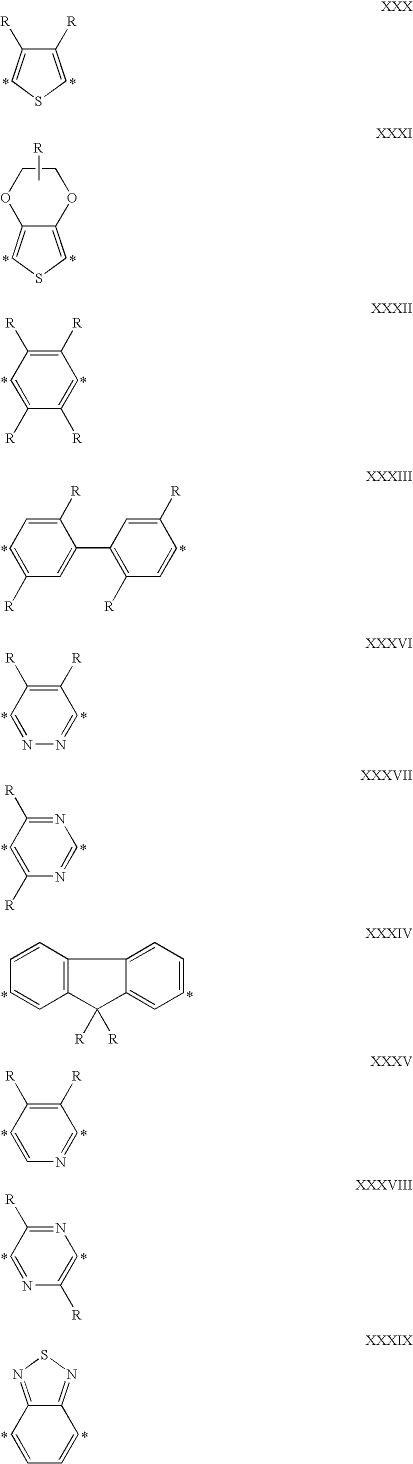 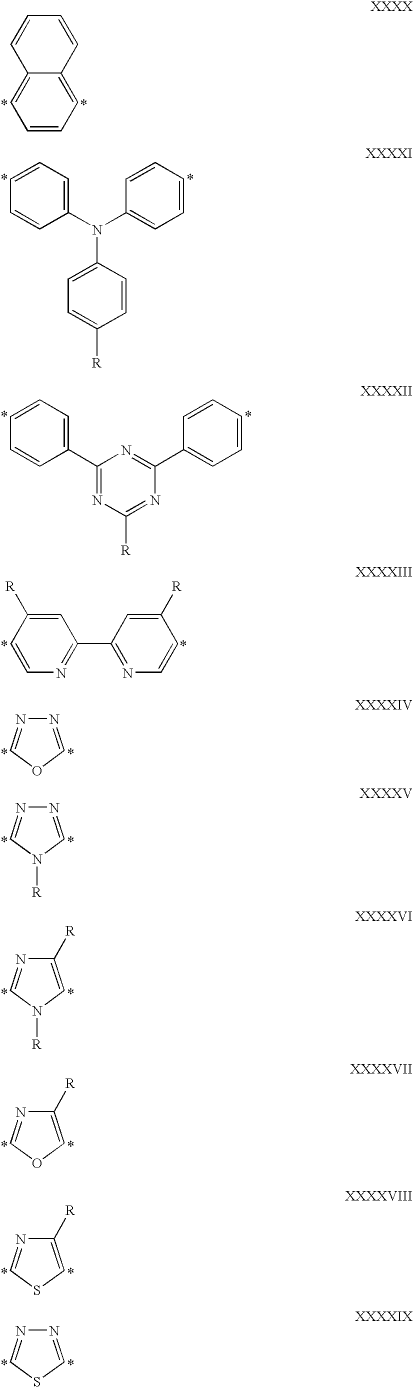 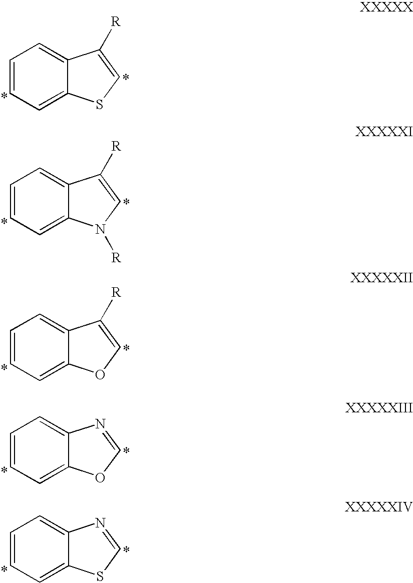
in which
R are identical or different and, independently of one another, represent H, F, CF₃, a linear or branched C₁-C₂₂-alkyl group, a linear or branched C₁-C₂₂-alkoxy group, an optionally C₁-C₃₀-alkyl-substituted C₅-C₂₂-aryl unit and/or an optionally C₁-C₃₀-alkyl-substituted heteroaryl unit having 5 to 9 ring C atoms and 1 to 3 ring hetero atoms from the group consisting of nitrogen, oxygen and sulphur.

5. Phosphorescent conjugated polymer in at least one of claims 1 to 4, characterized in that it contains repeating units of the general formulae A and B-Ia or A and B-II or a structure of the general formulae C or D
in which
Ar¹, Ar² and Ar³ are identical or different and, independently of one another, represent thiophene units of the formulae XXX and XXXI and benzene, biphenyl and fluorene units of the formulae XXXII to XXXIV 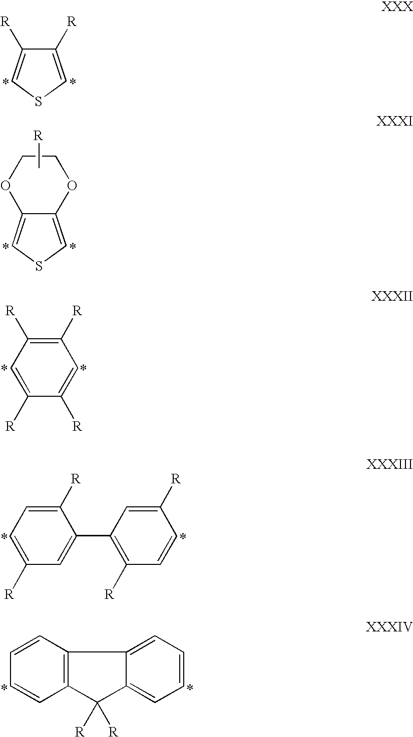
L¹ and L² are units selected from the formulae I, II, III, VIII, XVIII, XX, XXI, XXIV, XXVII, XXVIII and XXIX and

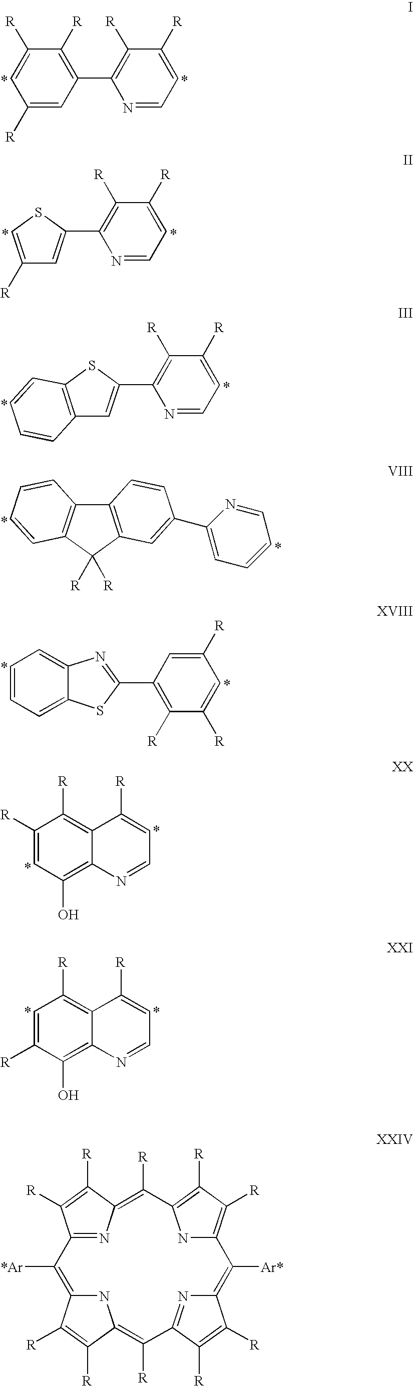

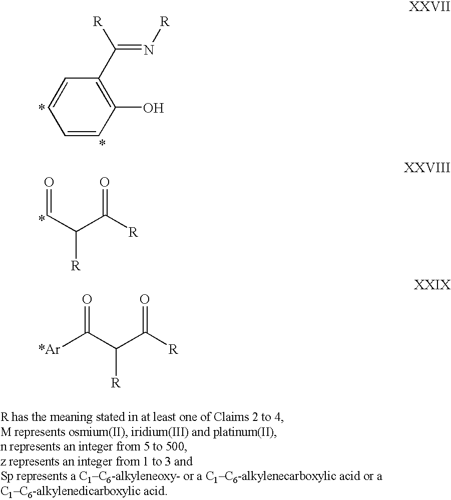

6. Phosphorescent conjugated polymer according to at least one of claims 1 to 5, characterized in that it contains repeating units selected from the following general formulae A and B-I-1 to B-I-5 or A and B-II-1 and B-II-4 or has a structure of the general formulae C-1 and C-2

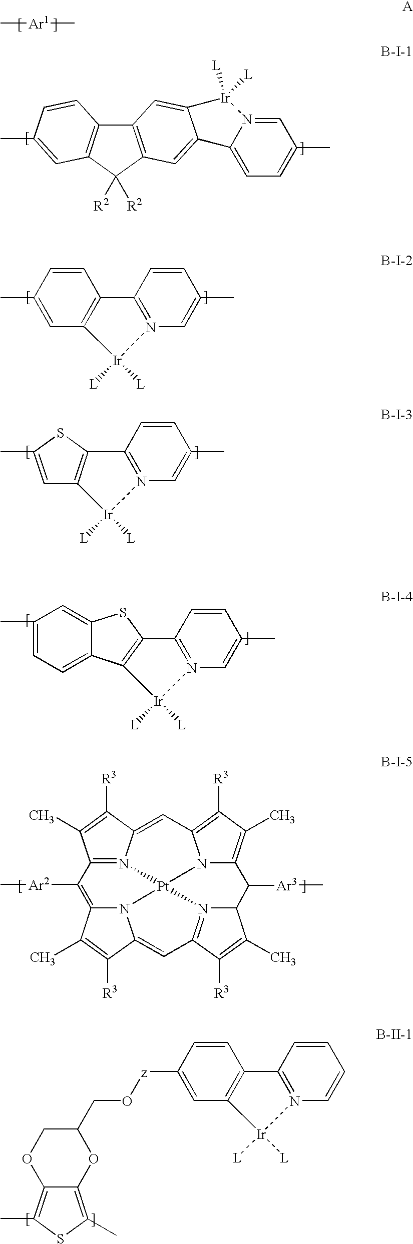

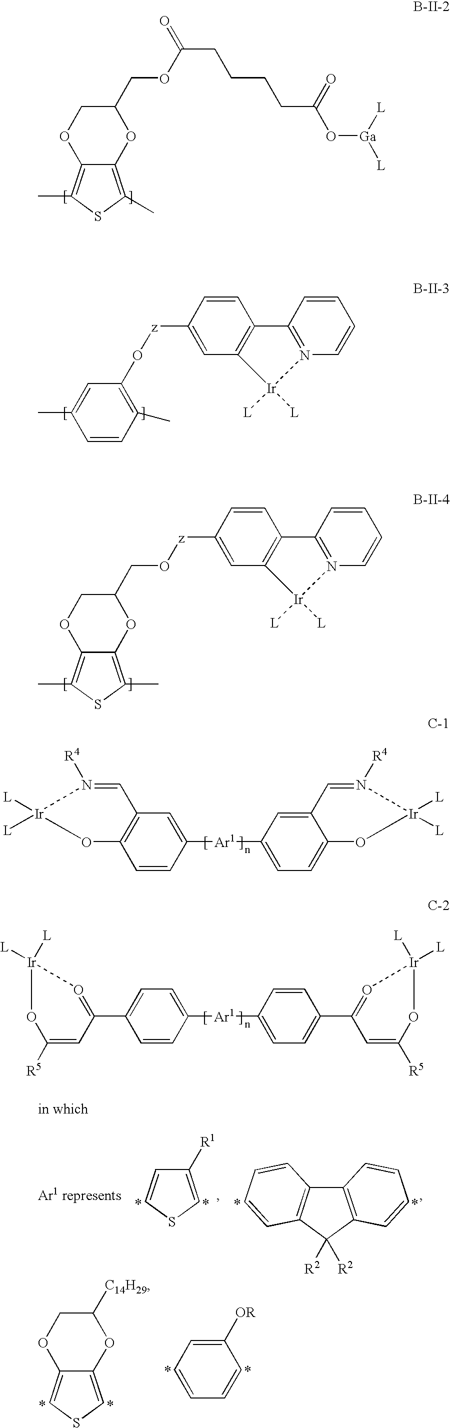

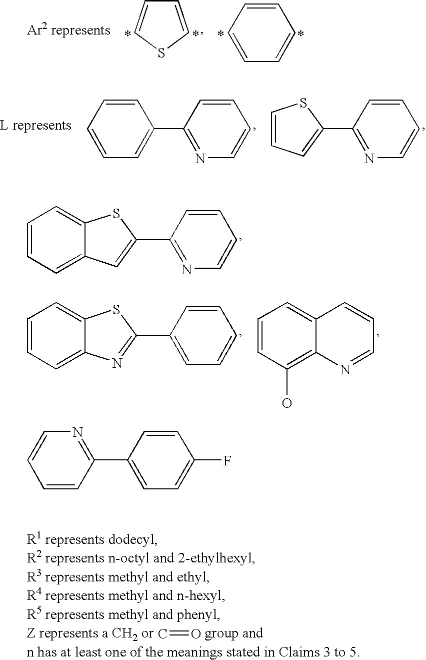

7. Phosphorescent conjugated polymer according to claim 1, characterized in that it contains at least one phosphorescent metal complex covalently bonded via at least one ligand L¹ and
the ligand L¹ represents units of the formulae I to XXIXc 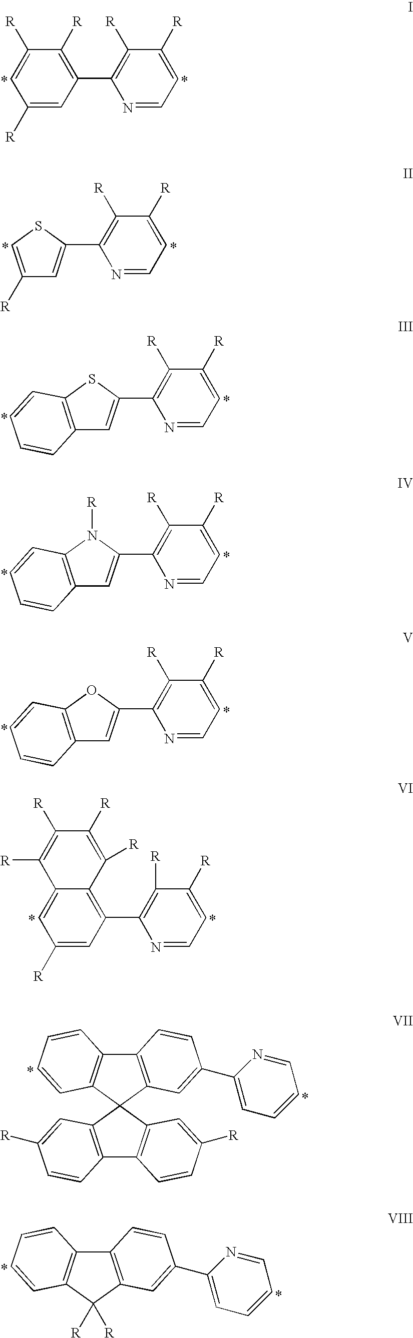 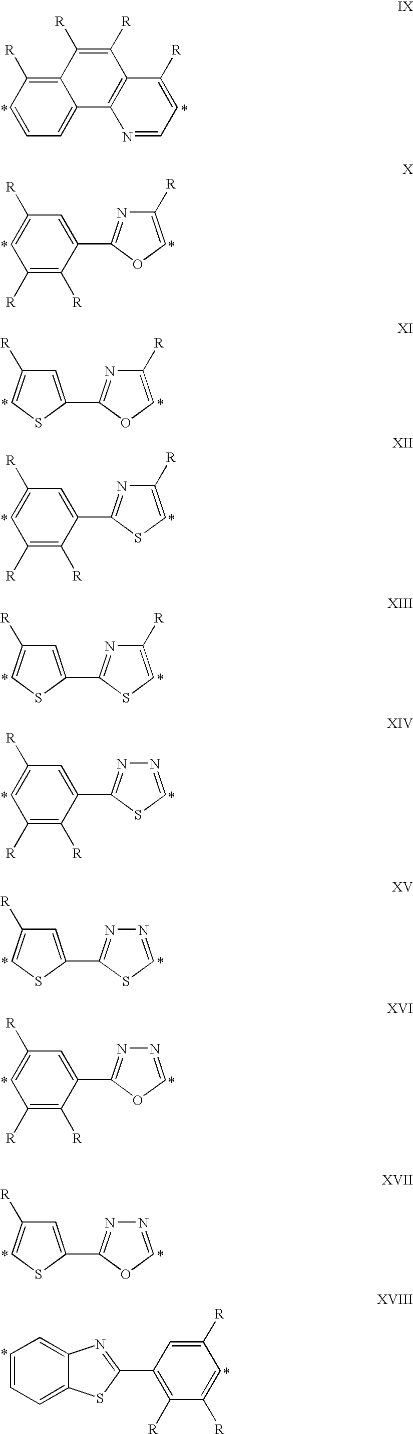 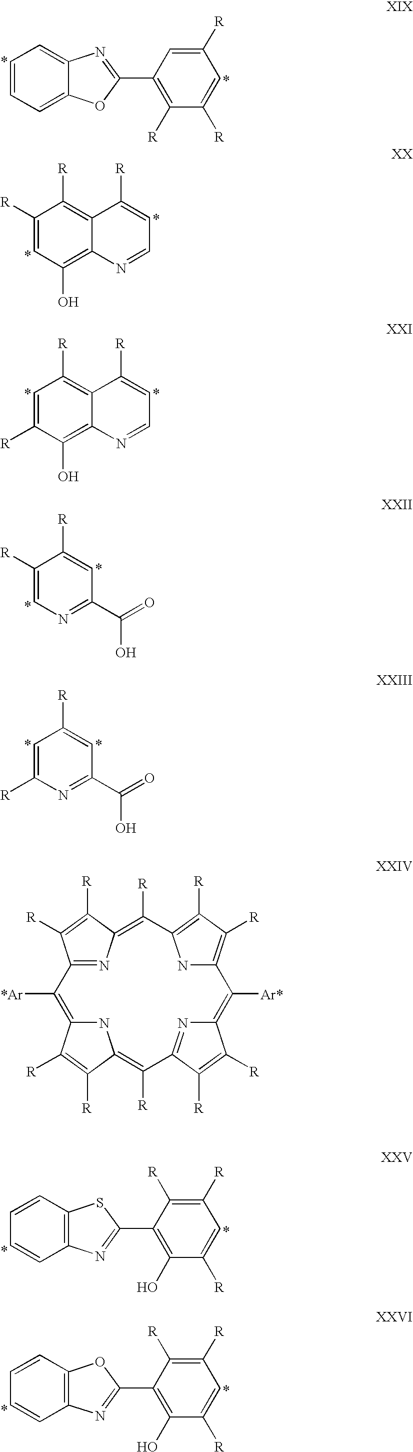 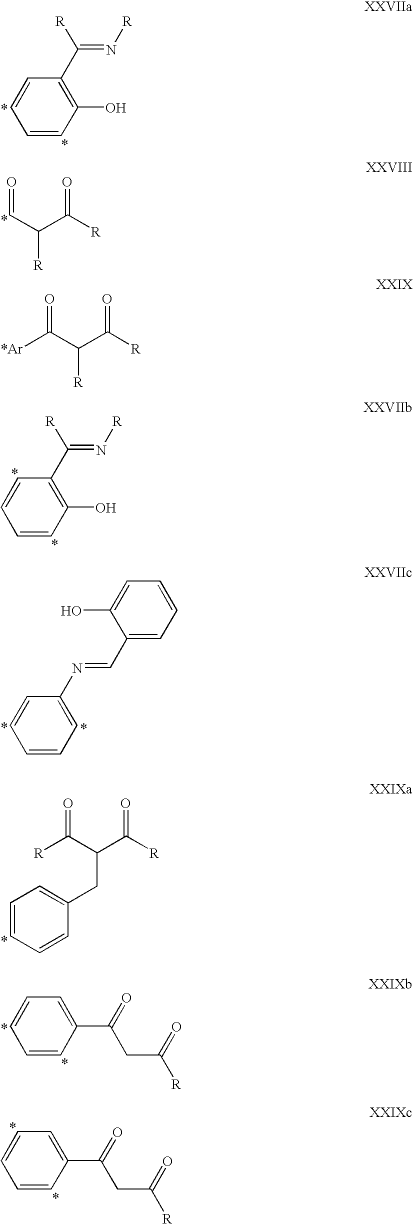
R are identical or different and, independently of one another, represent H, F. CF₃, a linear or branched C₁-C₂₂-alkyl group, a linear or branched C₁-C₂₂-alkoxy group, an optionally C₁-C₃₀-alkyl-substituted C₅-C₂₀-aryl unit and/or an optionally C₁-C₃₆-alkyl-substituted heteroaryl unit having 5 to 9 ring C atoms and 1 to 3 ring hetero atoms from the group consisting of nitrogen, oxygen and sulphur and/or represent a linear or branched partly fluorinated or perfluorinated C₁-C₂₂-alkyl group, a linear or branched C₁-C₂₂-alkoxycarbonyl group, a cyano group, a nitro group, an amino group, an alkylamino, dialkylamino, arylamino, diarylamino or alkylarylamino group or represent an alkyl- or arylcarbonyl group, alkyl denoting C₁-C₃₀-alkyl and aryl denoting C₅-C₂₀-aryl, and
Ar represents optionally substituted phenylene, biphenylene, naphthylene, thienylene and/or fluorenylene units.

8. Phosphorescent conjugated polymer according to at least one of claims 1 and 7, characterized in that it contains repeating units of the general formulae A and B-Ia, A and B-Ib or A and B-II or has a structure of the general formulae C or D 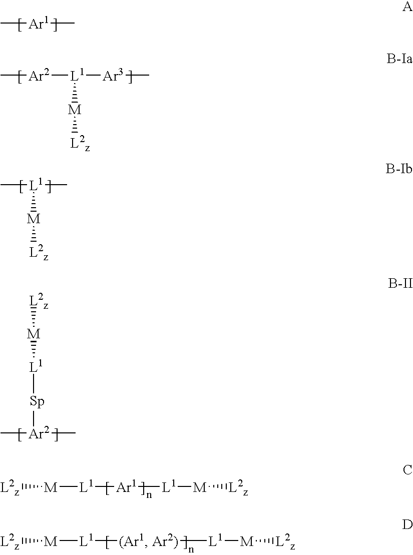
in which
Ar¹, Ar² and Ar³ are identical or different and, independently of one another, represent optionally C₁-C₃₀-alkyl-substituted C₅-C₂₀-aryl units and/or optionally C₁-C₃₀-alkyl-substituted heteroaryl units having 5 to 9 ring C atoms and 1 to 3 ring hetero atoms from the group consisting of nitrogen, oxygen and sulphur,
L¹ and L² are identical or different and
L¹ has one of the abovementioned meanings, in the case of structures B-II, C and D one of the two linkage positions being saturated by H, F, CF₃, a linear or branched C₁-C₂₂-alkyl group, a linear or branched C₁-C₂₂-alkoxy group, an optionally C₁-C₃₀-alkyl-substituted C₅-C₂₀-aryl unit and/or an optionally C₁-C₃₀-alkyl-substituted heteroaryl unit having 5 to 9 ring C atoms and 1 to 3 ring hetero atoms from the group consisting of nitrogen, oxygen and sulphur and/or by a linear or branched, partly fluorinated or perfluorinated C₁-C₂₂-alkyl group, a linear or branched C₁-C₂₂-alkoxycarbonyl group, a cyano group, a nitro group, an amino group, an alkylamino, dialkylamino; arylamino, diarylamino or alkylarylamino group or by an alkyl- or arylcarbonyl group, alkyl denoting C₁-C₃₀-alkyl and aryl denoting C₅-C₄₀-aryl, and
L², independently of L¹, has one of the meanings mentioned above for L¹, the two linkage positions independently of one another being saturated by H, F, CF₃, a linear or branched C₁-C₂₂-alkyl group, a linear or branched C₁-C₂₂-alkoxy group, an optionally C₁-C₃₀-alkyl-substituted C₅-C₂₀-aryl unit and/or an optionally C₁-C₃₀-alkyl-substituted heteroaryl unit having 5 to 9 ring C atoms and 1 to 3 ring hetero atoms from the group consisting of nitrogen, oxygen and sulphur and/or by a linear or branched, partly fluorinated or perfluorinated C₁-C₂₂-alkyl group, a linear or branched C₁-C₂₂-alkoxycarbonyl group, a cyano group, a nitro group, an amino group, an alkylamino, dialkylamino, arylamino, diarylamino or alkylarylamino group or by an alkyl- or arylcarbonyl group, alkyl denoting C₁-C₃₀-alkyl and aryl denoting C₅-C₂₀-aryl, and linkage positions being understood as meaning the positions marked with * in the formulae I to XXIX,
the ligands L¹ and L² complex the metal M in a chelate-like manner,
M represents iridium(III), platinum(II), osmium(II), gallium(III) or rhodium(III),
n represents an integer from 3 to 10 000,
z represents an integer from 0 to 3 and
Sp is a spacer, in particular a linear or branched C₂-C₁₅-alkylene unit or a C₂-C₁₅-heteroalkylene unit having 1 to 3 chain hetero atoms from the group consisting of nitrogen, oxygen and sulphur, a C₅-C₂₀-arylene unit and/or a heteroarylene unit having 5 to 9 ring C atoms and 1 to 3 ring hetero atoms from the group consisting of nitrogen, oxygen and sulphur, or a C₁-C₁₂-alkylenecarboxylic acid unit or C₁-C₁₂-alkylenedicarboxylic acid unit or a C₁-C₁₂-alkylenecarboxamide unit or a C₁-C₁₂-alkylenedicarboxamide unit.

9. Phosphorescent conjugated polymer according to at least one of claims 1, 7 or 8, characterized in that it contains repeating units of the general formulae A and B-Ia, A and B-Ib or A and B-II or has a structure of the general formulae C or D,
in which
Ar¹, Ar² and Ar³ are identical or different and, independently of one another, represent thiophene units of the formulae XXX and XXI, benzene, biphenyl and fluorene units of the formulae XXXII to XXXIV and/or heterocycles of the formulae XXXV to XXXXXIV and/or units of the formulae XXXXXV to XXXXXXIII, 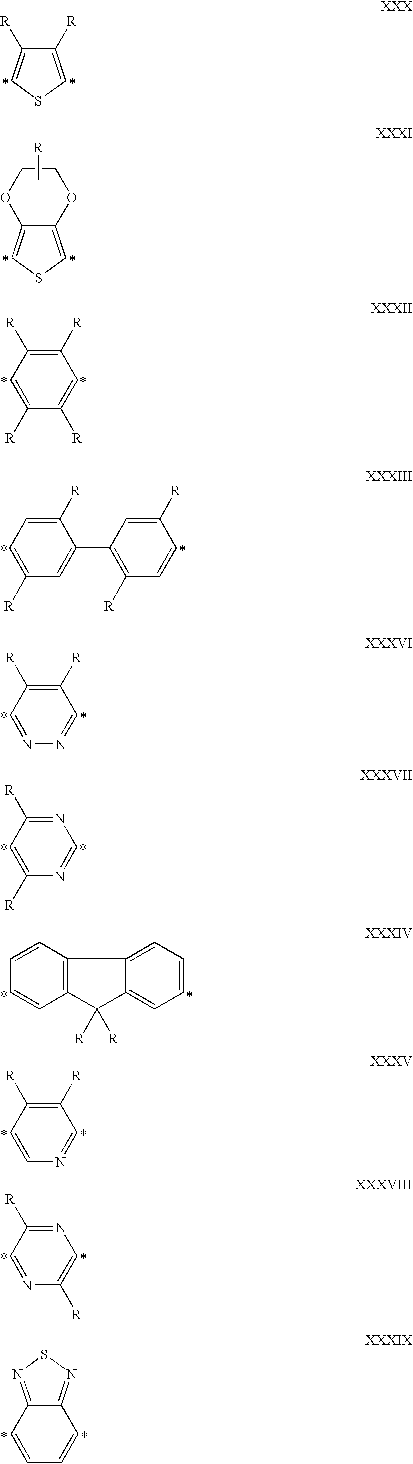 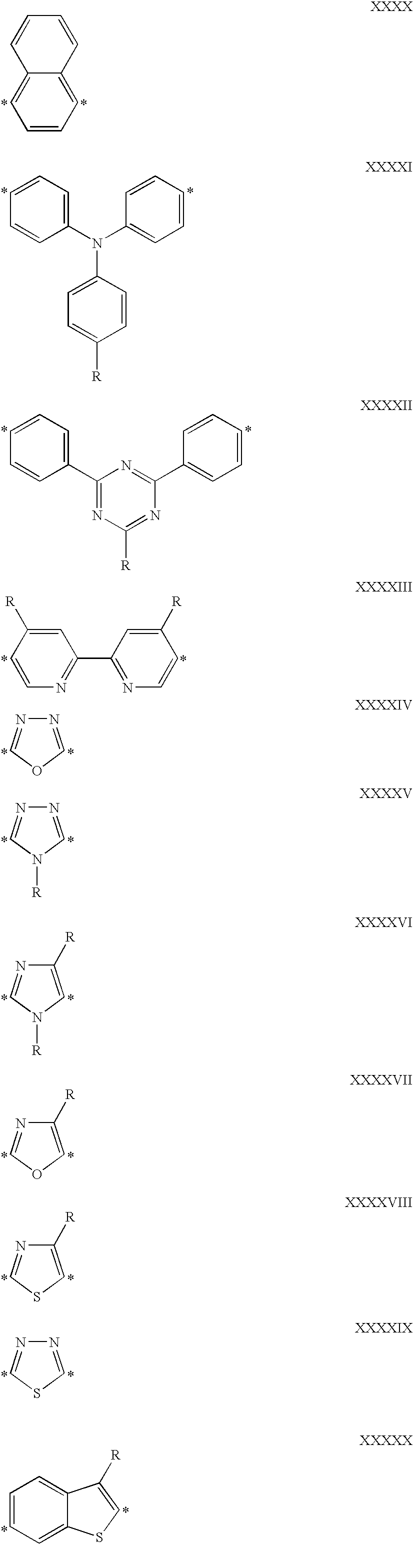 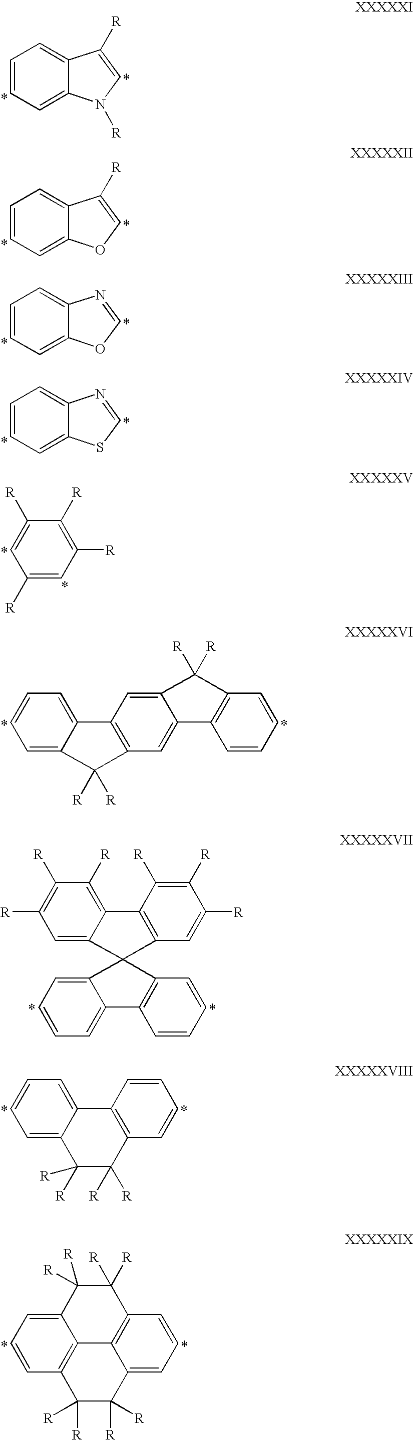 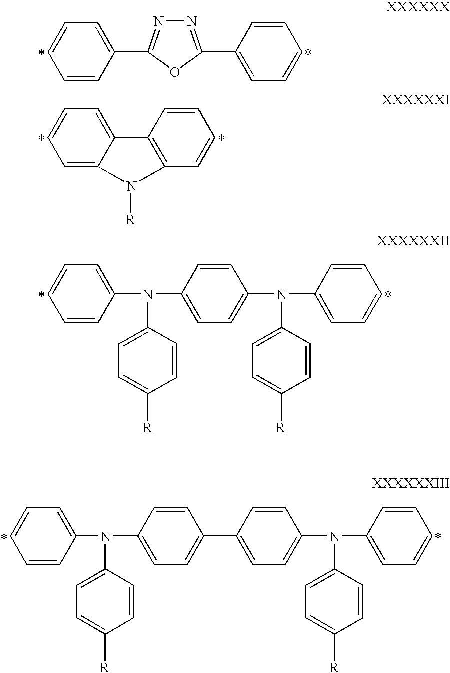
in which
R are identical or different and, independently of one another, represent H, F, CF₃, a linear or branched C₁-C₂₂-alkyl group, a linear or branched C₁-C₂₂-alkoxy group, an optionally C₁-C₃₀-alkyl-substituted C₅-C₂₀-aryl unit and/or an optionally C₁-C₃₀-alkyl-substituted heteroaryl unit having 5 to 9 ring C atoms and 1 to 3 ring hetero atoms from the group consisting of nitrogen, oxygen and sulphur and/or represent a linear or branched, partly fluorinated or perfluorinated C₁-C₂-alkyl group, a linear or branched C₁-C₂₂-alkoxycarbonyl group, a cyano group, a nitro group, an amino group, an alkylamino, dialkylamino, arylamino, diarylamino or alkylarylamino group or represent an alkyl- or arylcarbonyl group, alkyl denoting C₁-C₃₀-alkyl and aryl denoting C₅-C₂₀-aryl.

10. Phosphorescent conjugated polymer according to at least one of claims 1 or 7 to 9, characterized in that it contains repeating units selected from the following general formulae A and B-I-1 to B-I-6 or A and B-II-1 to B-II-4 or has a structure of the general formulae C-1, C-2 or C-3 or D-1, D-2 or D3

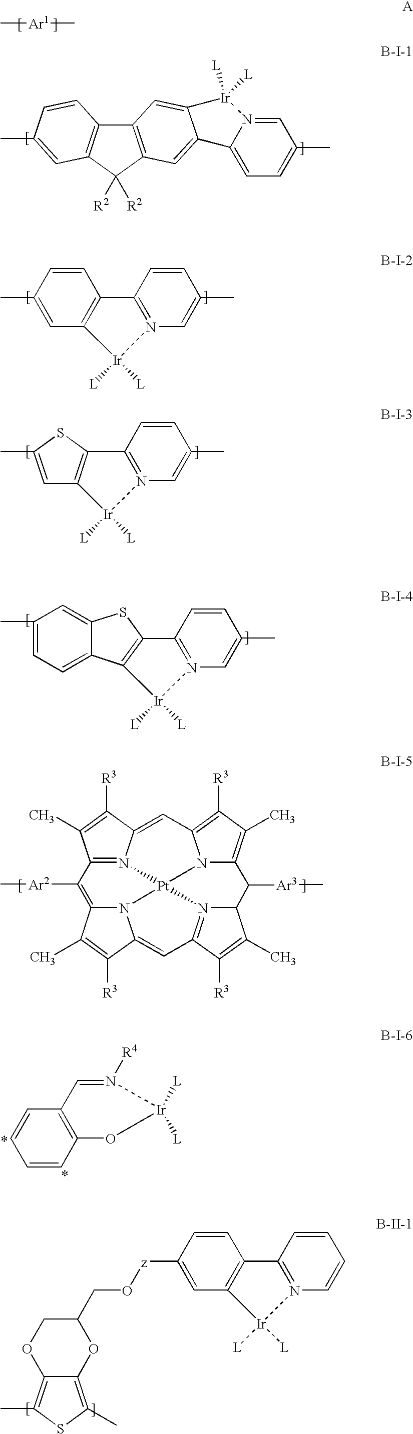

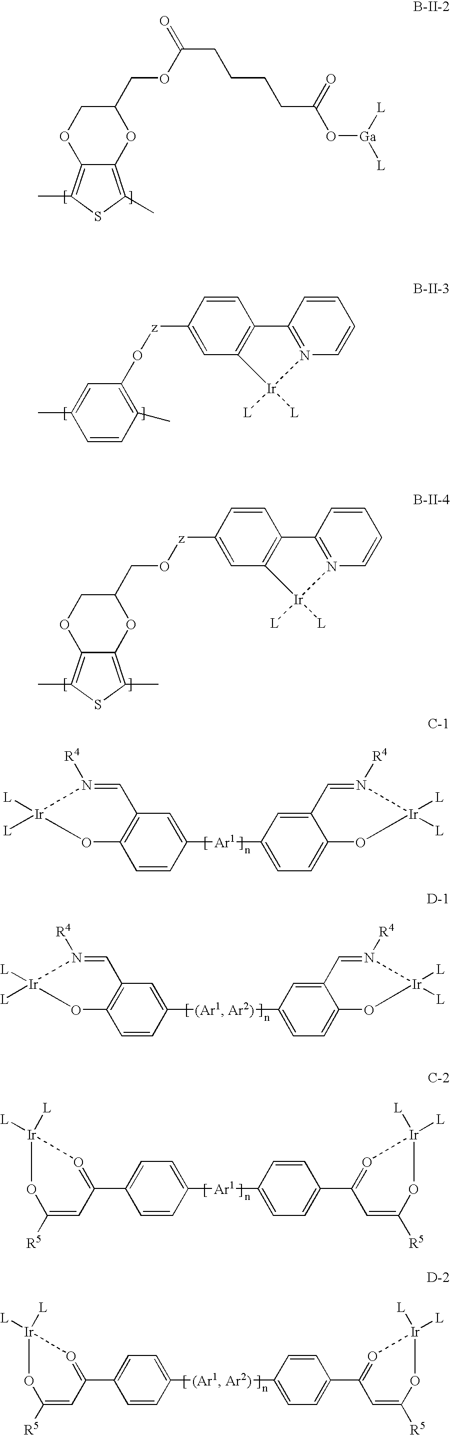

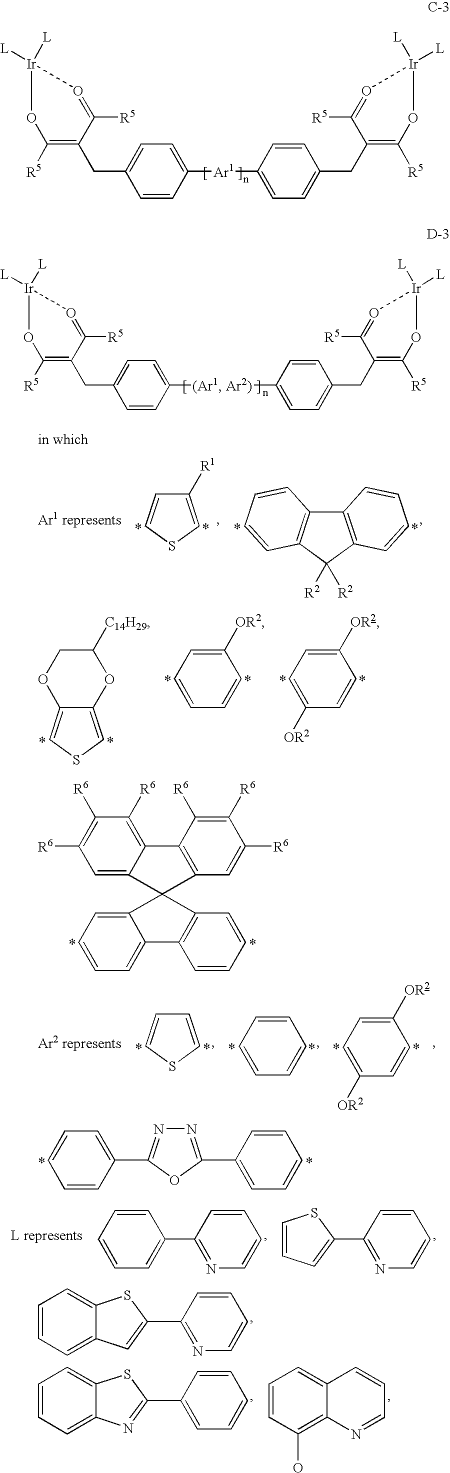

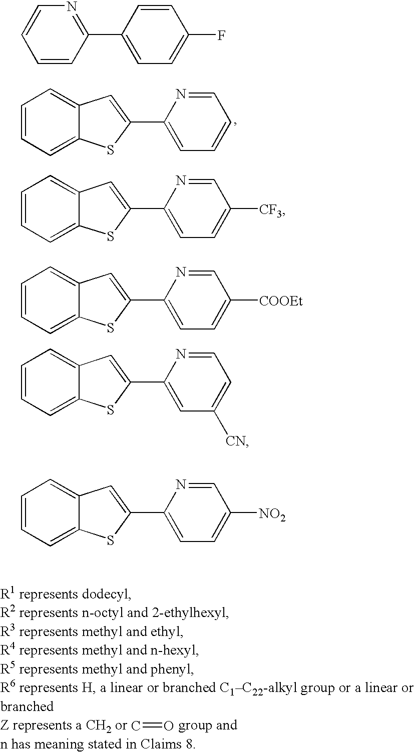

11. Luminescent polymer, characterized in that it has a conjugated main chain and contains at least one covalently bonded metal complex, the luminescence being a combination of the fluorescence of the conjugated main chain and of the phosphorescence of the covalently bonded metal complex or complexes.

12. Luminescent polymer according to claim 11, characterized in that it emits white light.

13. Luminescent polymer according to claim 11 or 12, characterized in that it emits light which is defined by a colour location of x=0.33±0.13 and y=0.33±0.13 in the chromaticity diagram according to CIE 1931.

14. Luminescent polymer according to at least one of claims 11 to 13, characterized in that the metal complex or complexes, which may be identical or different, is or are covalently bonded to the chain ends of the conjugated main chain.

15. Luminescent polymer according to claim 14, characterized in that it has a structure of the general formula (Ia) or (Ib) 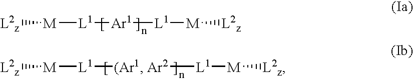
in which
Ar¹ represents optionally substituted phenylene units (IIa) or (IIb), biphenylene units (IIc), fluorenylene units (IId), dihydroindenofluorenylene units (Hie), spirobifluorenylene (IIf), dihydrophenanthrylene units (IIg) or tetrahydropyrenylene units (IIh) 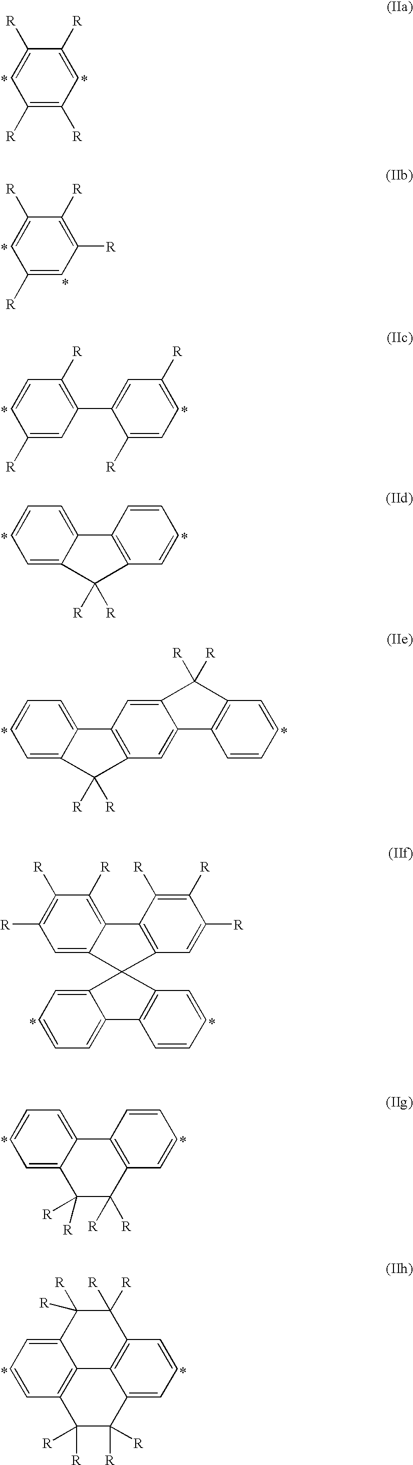
Ar² differs from Ar¹ and represents units selected from (IIa) to (IIq) 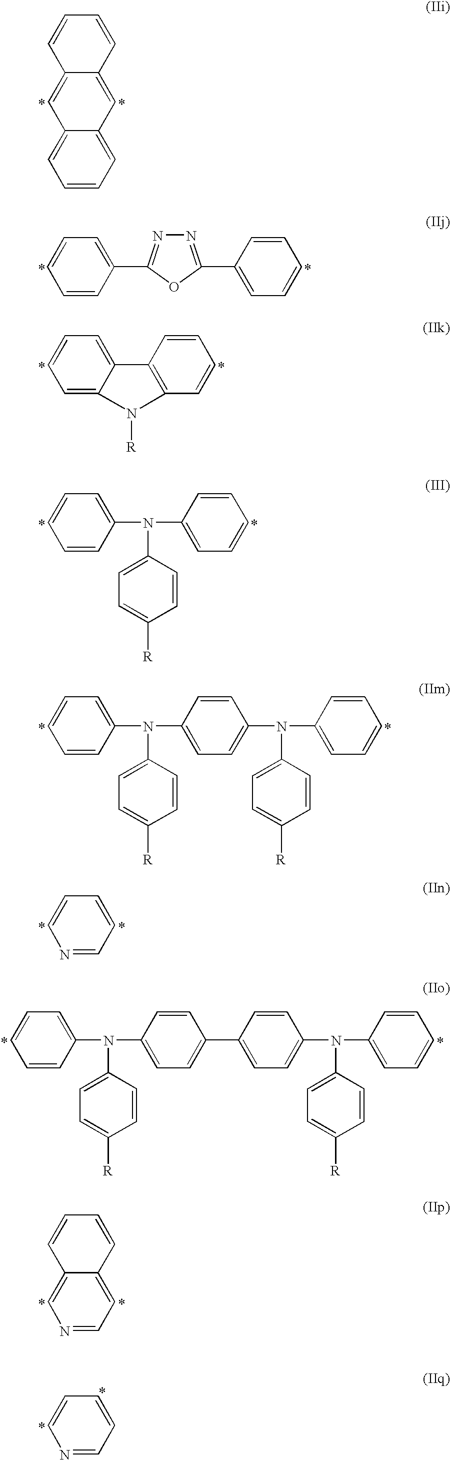
L¹ and L² in each case are identical or different and
L¹ is a ligand of the formulae (IIIa-1) to (IIId-1) 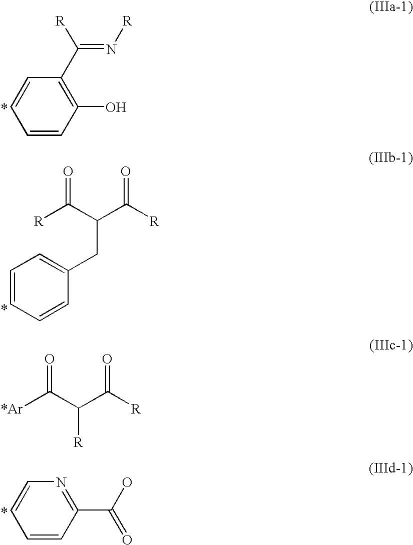
in which
Ar represents optionally substituted phenylene, biphenylene, naphthylene, thienylene or fluorenylene units,
L² independently of L¹, is a ligand selected from units of the formulae (IVa-1) to (IVy-1) 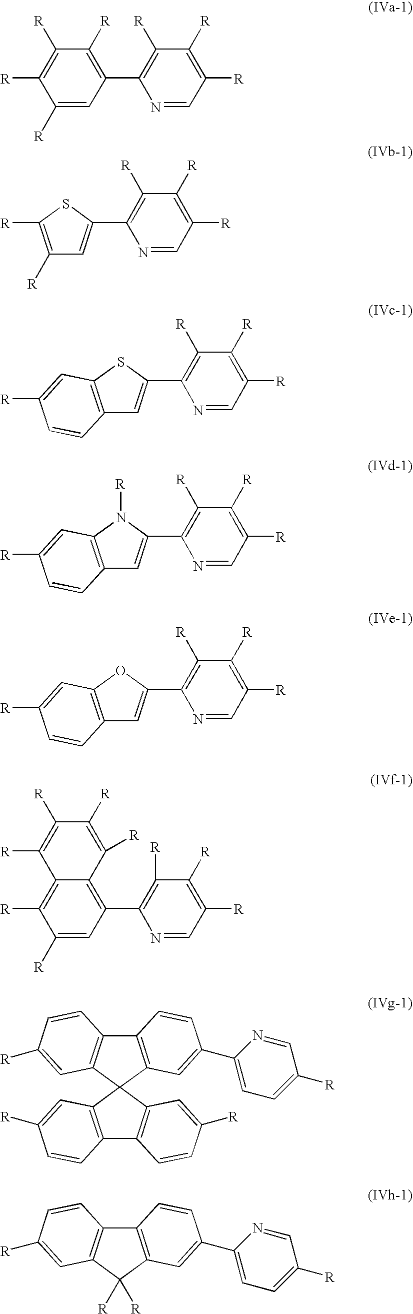 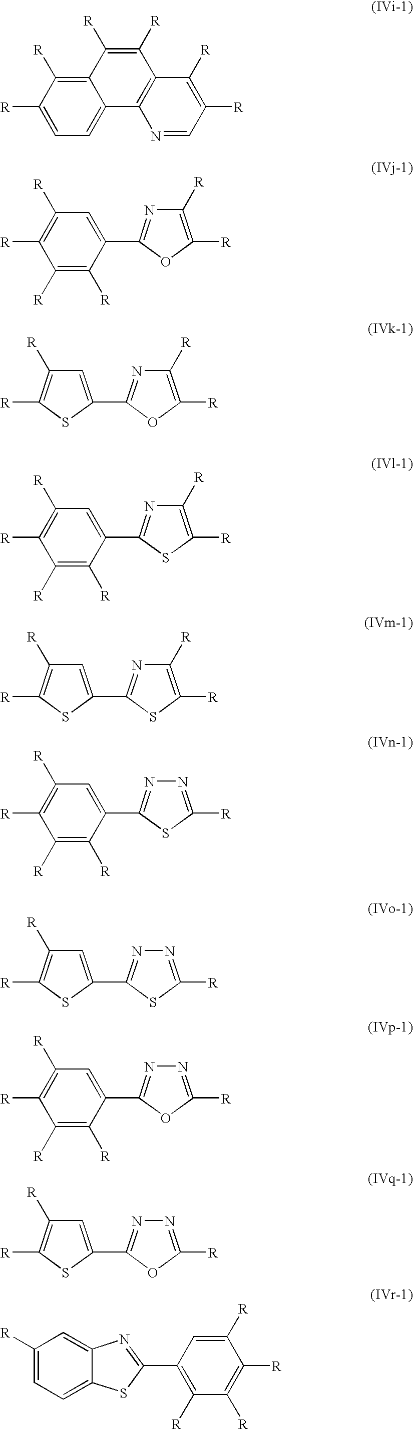 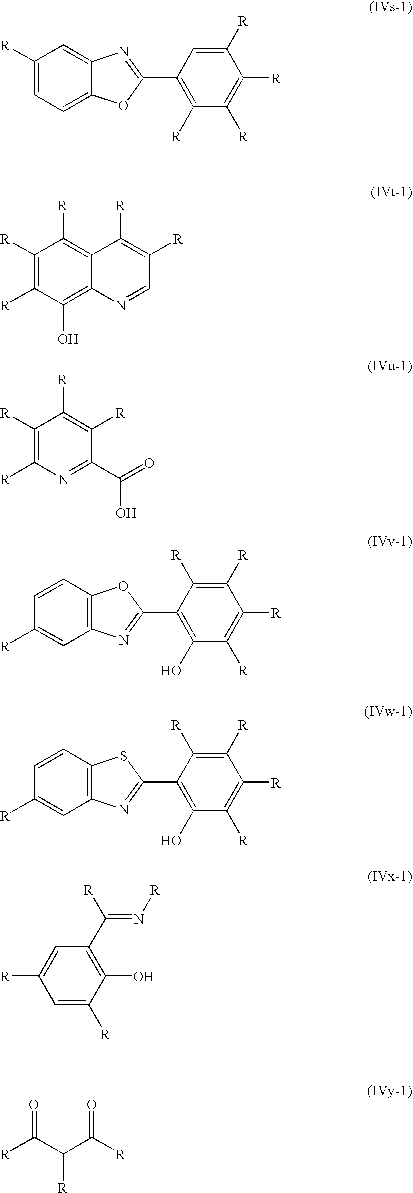
the ligands L¹ and L² complex the metal M in a chelate-like manner,
M represents iridium(III), platinum(II), osmium(II) or rhodium(III),
n represents an integer from 3 to 10 000,
z is an integer from 1 to 3 and
R are identical or different radicals and, independently of one another, represent, H, F, CF₃, a linear or branched C₁-C₂₂-alkyl group, a linear or branched partly fluorinated or perfluorinated C₁-C₂₂-alkyl group, a linear or branched C₁-C₂₂-alkoxy group, an optionally C₁-C₃₀-alkyl-substituted C₅-C₂₀-aryl unit and/or an optionally C₁-C₃₀-alkyl-substituted heteroaryl unit having 5 to 9 ring C atoms and 1 to 3 ring hetero atoms from the group consisting of nitrogen, oxygen and sulphur.

16. Luminescent polymer according to at least one of claims 14 and 15, characterized in that it has a structure of the general formulae (Ia-1) to (Ib-2) 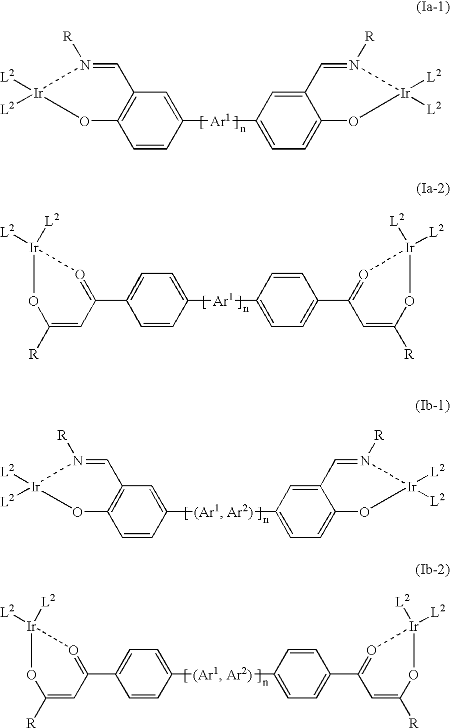
in which
R represents a linear or branched C₁-C₂₂-alkyl group or a linear or branched partly fluorinated or perfluorinated C₁-C₂₂-alkyl group and
n, Ar¹, Ar² and L² have the meaning stated in claim 15.

17. Luminescent polymer according to at least one of claims 14 and 15, characterized in that it has a structure of the general formulae (Ia-3) or (Ib-3) 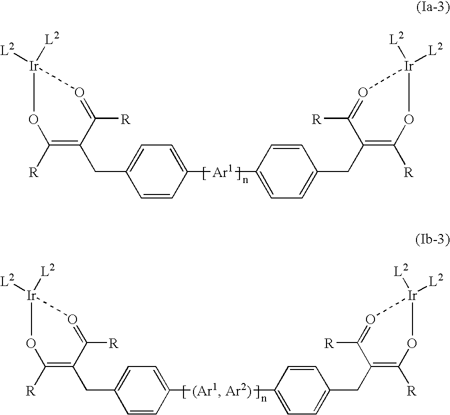
in which
R represents a linear or branched C₁-C₂₂-alkyl group or a linear or branched partly fluorinated or perfluorinated C₁-C₂₂-alkyl group and
n, Ar¹, Ar² and L² have the meaning stated in claim 15.

18. Luminescent polymer according to at least one of claims 11 to 13, characterized in that the metal complex or complexes, which may be identical or different, is or are covalently bonded to the conjugated main chain.

19. Luminescent polymer according to claim 18, characterized in that it contains n repeating units of the general formulae (Ic-1) and (Id) or (Ic-1), (Ic-2) and (Id) 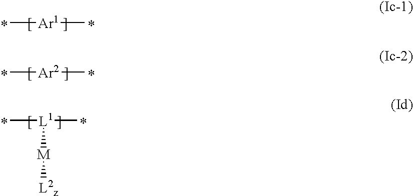
in which
Ar¹ represents optionally substituted phenylene units (IIa) or (IIb), biphenylene units (IIc), fluorenylene units (IId), dihydroindenofluorenylene units (IIe), spirobifluorenylene units (IIf), dihydrophenanthrylene units (IIg) or tetrahydropyrenylene units (IIh) 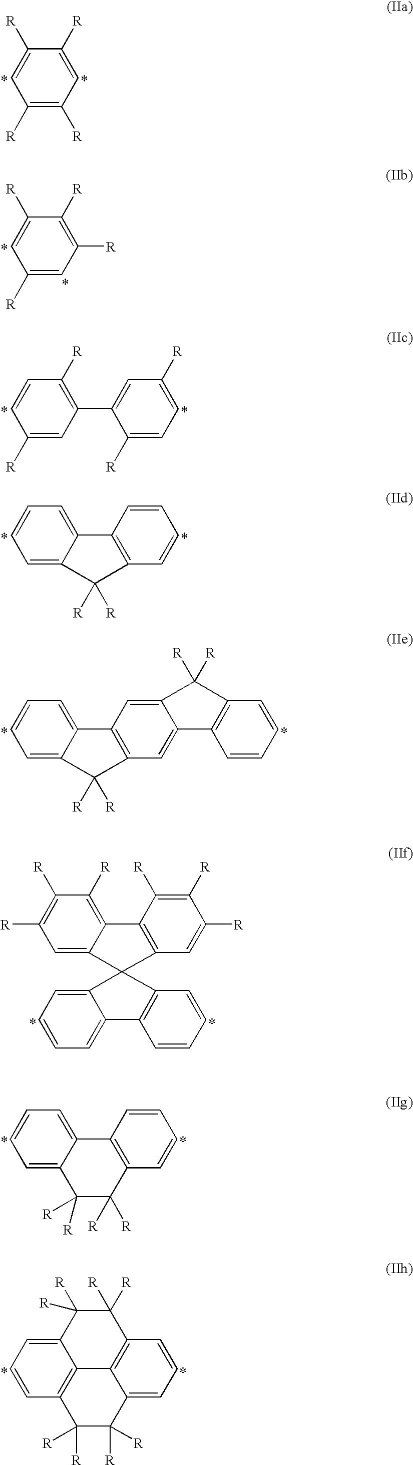
Ar² differs from Ar¹ and represents units selected from (IIa) to (IIq) 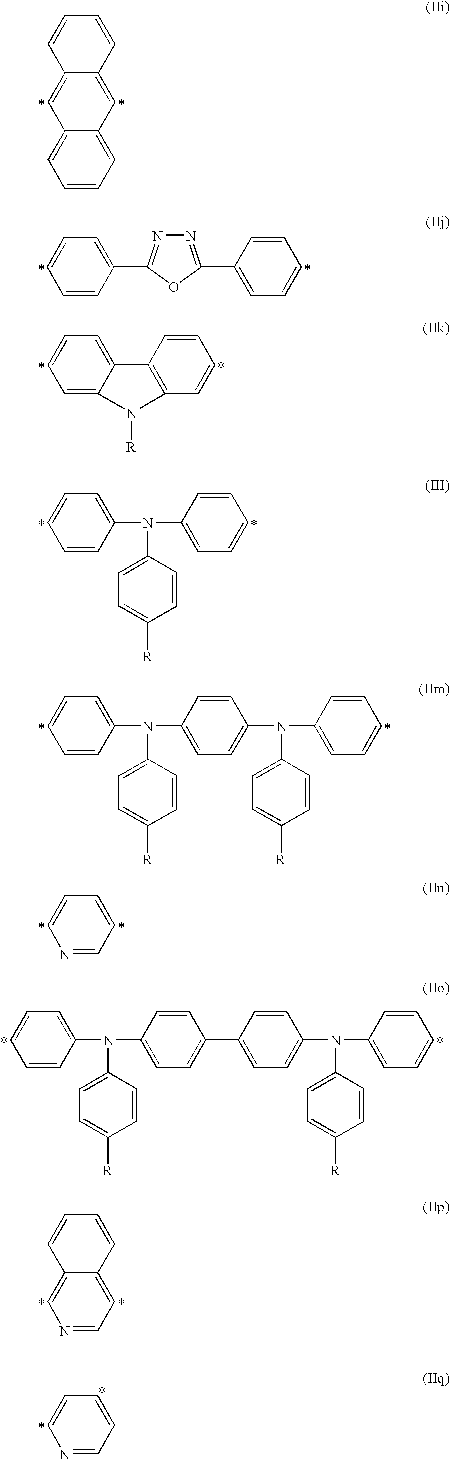
L¹ and L² in each case are identical or different and
L¹ is a ligand of the formula (IIIa-2) to (IIIi-1) 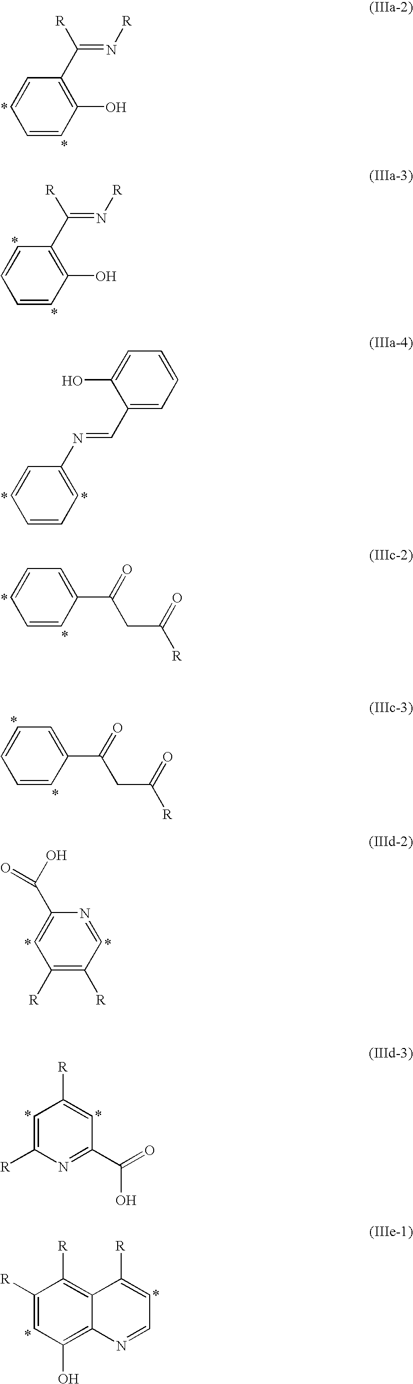 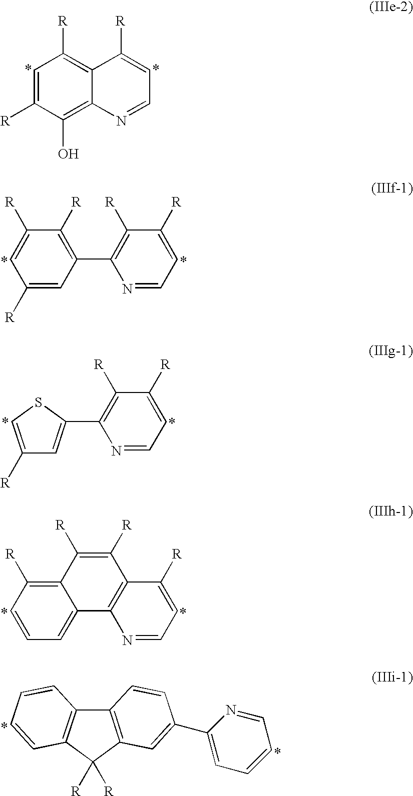
L², independently of L¹, is a ligand selected from units of the formulae (IVa-1) to (IVy-1) 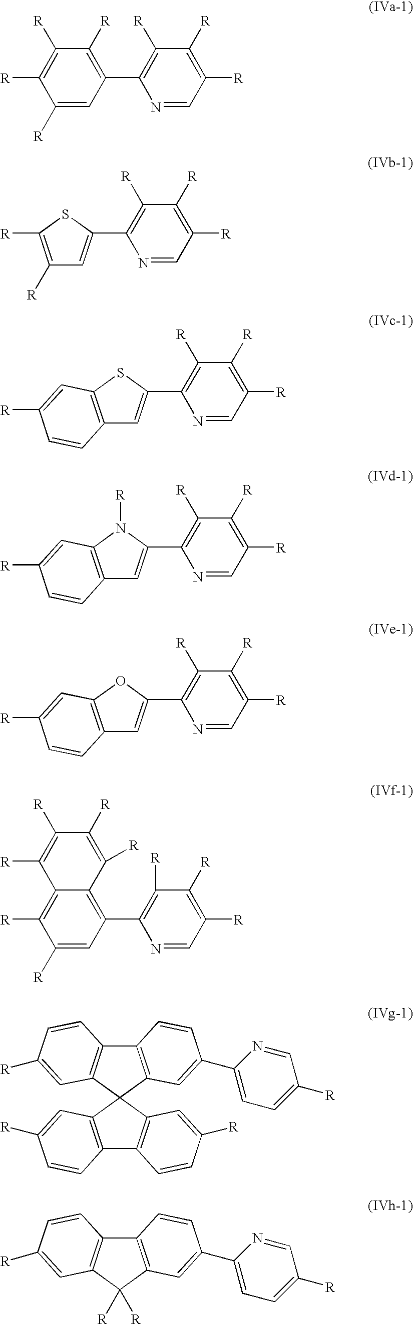 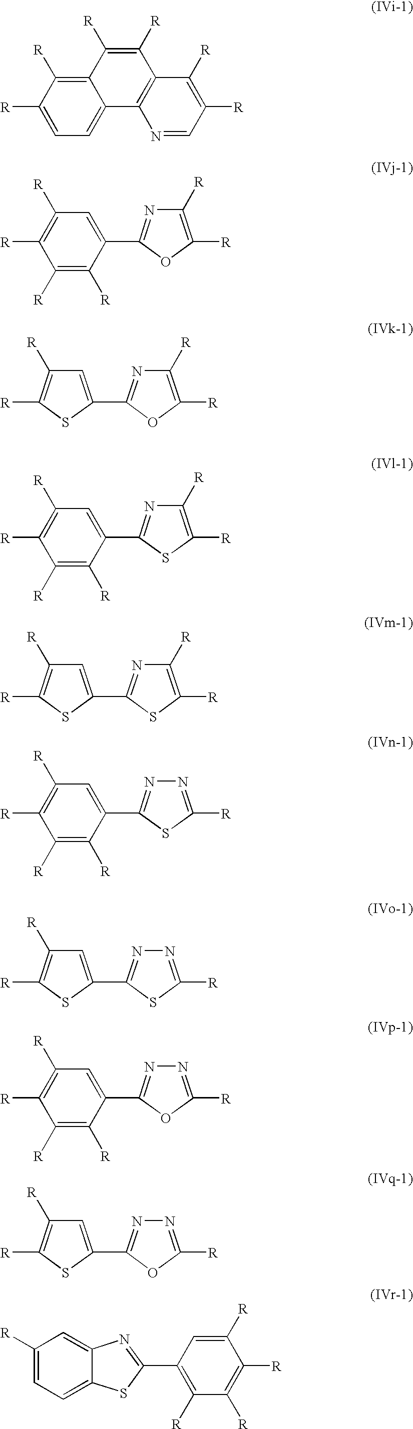 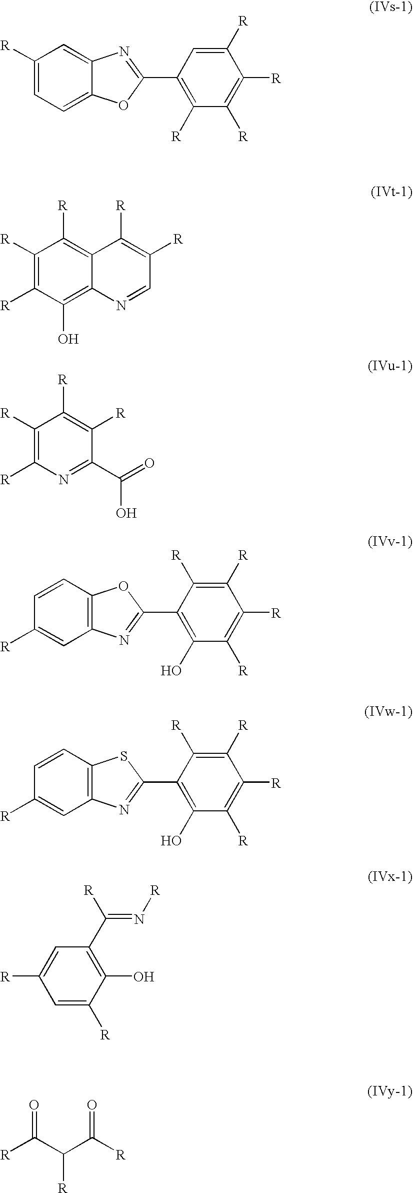
the ligands L¹ and L² complex the metal M in a chelate-like manner,
M represents iridium(III), platinum(II), osmium(II) or rhodium(III),
n represents an integer from 3 to 10 000,
z represents an integer from 1 to 3 and
R are identical or different radicals and, independently of one another, represent, H, F, CF₃, a linear or branched C₁-C₂₂-alkyl group, a linear or branched partly fluorinated or perfluorinated C₁-C₂₂-alkyl group, a linear or branched C₁-C₂₂-alkoxy group, an optionally C₁-C₃₀-alkyl-substituted C₅-C₂₀-aryl unit and/or an optionally C₁-C₃₀-alkyl-substituted heteroaryl unit having 5 to 9 ring C atoms and 1 to 3 ring hetero atoms from the group consisting of nitrogen, oxygen and sulphur.

20. Luminescent polymer according to claim 19, characterized in that it contains n repeating units of the general formulae (Ic-1) and (Id-1) 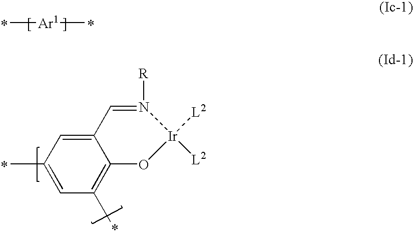
in which
R represents a linear or branched C₁-C₂₂-alkyl group or a linear or branched partly fluorinated or perfluorinated C₁-C₂-alkyl group and
n, Ar¹ and L² have the meaning stated in claim 18.

21. Luminescent polymer according to at least one of claims 15 to 20, characterized in that L² represents ligands selected from units of the formulae

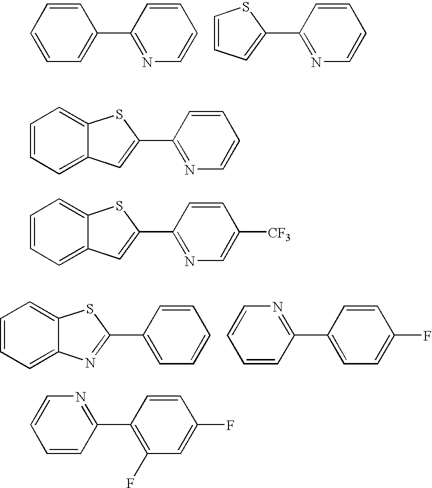

22. Luminescent polymer according to at least one of claims 15 to 21, characterized in that Ar¹ and Ar², independently of one another, represent units of the formulae 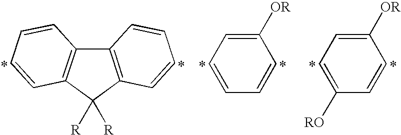
in which
R represents a linear or branched C₁-C₂₂-alkyl group.

23. Luminescent polymer according to at least one of claims 15 to 22, characterized in that n represents an integer from 10 to 5 000, preferably from 20 to 1 000, particularly preferably from 40 to 500.

24. Process for the preparation of phosphorescent or luminescent polymers according to at least one of claims 1 to 23, characterized in that uncomplexed ligand polymers are complexed with iridium(III), platinum(II), osmium(II) or rhodium(III) precursor complexes.

25. Process for the preparation of phosphorescent or luminescent polymers according to claim 24, characterized in that uncomplexed ligand polymers are complexed with iridium(III) precursor complexes of the general formula E
(L²)₂Ir(μ-C)₂Ir(L²)₂ E
in which L² has the meaning stated in at least one of claims 1 to 23.

26. Use of the phosphorescent or luminescent polymers according to at least one of claims 1 to 23 or blends thereof as emitters in light-emitting components.

27. Electroluminescent arrangement, characterized in that it contains at least one phosphorescent or luminescent polymer according to at least one of claims 1 to 23 or blends thereof.

28. Electroluminescent arrangement according to claim 27, characterized in that it contains a hole-injecting layer.

29. Production of the electroluminescent elements in the electroluminescent arrangements according to claim 27 or 28, characterized in that the phosphorescent or luminescent polymers according to at least one of claims 1 to 23 or blends thereof are applied from solution.
